(19) United States
(12) Patent Application Publication
(10) Pub. No.: US 2016/0153089 A1
(43) Pub. Date: Jun. 2, 2016

(54) GAS BARRIER FILM, METHOD FOR PRODUCING THE SAME, AND ELECTRONIC DEVICE USING THE SAME

(71) Applicant: KONICA MINOLTA, INC., Tokyo (JP)

(72) Inventor: Yoshitaka GOTO, Hino-shi, Tokyo (JP)

(21) Appl. No.: 14/900,474

(22) PCT Filed: Jun. 30, 2014
(86) PCT No.: PCT/JP2014/067464

§ 371 Date: Dec. 21, 2015

(30) Foreign Application Priority Data
Jul. 1, 2013 (JP) 2013-138333

(51) Int. Cl. C23C 16/48; C23C 16/22

(52) U.S. Cl. CPC C23C 16/48; C23C 16/22

(57) ABSTRACT

[Object] Provided is a gas barrier film which exhibits excellent gas barrier property and excellent storage stability in an environment of a high temperature and high humidity condition, particularly adhesive property or folding resistance.

[Solving Means] Disclosed is a gas barrier film which includes a substrate, a barrier layer formed by vapor phase film deposition of an inorganic compound at least one surface of the substrate, and a barrier layer formed by coating a solution containing a polysilazane compound at least on the same surface as the surface of the substrate on which the barrier layer formed by vapor phase film deposition of an inorganic compound is formed, in which the barrier layer formed by coating a solution containing a polysilazane compound contains at least one element selected from the group consisting of Group 2 elements, Group 13 elements, and Group 14 elements in the long-period periodic table (provided that silicon and carbon are excluded) and a thickness of the barrier layer formed by coating a solution containing a polysilazane compound is 0.1 nm or more and less than 150 nm.

### TECHNICAL FIELD

The present invention relates to a gas barrier film, a method for producing the same, and an electronic device using the same. More specifically, the present invention relates to a gas barrier film which exhibits high gas barrier property and excellent stability, a method for producing the same, and an electronic device using the same.

### BACKGROUND ART

Hitherto, gas barrier films having a relatively simple structure in which an inorganic film such as a deposited film of a metal or a metal oxide is provided on the surface of a resin substrate have been used in the fields such as food, packaging materials, and pharmaceuticals in order to prevent the permeation of gas such as water vapor or oxygen.

In recent years, such gas barrier films to prevent the permeation of water vapor, oxygen, or the like have been also utilized in the field of electronic devices such as a liquid crystal display device (LCD), a photovoltaic (PV) cell, and organic electroluminescence (EL) device. Not a glass substrate that is hard and easily broken but a gas barrier film exhibiting high gas barrier property is required in order to impart flexibility and the property that is light and hardly broken to such an electronic device.

As the strategy for obtaining a gas barrier film which is applicable in an electronic device, a method in which a barrier layer is formed on a substrate such as a film or a resin substrate by a plasma CVD method (Chemical Vapor Deposition) or a method in which a barrier layer is formed by coating a coating liquid containing a polysilazane as a main component on a substrate and then subjecting the coated substrate to a surface treatment (modification treatment) is known.

For example, a technology is disclosed in JP 2009-255040 A in which a thin film is stacked on a substrate by repeatedly conducting a step of forming a polysilazane film from a liquid containing a polysilazane using a wet coating method and a step of irradiating the polysilazane film with vacuum ultraviolet rays, each step being performed two or more times, in order to achieve both the thickening of the barrier layer for achieving high gas barrier property and the suppression of cracking of the thickened barrier layer.

In addition, a gas barrier film exhibiting improved abrasion resistance by the addition of a transition metal to the silicon-containing film is disclosed in JP 2012-148416 A.

In addition, a method is described in JP 63-191832 A in which polyaluminosilazane as a material of a film which has a high hardness and exhibits excellent heat resistance and oxidation resistance is obtained by the thermal reaction of polysilazane and aluminum alkoxide.

### SUMMARY OF INVENTION

In the gas barrier films described in JP 2009-255040 A and JP 2012-148416 A, the barrier layer is formed by irradiating the polysilazane film with vacuum ultraviolet rays to modify it. However, the barrier layer is modified from the surface side irradiated with vacuum ultraviolet rays and thus oxygen or moisture does not enter the inside of the barrier layer and an unreacted (unmodified) region in which ammonia may be generated by hydrolysis remains. The unreacted (unmodified) region gradually undergoes a reaction in a high temperature and high humidity environment to produce a byproduct, the deformation or fracture of the barrier layer is caused by the diffusion of this byproduct in some cases, and as a result, the gas barrier property gradually decreases, which is a problem.

Furthermore, it is required to increase the light quantity of ultraviolet rays to modify the polysilazane film and to stack a plurality of barrier layers in order to obtain higher gas barrier property. However, there is also a problem that the internal shrinkage stress in the film increases and the flexibility (plasticity) that is a characteristic of a flexible gas barrier film and the durability to a physical stress such as bending decrease as well as the productivity decreases as the progress degree of modification or the number of stacked layers increases and the film thickness increases.

Accordingly, the present invention has been made in view of the above circumstances, and an object thereof is to provide a gas barrier film which exhibits high gas barrier property, adhesive property, and folding resistance, maintains excellent gas barrier property, adhesive property, and folding resistance even after being stored in an environment of a high temperature and high humidity condition, and exhibits excellent crack resistance.

The present inventor has carried out extensive studies in order to solve the above problem. As a result, the inventor has found out that the above problem can be solved by allowing a barrier layer to contain a specific element, the barrier layer being formed by coating and further controlling the thickness of the barrier layer formed by coating to be in a predetermined range in a gas barrier film having a barrier layer formed by vapor phase film deposition of an inorganic compound and a barrier layer formed by coating a solution containing a polysilazane compound, thereby completing the present invention.

### BRIEF DESCRIPTION OF DRAWINGS

FIG. 1 is a schematic diagram illustrating an example of a vacuum plasma CVD apparatus used in the formation of a barrier layer formed by vapor phase film deposition in a gas barrier film of the present invention. 101 is a plasma CVD apparatus, 102 is a vacuum chamber, 103 is a cathode electrode, 105 is a susceptor, 106 is a heat medium circulating system, 107 is a vacuum pumping system, 108 is a gas introducing system, 109 is a high frequency power supply, 110 is a substrate, and 160 is a heating and cooling system.

FIG. 2 is a schematic diagram illustrating an example of another producing apparatus used in the formation of a barrier layer formed by vapor phase film deposition. 1 is a gas barrier film, 2 is a substrate, 3 is a barrier layer, 31 is a producing apparatus, 32 is a delivery roller, 33, 34, 35 and 36 are a conveying roller, 39 and 40 are a film depositing roller, 41 is a gas supply pipe, 42 is a power supply for plasma generation, 43 and 44 are a magnetic field generator, and 45 is a winding roller.

FIG. 3 is a schematic diagram illustrating an example of a vacuum ultraviolet ray irradiating apparatus. 21 is a chamber of the apparatus, 22 is an Xe excimer lamp, 23 is a holder of the excimer lamp which also serves as an external electrode, 24 is a sample stage, 25 is a sample on which a polysilazane coating layer is formed, and 26 is a light shielding plate.

### DETAILED DESCRIPTION

The present invention is a gas barrier film which includes a substrate, a barrier layer formed by vapor phase film deposition of an inorganic compound at least on one surface of the substrate, and a barrier layer formed by coating a solution containing a polysilazane compound at least on the same surface as the surface of the substrate on which the barrier layer formed by vapor phase film deposition of an inorganic compound is formed, in which the barrier layer formed by coating a solution containing a polysilazane compound contains at least one element selected from the group consisting of Group 2 elements, Group 13 elements, and Group 14 elements in the long-period periodic table (provided that silicon and carbon are excluded), and a thickness of the barrier layer formed by coating a solution containing a polysilazane compound is 0.1 nm or more and less than 150 nm.

In addition, the present invention is a method for producing a gas barrier film which includes forming a barrier layer on a substrate by vapor phase film deposition of an inorganic compound and forming a barrier layer on the barrier layer formed by vapor phase film deposition of an inorganic compound by coating a solution containing a polysilazane compound and a compound containing at least one element selected from the group consisting of Group 2 elements, Group 13 elements, and Group 14 elements in the long-period periodic table (provided that silicon and carbon are excluded) and in which a thickness of the barrier layer formed by coating a solution containing a polysilazane compound is 0.1 nm or more and less than 150 nm.

According to the present invention, a gas barrier film which exhibits high gas barrier property, adhesive property, and folding resistance, maintains excellent gas barrier property, adhesive property, and folding resistance after being stored in an environment of a high temperature and high humidity condition, and exhibits excellent crack resistance is provided.

The gas barrier film of the present invention contains a Group 2 element, Group 13 element, or Group 14 element (provided that silicon and carbon are excluded) in the barrier layer formed by using a solution containing a polysilazane compound. The gas barrier film of the present invention having such a configuration stably exerts barrier performance and exhibits favorable adhesive property even when being stored in a high temperature and a high humidity and excellent resistance without being changed in barrier property.

Hitherto, sufficient defect repair has not been achieved in a case in which it is attempted to repair the defect of the barrier layer by vapor phase film deposition with a film that is obtained by coating a coating liquid containing a polysilazane compound on a barrier layer formed by vapor phase film deposition and subjecting the resultant to a modification treatment of being irradiated with vacuum ultraviolet rays using an excimer lamp or the like. This is because the fact that it cannot be said that the adhesive force at the interface between the barrier layer by vapor phase film deposition itself and the film obtained by coating a coating liquid containing a polysilazane compound and subjecting the resultant to a modification treatment of being irradiated with vacuum ultraviolet rays using an excimer lamp or the like itself is sufficient is a factor, and it has been a great problem.

In the method for producing a gas barrier film including forming a barrier layer by coating a coating liquid containing a polysilazane compound and then subjecting the resultant to a modification treatment of being irradiated with vacuum ultraviolet rays using an excimer lamp or the like, the barrier layer is formed from the surface layer, and thus there is a problem that oxygen or moisture does not enter the inside of the layer, the inside of the layer or still more the interface of the barrier layer by vapor phase film deposition is not oxidized but remains as it is unmodified and unstable, and the performance, particularly the performance at a high temperature and a high humidity fluctuates. It has been attempted to advance the modification by increasing the quantity of light, but there is also a problem that a dangling bond is formed on the surface as the barrier layer is exposed to light, the quantity of light absorbed by the surface increases, and the efficiency of modification worsens.

w wavelength side decreases as the barrier layer is irradiated invention, the modification of the film uniformly proceeds even to the interface with the barrier layer by vapor phase film deposition, and as a result, the adhesive force with the barrier layer by vapor phase film deposition is greatly improved and the barrier performance is stably exerted as the barrier layer formed by coating a solution containing a polysilazane compound contains at least one element selected from the group consisting Group 2 elements, Group 13 elements, and Group 14 elements (provided that silicon and carbon are excluded). Furthermore, it is possible to structure a gas barrier film which exhibits high resistance so that the barrier property does not change during the storage under a wet heat condition. In addition, it is demonstrated that the resistance in a wet heat environment is improved by controlling the thickness of the barrier layer formed by coating a solution containing a polysilazane compound to 0.1 nm or more and less than 150 nm.

In the gas barrier film according to the present invention, the regularity and melting point of the film decrease, and the flexibility of the film is improved by heat or light during the film forming process or the film is melted as a specific additive element is contained in the barrier layer formed by coating a solution containing a polysilazane compound. It is believed that the defect is repaired by this improvement in flexibility of the film or this melting of the film so that the film becomes a dense film and the gas barrier property thereof is improved. In addition, it is believed that oxygen is supplied to the inside of the film as the fluidity increases by an improvement in flexibility of the film or the melting of the film, and thus a barrier layer in which even the inside of the film is modified is obtained and the barrier layer exhibits high resistance to oxidation in a state in which the film formation is finished. Furthermore, it is preferable that the barrier layer formed by coating a solution containing a polysilazane compound is formed, for example, through a modification treatment by an active energy ray. The gas barrier property can be improved by the modification treatment. Here, the dangling bond increases as the barrier layer which does not contain an additive element is irradiated with an active energy ray, and perhaps due to this, the absorbance at 250 nm or less increases, the active energy ray is gradually less likely to penetrate to the inside of the film, and only the film surface is modified. On the other hand, the barrier layer formed by coating a solution containing a polysilazane compound in the gas barrier film of the present invention contains a specific additive element, thus the absorbance on the low wavelength side decreases as the barrier layer is irradiated with an active energy ray although the reason is not clear, and it is believed from the fact that the modification of the barrier layer homogeneously proceeds from the surface toward the inside thereof. Particularly, in a gas barrier film which includes the substrate, the barrier layer formed by vapor phase film deposition, and the barrier layer formed by coating a solution containing a polysilazane compound in this order, it is believed that the modification uniformly proceeds even to the interface with the barrier layer formed by vapor phase film deposition, and as a result, the adhesive force at the interface between the barrier layer formed by vapor phase film deposition and the barrier layer formed by coating is significantly enhanced. As a result, it is believed that a gas barrier film which exhibits strong resistant so that the film is hardly denatured even in a high temperature and high humidity environment is formed. In addition, it is preferable that at least either of the barrier layer formed by deposition (vapor phase film deposition) of an inorganic compound or the barrier layer formed by coating a solution containing a polysilazane compound is formed through a modification treatment, for example, by vacuum ultraviolet irradiation. The above effect can be more remarkably obtained as the barrier layer formed by coating a solution containing a polysilazane compound is modified by irradiating with vacuum ultraviolet rays. When the barrier layer formed by vapor phase film deposition is irradiated with an active energy ray such as vacuum ultraviolet rays to conduct a modification treatment, the foreign substance is decomposed, oxidized, and removed by the energy of vacuum ultraviolet light and ozone, active oxygen, and the like generated by the energy, and thus the defect as a barrier layer is repaired or the surface smoothness is enhanced so that the coating uniformity of the solution containing a polysilazane compound can be improved, and as a result, it leads to an improvement in gas barrier property.

Furthermore, the present inventors have found out that in the gas barrier film including a barrier layer containing an additive element, as the thickness of the barrier layer is controlled to 0.1 nm or more and less than 150 nm the modification in the film thickness direction can more homogeneously proceed as compared to a case in which a barrier layer having a thickness of 150 nm or more is formed, and thus the adhesive property at the interface between the barrier layer and the substrate or a barrier layer of a lower layer is further improved, the gas barrier property is further improved, and a decrease in gas barrier property in a wet heat environment is suppressed. In the gas barrier film of the present invention, the thickness of the barrier layer formed by coating a solution containing a polysilazane compound is 0.1 nm or more and less than 150 nm. In addition, the bending property and handleability of the gas barrier film to be obtained are improved as compared to a case in which a barrier layer having a thickness of 150 nm or more is formed by setting the thickness of the barrier layer to 0.1 nm or more and less than 150 nm. Moreover, the gas barrier film is hardly broken or cracked even when being bent to have a small curvature. In addition, it has been found that excellent adhesive property, folding resistance, and crack resistance are maintained even in a harsh high temperature and high humidity environment. In a case in which the thickness of the barrier layer formed by coating is 150 nm or more, the flexibility of the film is not sufficient and thus the film is broken by the stress in some cases. On the other hand, it is impossible to obtain sufficient gas barrier property when the thickness of the barrier layer formed by coating a solution containing a polysilazane compound is less than 0.1 nm. The thickness of the barrier layer formed by coating a solution containing a polysilazane compound is preferably from 1 to 100 nm, more preferably from 2 to 80 nm, and more preferably from 5 to 60 nm. In a case in which the barrier layer formed from a solution containing a polysilazane compound does not contain at least one element selected from the group consisting of Group 2 elements, Group 13 elements, and Group 14 elements (provided that silicon and carbon are excluded), the gas barrier property tends to decrease when the thickness of the barrier layer is set to be thinner than about 100 nm and a change in performance in a high temperature and high humidity environment tends to increase. On the other hand, the modification hardly proceeds to the inside of the barrier layer even though the thickness of the barrier layer is set to be thick and thus it is not easy to obtain sufficient gas barrier property. However, the modification efficiently proceeds from the surface to the inside of the barrier layer in a case in which the specific element described above is contained, and excellent gas barrier property can be achieved in a thickness range of 0.1 nm or more. Moreover, the modification uniformly proceeds in the thickness direction, thus a barrier layer having a smaller difference in distribution of the composition can be formed in a thickness range of less than 150 nm, and high gas barrier property can be obtained. According to the present invention, the modification more uniformly proceeds and the adhesive force at the interface is further improved, thus a gas barrier film which exhibits strong resistance so that the film is hardly denatured even in a high temperature and high humidity environment can be formed as well as the gas barrier property is improved when the thickness of the barrier layer formed by coating a solution containing a polysilazane compound is in a range of 0.1 nm or more and less than 150 nm. Hence, a gas barrier film which exhibits high gas barrier property, excellent storage stability in an environment of a high temperature and high humidity condition, and particularly improved adhesive property, resistance to folding, or handleability can be obtained. In a case in which the barrier layer formed by coating a solution containing a polysilazane compound is constituted by two or more layers, it is sufficient that at least one layer contains the specific element described above and has a thickness of 0.1 nm or more and less than 150 nm, but it is preferable that all of the respective barrier layers contain the specific element described above and have a thickness as described above.

In addition, in the gas barrier film of the present invention, it is preferable that the barrier layer formed by vapor phase film deposition of an inorganic compound is a deposited layer containing a nitrogen atom. In particular, in the configuration including the barrier layer which is formed by vapor phase film deposition and contains a nitrogen atom and the layer which contains a specific additive element and is formed by coating a solution containing a polysilazane compound, the absorption of the vacuum ultraviolet rays at the interface between the barrier layer formed by vapor phase film deposition and the barrier layer formed by coating increases when conducting the modification treatment by vacuum ultraviolet irradiation, further the modified adhesive force is improved, and a gas barrier film having a small change in performance in a high temperature and high humidity environment can be obtained as a whole.

Furthermore, it is preferable that the barrier layer formed by coating a solution containing a polysilazane compound is formed through an after-treatment (particularly, temperature treatment). As the barrier layer formed by coating is subjected to an after-treatment (particularly, temperature treatment), oxygen or moisture enters the inside of the film by heat or humidity in the barrier layer, the oxidation proceed to the inside of the barrier layer formed by coating a solution containing a polysilazane compound or the interface with the barrier layer formed by vapor phase film deposition, the unmodified part in the barrier layer formed by coating decreases, and a gas barrier film having more favorable performance can be obtained.

Hereinafter, preferred embodiments of the present invention will be described. Incidentally, the present invention is not limited to the following embodiments.

In addition, in the present specification, the expression “X to Y” which denotes the range means “X or more and Y or less”.

<Gas Barrier Film>

The gas barrier film of the present invention includes a substrate, a barrier layer formed by vapor phase film deposition of an inorganic compound, a barrier layer formed by coating a solution containing a polysilazane compound. The gas barrier film of the present invention may further include another member. In addition, the barrier layer formed by coating a solution containing a polysilazane compound contains at least one element selected from the group consisting of Group 2 elements, Group 13 elements, and Group 14 elements in the long-period periodic table (provided that silicon and carbon are excluded). The gas barrier film of the present invention may include another member, for example, between the substrate and either of the barrier layers, on either of the barrier layers, or on the other surface on which a barrier layer is not formed of the substrate. Here, another member is not particularly limited, and a member that is used in a gas barrier film of the prior art can be used in the same manner or after being appropriately qualified. Specific examples thereof may include a barrier layer containing silicon, carbon, and oxygen, a smoothing layer, an anchor coat layer, a bleed-out preventing layer, and a functional layer such as a protective layer, a moisture absorbing layer, or an antistatic layer.

Incidentally, in the present invention, each of the barrier layers described above may be present as a single layer or may have a multilayer structure of two or more layers.

Moreover, in the present invention, each of the barrier layers described above may be formed at least on one same surface of the substrate. Hence, the gas barrier film of the present invention includes both of a form in which each of the barrier layers described above is formed on one surface of the substrate and a form in which each of the barrier layers described above is formed on both surfaces of the substrate.

(Substrate)

In the gas barrier film according to the present invention, a plastic film or sheet is usually used as the substrate and a film or sheet composed of a colorless and transparent resin is preferably used. The material nature, thickness, and the like of the plastic film to be used are not particularly limited as long as the plastic film is a film which can hold the barrier layer and the like, and they can be appropriately selected depending on the purpose of use and the like. Specific examples of the plastic film may include a polyester resin, a methacrylic resin, a methacrylic acid-maleic acid copolymer, a polystyrene resin, a transparent fluororesin, a polyimide, a fluorinated polyimide resin, a polyamide resin, a polyamide-imide resin, a polyetherimide resin, a cellulose acylate resin, a polyurethane resin, a polyetheretherketone resin, a polycarbonate resin, an alicyclic polyolefin resin, a polyarylate resin, a polyethersulfone resin, a polysulfone resin, a cycloolefin copolymer, a fluorene ring-modified polycarbonate resin, an alicyclic-modified polycarbonate resin, a fluorene ring-modified polyester resin, and a thermoplastic resin such as an acryloyl compound.

As preferred forms of the material nature, thermal properties, optical properties, thickness, producing method, and the like of the substrate, the forms disclosed in the paragraphs “0114” to “0126” of JP 2013-226757 A, and the like are appropriately adopted.

[Barrier Layer Formed by Vapor Phase Film Deposition of Inorganic Compound (Dry Barrier Layer)]

The barrier layer formed by vapor phase film deposition of an inorganic compound contains an inorganic compound. The inorganic compound contained in the barrier layer formed by vapor phase film deposition is not particularly limited, but examples thereof may include a metal oxide, a metal nitride, a metal carbide, a metal oxynitride, or a metal oxycarbide. Among them, from the viewpoint of gas barrier performance, an oxide, a nitride, a carbide, an oxynitride, or an oxycarbide containing one or more kinds of metals selected from Si, Al, In, Sn, Zn, Ti, Cu, Ce, and Ta can be preferably used, an oxide, a nitride, an oxynitride, or an oxycarbide of a metal selected from Si, Al, In, Sn, Zn, and Ti is more preferable, and particularly an oxide, a nitride, an oxynitride, or an oxycarbide of at least either kind of Si or Al is preferable. Specific examples of suitable inorganic compound may include a composite such as silicon oxide, silicon nitride, silicon oxynitride, silicon carbide, silicon oxycarbide, aluminum oxide, titanium oxide, or aluminum silicate. The inorganic compound may contain another element as a secondary component.

The content of the inorganic compound contained in the barrier layer formed by vapor phase film deposition is not particularly limited, but it is preferably 50% by mass or more, more preferably 80% by mass or more, even more preferably 95% by mass or more, particularly preferably 98% by mass or more, and most preferably 100% by mass (that is, the barrier layer formed by vapor phase film deposition is composed of an inorganic compound) in the barrier layer formed by vapor phase film deposition.

The barrier layer formed by vapor phase film deposition exhibits gas barrier property as it contains an inorganic compound. Here, as the gas barrier property of the barrier layer formed by vapor phase film deposition, the water vapor transmission rate (WVTR) is preferably 1×10⁻³ g/m²·day or less and more preferably 1×10⁻⁴ g/m²·day or less when calculated using a stacked body fabricated by forming the barrier layer formed by vapor phase film deposition on a substrate.

The film thickness of the barrier layer formed by vapor phase film deposition is not particularly limited, but it is preferably from 50 to 600 nm and more preferably from 100 to 500 nm. High gas barrier performance, folding resistance, and excellent cutting processing suitability are exhibited when the film thickness is in such a range. In addition, the barrier layer formed by vapor phase film deposition may be constituted by two or more layers, and the total thickness of the barrier layers formed by vapor phase film deposition in this case is not particularly limited, but it is preferably about from 100 to 2000 nm. The gas barrier film can exert excellent gas barrier property and an excellent cracking suppressing/preventing effect at the time of being bent when the barrier layers have such a thickness.

The barrier layer formed by vapor phase film deposition of an inorganic compound may be formed between the substrate and the barrier layer formed by coating a solution containing a polysilazane compound or on top of the barrier layer formed on the substrate by coating a solution containing a polysilazane compound. Preferably, the gas barrier film is formed so as to include the substrate, the barrier layer formed by vapor phase film deposition of an inorganic compound, and the barrier layer formed by coating a solution containing a polysilazane compound in this order. The gas barrier property can be further improved by forming the gas barrier film in this manner.

The vapor phase film deposition method for forming the barrier layer formed by vapor phase film deposition is not particularly limited. It is possible to utilize the existing thin film depositing technology. For example, a vapor phase film deposition method such as a deposition method, a reactive deposition method, a sputtering method, a reactive sputtering method, or a chemical vapor deposition method can be used. In the present invention, a chemical vapor deposition method is preferably used.

The chemical vapor deposition method (CVD method) is a method in which a raw material gas containing the component of the intended thin film is supplied onto the substrate and a film is deposited by a chemical reaction on the substrate surface or in a gas phase. In addition, there is a method in which a plasma and the like are generated for the purpose of activating the chemical reaction, and examples thereof may include a known CVD method such as a thermal CVD method, a catalytic chemical vapor deposition method, an optical CVD method, a vacuum plasma CVD method, or an atmospheric pressure plasma CVD method. The CVD method is a more promising technique since it is possible to form a film at a high speed and coatability with respect to the substrate is more favorable as compared to the sputtering method and the like. In particular, the catalytic chemical vapor deposition (Cat-CVD) method to use a catalytic body at a significantly high temperature as the excitation source or the plasma-enhanced chemical vapor deposition (PECVD) method to use a plasma as the excitation source is a preferred method.

(Cat-CVD Method)

The Cat-CVD method is a method in which a material gas is allowed to flow into a vacuum vessel having a wire made of tungsten or the like arranged therein, the decomposition reaction of the material gas is catalyzed by the wire that is electrically heated by a power supply, and the reactive species thus generated is deposited on the substrate.

(PECVD Method)

The PECVD method is a method in which a material gas is allowed to flow into a vacuum vessel which is equipped with a plasma source, a discharge plasma is generated in the vacuum vessel by supplying the electrical power from the power supply to the plasma source, the material gas is subjected to the decomposition reaction by the plasma, and the reactive species thus generated is deposited on the substrate. As the method of the plasma source, a capacitively coupled plasma using parallel plate electrodes, an inductively coupled plasma, a microwave excited plasma utilizing a surface wave, or the like is used.

A barrier layer obtained by the vacuum plasma CVD method or the plasma CVD method under the atmospheric pressure or a pressure near the atmospheric pressure is preferable since it is possible to produce an intended compound by choosing the conditions such as the metal compound that is the primary material (also referred to as the raw material), the decomposition gas, the decomposition temperature, and the input electrical power. The more detailed conditions for forming the barrier layer by the plasma CVD method, for example, the conditions described in the paragraphs “0033” to “0051” of international publication (WO) No. 2012/067186 may be appropriately adopted.

Hereinafter, the vacuum plasma CVD method that is a preferred form among the CVD methods will be specifically described.

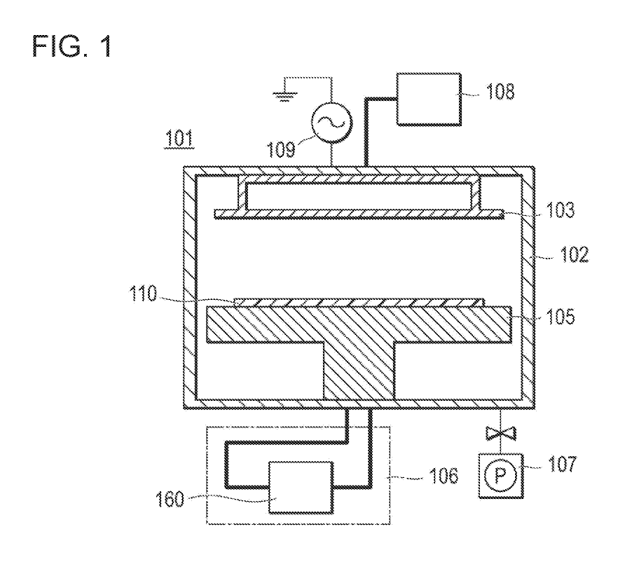

FIG. 1 is a schematic diagram illustrating an example of a vacuum plasma CVD apparatus used in the formation of the barrier layer formed by vapor phase film deposition.

In FIG. 1, a vacuum plasma CVD apparatus 101 includes a vacuum chamber 102, and a susceptor 105 is disposed on the bottom side of the inside of the vacuum chamber 102. In addition, a cathode electrode 103 is disposed on the ceiling side of the inside of the vacuum chamber 102 at a location facing the susceptor 105. A heating medium circulating system 106, a vacuum pumping system 107, a gas introducing system 108, a high frequency power supply 109 are disposed on the outside of the vacuum chamber 102. A heating medium is disposed in the heating medium circulating system 106. The heating medium circulating system 106 is provided with a heating and cooling device 160 which includes a pump for moving the heating medium, a heating device for heating the heating medium, a cooling device for cooling, a temperature sensor for measuring the temperature of the heating medium, and a memory unit to memorize the set temperature of the heating medium.

In addition, as a suitable embodiment of the layer formed by vapor phase film deposition of an inorganic compound (dry barrier layer) according to the present invention, it is preferable that the barrier layer formed by vapor phase film deposition contains carbon, silicon, and oxygen as the constituent elements. Amore suitable embodiment is a layer which satisfies the following requirements of (i) to (iii).

(i) In the silicon distribution curve that indicates the relation between the distance (L) from the surface of the barrier layer in the film thickness direction of the barrier layer and the ratio (atomic ratio of silicon) of the amount of the silicon atom to the total amount of the silicon atom, the oxygen atom, and the carbon atom, the oxygen distribution curve that indicates the relation between the L described above and the ratio (atomic ratio of oxygen) of the amount of the oxygen atom to the total amount of the silicon atom, the oxygen atom, and the carbon atom, and the carbon distribution curve that indicates the relation between the L described above and the ratio (atomic ratio of carbon) of the amount of the carbon atom to the total amount of the silicon atom, the oxygen atom, and the carbon atom, the (atomic ratio of oxygen), the (atomic ratio of silicon), and the (atomic ratio of carbon) decrease in this order (atomic ratio is O>Si>C) in the region of 90% or more (upper limit: 100%) of the film thickness of the barrier layer;

(ii) the carbon distribution curve has at least two extreme values; and

(iii) the absolute value of the difference between the maximum value and the minimum value of the atomic ratio of carbon in the carbon distribution curve (hereinafter, also simply referred to as the “Cₘₐₓ−Cₘᵢₙ difference”) is 3 at % or more.

First, in the barrier layer, it is preferable that (i) in the silicon distribution curve that indicates the relation between the distance (L) from the surface of the barrier layer in the film thickness direction of the barrier layer and the ratio (atomic ratio of silicon) of the amount of the silicon atom to the total amount of the silicon atom, the oxygen atom, and the carbon atom, the oxygen distribution curve that indicates the relation between the L described above and the ratio (atomic ratio of oxygen) of the amount of the oxygen atom to the total amount of the silicon atom, the oxygen atom, and the carbon atom, and the carbon distribution curve that indicates the relation between the L described above and the ratio (atomic ratio of carbon) of the amount of the carbon atom to the total amount of the silicon atom, the oxygen atom, and the carbon atom, the (atomic ratio of oxygen), the (atomic ratio of silicon), and the (atomic ratio of carbon) decrease in this order (atomic ratio is O>Si>C) in the region of 90% or more (upper limit: 100%) of the film thickness of the barrier layer. The gas barrier property or bending property of the gas barrier film to be obtained is favorable when the condition (i) is satisfied. Here, the relation among the (atomic ratio of oxygen), the (atomic ratio of silicon), and the (atomic ratio of carbon) in the carbon distribution curve is more preferably satisfied in the region of at least 90% or more (upper limit: 100%) and more preferably satisfied in the region of at least 93% or more (upper limit: 100%) of the film thickness of the barrier layer. Here, the “at least 90% or more of the film thickness of the barrier layer” may not be continuous in the barrier layer but may simply satisfy the relation described above at the part of 90% or more.

Preferably, in the barrier layer, (ii) the carbon distribution curve has at least two extreme values. In the barrier layer, the carbon distribution curve has more preferably at least three extreme values and even more preferably at least four extreme values, but the carbon distribution curve may have five or more extreme values. The gas barrier property in the case of bending the gas barrier film to be obtained is favorable when the extreme value on the carbon distribution curve is two or more. Incidentally, the upper limit of the extreme value on the carbon distribution curve is not particularly limited, but for example, it is preferably 30 or less and more preferably 25 or less. The number of extreme values cannot be generally defined since it is also dependent on the film thickness of the barrier layer.

Here, in the case of having at least three extreme values, all of the absolute values of the difference in distance (L) from the surface of the barrier layer in the film thickness direction of the barrier layer in one extreme value and another extreme value adjacent to the one extreme value (hereinafter, also simply referred to as the “distance between the extreme values”) belonging to the carbon distribution curve are preferably 200 nm or less, more preferably 100 nm or less, and even more preferably 75 nm or less. The site (local maximum value) at which the carbon atomic ratio is great is present in an adequate period in the barrier layer when the distance between the extreme values is in such a range, and thus adequate bending property is imparted to the barrier layer and cracking of the gas barrier film at the time of being bent can be more effectively suppressed and prevented. Incidentally, the “extreme value” in the present specification refers to the local maximum value or local minimum value of the atomic ratio of an element with respect to the distance (L) from the surface of the barrier layer in the film thickness direction of the barrier layer. In addition, the “local maximum value” in the present specification refers to the point at which the value of the atomic ratio of an element (oxygen, silicon, or carbon) changes from an increase to a decrease in the case of changing the distance from the surface of the barrier layer and also refers to the point at which the value of the atomic ratio of the element at the location to which the distance from the surface of the barrier layer in the film thickness direction of the barrier layer is further changed from the point in the range of from 4 to 20 nm decreases by 3 at % or more from the value of the atomic ratio of the element at that point. In other words, the value of the atomic ratio of an element may decrease by 3 at % or more in any range when the distance is changed in the range of from 4 to 20 nm. In the same manner, the “local minimum value” in the present specification refers to the point at which the value of the atomic ratio of an element (oxygen, silicon, or carbon) changes from a decrease to an increase in the case of changing the distance from the surface of the barrier layer and also refers to the point at which the value of the atomic ratio of the element at the location to which the distance from the surface of the barrier layer in the film thickness direction of the barrier layer is further changed from the point in the range of from 4 to 20 nm increases by 3 at % or more from the value of the atomic ratio of the element at that point. In other words, the value of the atomic ratio of an element may increase by 3 at % or more in any range when the distance is changed in the range of from 4 to 20 nm. Here, the lower limit of the distance between the extreme values in the case of having at least three extreme values is not particularly limited since the effect of improving cracking suppression/prevention of the gas barrier film at the time of being bent is greater as the distance between the extreme values is smaller, but it is preferably 10 nm or more and more preferably 30 nm or more in consideration of the bending property of the barrier layer, the crack suppressing/preventing effect and thermal expansion property.

Preferably, in the barrier layer, (iii) the absolute value of the difference between the maximum value and the minimum value of the atomic ratio of carbon in the carbon distribution curve (hereinafter, also simply referred to as the “Cₘₐₓ−Cₘᵢₙ difference”) is 3 at % or more. The gas barrier property of the gas barrier film to be obtained is favorable even in the case of being bent when the absolute value is 3 at % or more. The Cₘₐₓ−Cₘᵢₙ difference is more preferably 5 at % or more, even more preferably 7 at % or more, and even more preferably 10 at % or more. It is possible to further improve the gas barrier property by setting the Cₘₐₓ−Cₘᵢₙ difference to the above value. Incidentally, the “maximum value” in the present specification is the atomic ratio of each element to be the maximum in the distribution curve of each element and is the highest value among the local maximum values. In the same manner, the “minimum value” in the present specification is the atomic ratio of each element to be the minimum in the distribution curve of each element and is the lowest value among the local minimum values. Here, the upper limit of the Cₘₐₓ−Cₘᵢₙ difference is not particularly limited, but it is preferably 50 at % or less and more preferably 40 at % or less in consideration of the effect of improving cracking suppression/prevention of the gas barrier film at the time of being bent.

In the present invention, the oxygen distribution curve of the barrier layer preferably has at least one extreme value, more preferably at least two extreme values, and even more preferably at least three extreme values. The gas barrier property in the case of bending the gas barrier film to be obtained is further improved in a case in which the oxygen distribution curve has at least one extreme value. Incidentally, the upper limit of the extreme value on the oxygen distribution curve is not particularly limited, but for example, it is preferably 20 or less and more preferably 10 or less. The number of extreme values of the oxygen distribution curve cannot be also generally defined since it is partly dependent on the film thickness of the barrier layer. In addition, in the case of having at least three extreme values, all of the absolute values of the difference in distance from the surface of the barrier layer in the film thickness direction of the barrier layer in one extreme value and another extreme value adjacent to the one extreme value belonging to the oxygen distribution curve are preferably 200 nm or less and more preferably 100 nm or less. It is possible to more effectively suppress and prevent cracking of the gas barrier film at the time of being bent when the distance between the extremes values are in such a range. Here, the lower limit of the distance between the extreme values in the case of having at least three extreme values is not particularly limited, but it is preferably 10 nm or more and more preferably 30 nm or more in consideration of the effect of improving cracking suppression/prevention of the gas barrier film at the time of being bent and thermal expansion property.

In addition, in the present invention, the absolute value of the difference between the maximum value and the minimum value of the atomic ratio of oxygen in the oxygen distribution curve of the barrier layer (hereinafter, also simply referred to as the “Oₘₐₓ−Oₘᵢₙ difference”) is preferably 3 at % or more, more preferably 6 at % or more, and even more preferably 7 at % or more. The gas barrier property of the gas barrier film to be obtained in the case of bending the film is further improved when the absolute value is 3 at % or more. Here, the upper limit of the Oₘₐₓ−Oₘᵢₙ difference is not particularly limited, but it is preferably 50 at % or less and more preferably 40 at % or less in consideration of the effect of improving cracking suppression/prevention of the gas barrier film at the time of being bent.

In the present invention, the absolute value of the difference between the maximum value and the minimum value of the atomic ratio of silicon in the silicon distribution curve of the barrier layer (hereinafter, also simply referred to as the “Siₘₐₓ−Siₘᵢₙ difference”) is preferably 10 at % or less, more preferably 7 at % or less, and even more preferably 3 at % or less. The gas barrier property of the gas barrier film to be obtained is further improved in a case in which the absolute value is 10 at % or less. Here, the lower limit of the Siₘₐₓ−Siₘᵢₙ difference is not particularly limited since the effect of improving cracking suppression/prevention of the gas barrier film at the time of being bent is greater as the Siₘₐₓ−Siₘᵢₙ difference is smaller, but it is preferably 1 at % or more and more preferably 2 at % or more in consideration of the gas barrier property.

In addition, in the present invention, it is preferable that the total amount of the carbon and oxygen atoms with respect to the film thickness direction of the barrier layer is almost constant. By virtue of this, the barrier layer exerts adequate bending property and cracking of the gas barrier film at the time of being bent can be more effectively suppressed or prevented. More specifically, in the oxygen and carbon distribution curve that indicates the relation between the distance (L) from the surface of the barrier layer in the film thickness direction of the barrier layer and the ratio (atomic ratios of oxygen and carbon) of the total amount of the oxygen atom and the carbon atom to the total amount of the silicon atom, the oxygen atom, and the carbon atom, the absolute value of the difference between the maximum value and the minimum value of the sum of the atomic ratios of oxygen and carbon in the oxygen and carbon distribution curve (hereinafter, also simply referred to as the “OCₘₐₓ−OCₘᵢₙ difference”) is preferably less than 5 at %, more preferably less than 4 at %, and even more preferably less than 3 at %. The gas barrier property of the gas barrier film to be obtained is further improved when the absolute value is less than 5 at %. Incidentally, the lower limit of the OCₘₐₓ−OCₘᵢₙ difference is 0 at % since it is more preferable as the OCₘₐₓ−OCₘᵢₙ difference is smaller, but it is sufficient that the lower limit is 0.1 at % or more.

The silicon distribution curve, the oxygen distribution curve, the carbon distribution curve, and the oxygen and carbon distribution curve can be created by the so-called XPS depth profile measurement to sequentially conduct the surface composition analysis while exposing the inside of the sample by concurrently using the measurement by X-ray photoelectron spectroscopy (XPS) and the ion sputtering of a noble gas such as argon. The distribution curve obtained by such an XPS depth profile measurement can be created, for example, by plotting the atomic ratio of each element (unit:at %) on the longitudinal axis and the etching time (sputtering time) on the horizontal axis. Incidentally, the etching time is roughly correlated with the distance (L) from the surface of the barrier layer in the film thickness direction of the barrier layer in the film thickness direction in the distribution curve of the element in which the etching time is plotted on the horizontal axis as described above, and thus it is possible to adopt the distance from the surface of the barrier layer calculated from the relation between the etching rate and the etching time that are adopted in the XPS depth profile measurement as the “distance from the surface of the barrier layer in the film thickness direction of the barrier layer”. Incidentally, the silicon distribution curve, the oxygen distribution curve, the carbon distribution curve, and the oxygen and carbon distribution curve can be created under the following measurement conditions.

(Measurement Conditions)

Etching ion species: argon (Art);

Etching rate (SiO₂ thermal oxide film equivalent value): 0.05 nm/sec;

Etching interval (SiO₂ equivalent value): 10 nm;

X-ray photoelectron spectrometer: model name “VG Theta Probe” manufactured by Thermo Fisher Scientific, Inc.;

Radiated X-ray: single crystal spectrum due to Al Kα and

Spot and size of X-ray: elliptical shape of 800×400 μm.

In the present invention, it is preferable that the barrier layer is substantially uniform in the film surface direction (direction parallel to the surface of the barrier layer) from the viewpoint of forming a barrier layer exhibiting consistent and excellent gas barrier property in the entire film surface. Here, the fact that the barrier layer is substantially uniform in the film surface direction means that the number of extreme values on the carbon distribution curves obtained at the two arbitrary measurement places is the same and the absolute value of the difference between the maximum value and the minimum value of the atomic ratio of carbon in each of the carbon distribution curves is the same as each other or different from each other within 5 at % in the case of creating the oxygen distribution curve, the carbon distribution curve, and the oxygen and carbon distribution curve for two arbitrary measurement places on the film surface of the barrier layer by the XPS depth profile measurement.

Furthermore, in the present invention, it is preferable that the carbon distribution curve is substantially continuous. Here, the fact that the carbon distribution curve is substantially continuous means that the carbon distribution curve does not include the part at which the atomic ratio of carbon discontinuously changes and specifically means that the condition represented by the following Equation 3 is satisfied in the relation between the distance (x, unit: nm) from the surface of the barrier layer in the film thickness direction of at least one layer among the barrier layers calculated from the etching rate and the etching time and the atomic ratio (C, unit:at %) of carbon.

[Mathematical formula 1]

(dC/dx)≦0.5 Equation 3

The gas barrier film according to the present invention may be equipped, for example, with only one layer or two or more layers of the barrier layer which satisfies all of the conditions (i) to (iii) described above. Furthermore, in the case of equipping two or more layers of such a barrier layer, the material nature for the plurality of barrier layers may be the same as or different from one another.

In a case in which the atomic ratio of silicon, the atomic ratio of oxygen, and the atomic ratio of carbon in the silicon distribution curve, the oxygen distribution curve, and the carbon distribution curve satisfy the condition represented by (i) in the region of 90% or more of the film thickness of the barrier layer, the atomic ratio of the content of the silicon atom to the total amount of the silicon atom, the oxygen atom, and the carbon atom in the barrier layer is preferably from 20 to 45 at % and more preferably from 25 to 40 at %. In addition, the atomic ratio of the content of the oxygen atom to the total amount of the silicon atom, the oxygen atom, and the carbon atom in the barrier layer is preferably from 45 to 75 at % and more preferably from 50 to 70 at %. Furthermore, the atomic ratio of the content of the carbon atom to the total amount of the silicon atom, the oxygen atom, and the carbon atom in the barrier layer is preferably from 0 to 25 at % and more preferably from 1 to 20 at %.

In the present invention, the method for forming the barrier layer is not particularly limited, and a method of the prior art may be applied in the same manner or by appropriately qualifying. The barrier layer is formed preferably by a chemical vapor deposition (CVD) method, in particular, a plasma chemical vapor deposition method (plasma CVD, PECVD (plasma-enhanced chemical vapor deposition), hereinafter also simply referred to as the “plasma CVD method”) and more preferably by a plasma CVD method in which the substrate is disposed on a pair of film depositing rollers and a plasma is generated by discharging electricity between the pair of film depositing rollers.

In addition, the disposition of the barrier layer is not particularly limited, but the barrier layer may be disposed on the substrate.

Hereinafter, a method for forming a barrier layer on a substrate utilizing the plasma CVD method that is preferably used in the present invention will be described.

[Method for Forming Barrier Layer Formed by Vapor Phase Film Deposition]

It is preferable to form the barrier layer formed by vapor phase film deposition on the surface of the substrate. It is preferable to adopt a plasma CVD method as the method for forming the barrier layer on the surface of the substrate from the viewpoint of gas barrier property. Incidentally, the plasma CVD method may be a plasma CVD method of the Penning discharge plasma type.

In addition, when generating a plasma in the plasma CVD method, it is preferable to generate a plasma discharge in the space between a plurality of film depositing rollers and it is more preferable to use a pair of film depositing rollers, to dispose the substrate on each of the pair of film depositing rollers, and to generate a plasma by discharging electricity between the pair of film depositing rollers. By using a pair of film depositing rollers, disposing the substrate on the pair of film depositing rollers, and discharging electricity between the pair of film depositing rollers in this manner, not only a thin film can be efficiently produced as it is possible to simultaneously deposit a film on the surface part of the substrate that is present on the other film depositing roller while depositing a film on the surface part of the substrate that is present on one film depositing roller at the time of film deposition but also it is possible to double the film depositing rate as compared to a usual plasma CVD method without using a roller, also it is possible to at least double the extreme values in the carbon distribution curve since it is possible to deposit films having approximately the same structure as one another, and it is possible to efficiently form a layer which satisfies all of the conditions (i) to (iii) described above.

In addition, it is preferable to alternately invert the polarity of the pair of film depositing rollers when discharging electricity between a pair of film depositing rollers in this manner. Furthermore, as a film depositing gas used in such a plasma CVD method, those containing an organic silicon compound and oxygen are preferable, and the content of oxygen in the film depositing gas is preferably less than the theoretical amount of oxygen required to completely oxidize the entire amount of the organic silicon compound in the film depositing gas. In addition, in the gas barrier film of the present invention, it is preferable that the barrier layer is a layer formed by a continuous film depositing process.

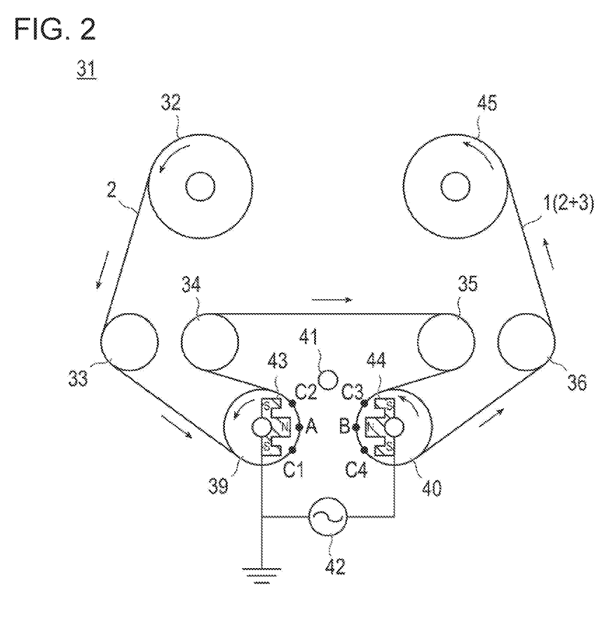

In addition, in the gas barrier film according to the present invention, it is preferable to form the barrier layer on the surface of the substrate by a roll-to-roll method from the viewpoint of productivity. In addition, the apparatus which can be used when producing the barrier layer by such a plasma CVD method is not particularly limited, but it is preferably an apparatus that is equipped with at least a pair of film depositing rollers and a plasma power supply and is configured so as to be capable of discharging electricity between the pair of film depositing rollers, and it is possible to produce the barrier layer by a roll-to-roll method while utilizing a plasma CVD method, for example, in the case of using the producing apparatus illustrated in FIG. 2.

Hereinafter, the method for forming the barrier layer formed by vapor phase film deposition will be described in more detail with reference to FIG. 2. Incidentally, FIG. 2 is a schematic diagram illustrating an example of a producing apparatus that can be suitably utilized for producing a barrier layer. In addition, in the following description and drawings, the same or corresponding elements are denoted by the same reference numerals and overlapping description will be omitted.

A producing apparatus 31 illustrated in FIG. 2 is equipped with a delivery roller 32, conveying rollers 33, 34, 35, and 36, film depositing rollers 39 and 40, a gas supply pipe 41, a power supply for plasma generation 42, magnetic field generators 43 and 44 mounted in the inside of the film depositing rollers 39 and 40, and a winding roller 45. In addition, in such a producing apparatus, at least the film depositing rollers 39 and 40, the gas supply pipe 41, the power supply for plasma generation 42, and the magnetic field generators 43 and 44 are disposed in a vacuum chamber that is not illustrated. Furthermore, in such a producing apparatus 31, the vacuum chamber is connected to a vacuum pump that is not illustrated, and it is possible to appropriately adjust the internal pressure of the vacuum chamber by the vacuum pump.

In such a producing apparatus, in order to allow a pair of film depositing rollers (the film depositing roller 39 and the film depositing roller 40) to function as a pair of counter electrodes, each of the film depositing rollers is connected to the power supply for plasma generation 42. Hence, in such a producing apparatus 31, it is possible to discharge electricity in the space between the film depositing roller 39 and the film depositing roller 40 by supplying the electrical power by the power supply for plasma generation 42 and it is possible to generate a plasma in the space between the film depositing roller 39 and the film depositing roller 40 by virtue of this. Incidentally, as described above, in the case of also utilizing the film depositing roller 39 and the film depositing roller 40 as an electrode, the material nature or design thereof may be appropriately changed so as to be able to utilize them as an electrode. In addition, in such a producing apparatus, it is preferable to dispose the pair of film depositing rollers (film depositing rollers 39 and 40) so that the central axes thereof are approximately parallel to each other on the same plane. By disposing the pair of film depositing rollers (film depositing rollers 39 and 40) in this manner, it is possible to double the film depositing rate and also it is possible to at least double the extreme values in the carbon distribution curve since it is possible to deposit films having the same structure as one another. In addition, according to such a producing apparatus, it is possible to form the barrier layer 3 on the surface of the substrate 2 by the CVD method and further it is also possible to deposit a barrier layer component on the surface of the substrate 2 on the film depositing roller 40 while depositing a barrier layer component on the surface of the substrate 2 on the film depositing roller 39, and thus it is possible to efficiently form a barrier layer on the surface of the substrate 2.

The insides of the film depositing roller 39 and the film depositing roller 40 are respectively provided with magnetic field generators 43 and 44 which are fixed so as not to rotate even though the film depositing rollers rotate.

In the magnetic field generators 43 and 44 that are respectively provided to the film depositing roller 39 and the film depositing roller 40, it is preferable to dispose the magnetic poles so that the lines of magnetic force do not extend over between the magnetic field generator 43 provided to one film depositing roller 39 and the magnetic field generator 44 provided to the other film depositing roller 40 and each of the magnetic field generators 43 and 44 forms an almost closed magnetic circuit. By providing such magnetic field generators 43 and 44, it is possible to promote the formation of the magnetic field bulged with the lines of magnetic force in the vicinity of the surface on the side facing each of the film depositing rollers 39 and 40 and the plasma easily converges on the bulged portion, and thus it is excellent from the viewpoint of being able to improve the film depositing efficiency.

In addition, it is preferable that the magnetic field generators 43 and 44 which are respectively provided to the film depositing roller 39 and the film depositing roller 40 are respectively equipped with a long racetrack-shaped magnetic pole in the roller axis direction and the magnetic poles are disposed so that the magnetic poles facing each other have the same polarity in one magnetic field generator 43 and the other magnetic field generator 44. By providing such magnetic field generators 43 and 44, for each of the magnetic field generators 43 and 44, the lines of magnetic force do not extend over the magnetic field generator on the side of the opposing roller but can easily form the racetrack-shaped magnetic field near the roller surface facing the opposed space (electricity discharge region) along the length direction of the roller shaft and it is possible to converge the plasma on the magnetic field, and thus it is excellent from the viewpoint of being able to efficiently form the barrier layer 3 using the wide substrate 2 wound along the width direction of the roller.

It is possible to appropriately use a known roller as the film depositing roller 39 and the film depositing roller 40. It is preferable to use those having the same diameter as such film depositing rollers 39 and 40 from the viewpoint of more efficiently forming a thin film. In addition, as the diameter of such film depositing rollers 39 and 40, it is preferable that the diameter is in a range of from 300 to 1000 mm φ and particularly in a range of from 300 to 700 mm φ from the viewpoint of the condition for electricity discharge and the space of the chamber and the like. It is preferable that the diameter of the film depositing roller is 300 mm φ or more since the space for plasma discharge does not decrease, thus the productivity does not deteriorate and it is possible to avoid that the entire amount of heat by the plasma discharge is applied to the substrate 2 in a short period of time, and thus it is possible to decrease the damage of the substrate 2. On the other hand, it is preferable that the diameter of the film depositing roller is 1000 mm φ or less since it is possible to maintain the utility related to the design of the apparatus including uniformity of the space for plasma discharge and the like.

In such a producing apparatus 31, the substrate 2 is disposed on a pair of film depositing rollers (film depositing roller 39 and the film depositing roller 40) so that the surfaces of the substrates 2 are opposed to each other. By disposing the substrate 2 in this manner, it is possible to simultaneously deposit a film on the respective surfaces of the substrates 2 present between the pair of film depositing rollers when the plasma is generated by discharging electricity in the opposing space between the film depositing roller 39 and the film depositing roller 40. In other words, according to such a producing apparatus, it is possible to deposit a barrier layer component on the surface of the substrate 2 on the film depositing roller 39 and further to deposit a barrier layer component on the film depositing roller 40 by a plasma CVD method, and thus it is possible to efficiently form a barrier layer on the surface of the substrate 2.

It is possible to appropriately use known rollers as the delivery roller 32 and the conveying rollers 33, 34, 35 and 36 used in such a producing apparatus. In addition, the winding roller 45 may be one that can wind the gas barrier film 1 fabricated by forming the barrier layer 3 on the substrate 2 and is not particularly limited, and it is possible to appropriately use a known roller.

In addition, it is possible to appropriately use those which can supply or discharge the raw material gas or the like at a predetermined rate as the gas supply pipe 41 and the vacuum pump.

In addition, it is preferable to provide the gas supply pipe 41 that is a gas supply means to one side of the opposed space between the film depositing roller 39 and the film depositing roller 40 (electricity discharge region: film depositing zone) and it is preferable to provide the vacuum pump (not illustrated) that is a vacuum pumping means on the other side of the opposed space. By disposing the gas supply pipe 41 that is a gas supply means and the vacuum pump that is a vacuum pumping means in this manner, it is excellent from the viewpoint of being able to efficiently supply the film depositing gas to the opposed space between the film depositing roller 39 and the film depositing roller 40 and to improve the film depositing efficiency.

Furthermore, it is possible to appropriately use the power supply of a known plasma generator as the power supply for plasma generation 42. Such a power supply for plasma generation 42 supplies the electrical power to the film depositing roller 39 and the film depositing roller 40 connected thereto and makes it possible to utilize these as counter electrodes for the electricity discharge. As such a power supply for plasma generation 42, it is preferable to utilize those which can alternately invert the polarity of the pair of film depositing rollers (alternating current power supply and the like) since it is possible to more efficiently carry out plasma CVD. In addition, as such a power supply for plasma generation 42, those which can supply an applied power of from 100 W to 10 kW and a frequency of alternating current of from 50 Hz to 500 kHz is more preferable since it is possible to more efficiently carry out plasma CVD. In addition, it is possible to appropriately use a known magnetic field generator as the magnetic field generators 43 and 44. Furthermore, as the substrate 2, it is possible to use those which are obtained by forming the barrier layer 3 in advance, in addition to the substrate used in the present invention. By using those which are obtained by forming the barrier layer 3 in advance as the substrate 2 in this manner, it is also possible to increase the thickness of the barrier layer 3.

It is possible to produce a barrier layer using such a producing apparatus 31 illustrated in FIG. 2, for example, by appropriately adjusting the kind of the raw material gas, the electrical power of the electrode drum of the plasma generator, the internal pressure of the vacuum chamber, the diameter of the film depositing roller, and the conveying speed of the film (substrate). In other words, by generating the electricity discharge between a pair of film depositing rollers (film depositing rollers 39 and 40) while supplying the film depositing gas (raw material gas and the like) into the vacuum chamber using the producing apparatus 31 illustrated in FIG. 2, the film depositing gas (raw material gas and the like) is decomposed by the plasma and the barrier layer 3 is formed on the surface of the substrate 2 on the film depositing roller 39 and on the surface of the substrate 2 on the film depositing roller 40 by the plasma CVD method. At this time, the racetrack-shaped magnetic field is formed near the roller surface facing the opposed space (electricity discharge region) along the length direction of the roller shaft of the film depositing rollers 39 and 40 and the plasma converges on the magnetic field. Hence, the local maximum value of the carbon distribution curve of a barrier layer is formed when the substrate 2 passes through the position A of the film depositing roller 39 and the position B of the film depositing roller 40 in FIG. 2. On the other hand, the local minimum value of the carbon distribution curve of a barrier layer is formed when the substrate 2 passes through the positions C1 and C2 of the film depositing roller 39 and the positions C3 and C4 of the film depositing roller 40 in FIG. 2. Consequently, usually five extreme values are generated for the two film depositing rollers. In addition, the distance between the extreme values of the barrier layer (the absolute value of the difference between the distances (L) from the surface of the barrier layer in the film thickness direction of the barrier layer in one extreme value and another extreme value adjacent to the one extreme value belonging to the carbon distribution curve) can be adjusted by the rotating speed (conveying speed of the substrate) of the film depositing rollers 39 and 40. Incidentally, upon such film deposition, the barrier layer 3 is formed on the surface of the substrate 2 by a continuous film deposition process of a roll-to-roll method as the substrates 2 are respectively conveyed by the delivery roller 32, the film depositing roller 39, or the like.

As the film depositing gas (raw material gas and the like) supplied to the opposed space through the gas supply pipe 41, it is possible to use a raw material gas, a reactive gas, a carrier gas, and a gas for electricity discharge singly or by mixing two or more kinds thereof. As the raw material gas in the film depositing gas used for forming the barrier layer 3, it is possible to appropriately select one according to the material nature of the barrier layer 3 to be formed and to use it. As such a raw material gas, for example, it is possible to use an organic silicon compound containing silicon or an organic compound gas containing carbon. Examples of such an organic silicon compound may include hexamethyldisiloxane (HMDSO), hexamethyldisilane (HMDS), 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane (TMOS), tetraethoxysilane (TEOS), phenyltrimethoxysilane, methyltriethoxysilane, and octamethylcyclotetrasiloxane. Among these organic silicon compounds, hexamethyldisiloxane and 1,1,3,3-tetramethyldisiloxane are preferable from the viewpoint of handleability of the compound and properties such as gas barrier property of the barrier layer to be obtained. These organic silicon compounds can be used singly or in combination of two or more kinds thereof. In addition, examples of the organic compound gas containing carbon may include methane, ethane, ethylene, and acetylene. These organic silicon compound gases or organic compound gases are appropriately selected as the raw material gas according to the kind of the barrier layer 3.

In addition, as the film depositing gas, a reactive gas may be used in addition to the raw material gas. As such a reactive gas, it is possible to appropriately select a gas which reacts with the raw material gas to form an inorganic compound such as an oxide or a nitride and to use it. In addition, as the reactive gas for forming an oxide, it is possible to use oxygen and ozone, for example. As the reactive gas for forming a nitride, it is possible to use nitrogen and ammonia, for example. These reactive gases can be used singly or in combination of two or more kinds thereof, and it is possible to use a reactive gas for forming an oxide and a reactive gas for forming a nitride in combination, for example, in the case of forming an oxynitride.

As the film depositing gas, a carrier gas may be used in order to supply the raw material gas into the vacuum chamber if necessary. Moreover, as the film depositing gas, a gas for electricity discharge may be used in order to generate plasma discharge if necessary. As such a carrier gas and a gas for electricity discharge, it is possible to appropriately use known gases, and for example, it is possible to use a noble gas such as helium, argon, neon, or xenon; and hydrogen.

In a case in which such a film depositing gas contains a raw material gas and a reactive gas, as the ratio of the reactive gas to the raw material gas, it is preferable that the ratio of the reactive gas is not excessively greater than the ratio of the amount of the reactive gas that is theoretically required in order to completely react the reactive gas and the raw material gas. As the ratio of the reactive gas is not excessive, it is excellent from the viewpoint of being able to obtain excellent barrier property or bending resistance by the barrier layer 3 to be formed. In addition, in a case in which the film depositing gas is one that contains the organic silicon compound and oxygen, it is preferable that the amount of oxygen is equal to or less than the theoretical amount of oxygen required to completely oxidize the entire amount of the organic silicon compound in the film depositing gas.

Hereinafter, the preferred ratio of a reactive gas to a raw material gas in a film depositing gas, and the like will be described in more detail by taking the case of using a gas that contains hexamethyldisiloxane (organic silicon compound, HMDSO, (CH₃)₆Si₂O) as a raw material gas and oxygen (O₂) as a reactive gas as the film depositing gas and producing a silicon-oxygen-based thin film as an example.

In a case in which a silicon-oxygen-based thin film is fabricated by reacting a film depositing gas which contains hexamethyldisiloxane (HMDSO, (CH₃)₆Si₂O) as a raw material gas and oxygen (O₂) as a reactive gas by plasma CVD, a reaction as represented by the following Reaction Formula 1 takes place by the film depositing gas and silicon dioxide is produced.

[Chem. 1]

(CH₃)₆Si₂O+12O₂→6CO₂+9H₂O+2SiO₂ Reaction Formula 1

In such a reaction, the amount of oxygen required to completely oxidize 1 mole of hexamethyldisiloxane is 12 moles. Hence, a uniform silicon dioxide film is formed (there is no carbon distribution curve) in a case in which 12 moles or more of oxygen with respect to 1 mole of hexamethyldisiloxane is contained in the film depositing gas and completely reacted, and thus it is impossible to form a barrier layer that satisfies all of the conditions (i) to (iii) described above. Hence, in the present invention, it is preferable that the amount of oxygen is set to be less than 12 moles of the stoichiometric ratio with respect to 1 mole of hexamethyldisiloxane so that the reaction of the Reaction Formula 1 above does not completely proceed when forming a barrier layer. Incidentally, hexamethyldisiloxane of the raw material and oxygen of the reactive gas are supplied from the gas supply portion to the film depositing region and subjected to the film deposition in the actual reaction in the plasma CVD chamber, and thus it is believed that it is realistically impossible to allow the reaction to completely proceed even if the molar amount (flow rate) of oxygen of the reactive gas is a molar amount (flow rate) to be 12 times the molar amount (flow rate) of hexamethyldisiloxane of the raw material but the reaction is first completed when the content of oxygen is excessively supplied as compared to the stoichiometric ratio (the molar amount (flow rate) of oxygen is set to be approximately equal to or more than 20 times the molar amount (flow rate) of hexamethyldisiloxane of the raw material in some cases, for example, in order to obtain silicon oxide through complete oxidation by CVD). Hence, the molar amount (flow rate) of oxygen with respect to the molar amount (flow rate) of hexamethyldisiloxane of the raw material is preferably equal to or less than an amount to be 12 times as the stoichiometric ratio (more preferably 10 times or less). The carbon atom or the hydrogen atom in hexamethyldisiloxane which has not been completely oxidized is incorporated into the barrier layer as hexamethyldisiloxane and oxygen are contained in such a ratio, and thus it is possible to forma barrier layer that satisfies all of the conditions (i) to (iii) described above and the gas barrier film to be obtained can exert excellent gas barrier property and bending resistance. Incidentally, the lower limit of the molar amount (flow rate) of oxygen with respect to the molar amount (flow rate) of hexamethyldisiloxane in the film depositing gas is preferably set to an amount to be more than 0.1 time the molar amount (flow rate) of hexamethyldisiloxane and more preferably set to an amount to be more than 0.5 time from the viewpoint of utilization of the bas barrier film in a flexible substrate for a device that requires transparency, such as an organic EL device or a solar cell.

In addition, the internal pressure (degree of vacuum) of the vacuum chamber can be appropriately adjusted according to the kind of the raw material gas and the like, but it is preferably set to be in a range of from 0.5 to 50 Pa.

In addition, in such a plasma CVD method, the electrical power applied to the electrode drum (in the present embodiment, it is mounted to the film depositing rollers 39 and 40) connected to the power supply for plasma generation 42 in order to discharge electricity between the film depositing roller 39 and the film depositing roller 40 can be appropriately adjusted according to the kind of the raw material gas, the internal pressure of the vacuum chamber, and the like, thus it cannot be generally said, but it is preferably set to be in a range of from 0.1 to 10 kW. It is possible to sufficiently suppress the generation of particles when such an applied electrical power is 100 W or more. On the other hand, it is possible to suppress the amount of heat generated at the time of film deposition and to suppress an increase in temperature of the surface of the substrate at the time of film deposition when the applied electrical power is 10 kW or less. Hence, it is excellent from the viewpoint that the substrate is not thermally defeated and the generation of wrinkles at the time of film deposition can be prevented.

The conveying speed (line speed) of the substrate 2 can be appropriately adjusted according to the kind of the raw material gas, the internal pressure of the vacuum chamber, and the like, but it is preferably set to be in a range of from 0.25 to 100 m/min and more preferably set to be in a range of from 0.5 to 20 m/min. It is possible to effectively suppress the generation of wrinkles on the substrate due to heat when the line speed is 0.25 m/min or more. On the other hand, it is excellent from the viewpoint of being able to secure a sufficient thickness as a barrier layer without impairing the productivity when the line speed is 100 m/min or less.

As described above, a more preferred aspect of the present embodiment is that the barrier layer according to the present invention is deposited as a film by a plasma CVD method using a plasma CVD apparatus with counter roll electrodes (roll-to-roll method) illustrated in FIG. 2. This is because it is possible to efficiently produce a barrier layer which exhibits excellent plasticity (bending property) and is equipped with both a mechanical strength, in particular durability at the time of being conveyed by roll-to-roll and the barrier performance in a case in which the barrier layer is mass-produced using a plasma CVD apparatus with counter roll electrodes (roll-to-roll method). Such a producing apparatus is also excellent in that a gas barrier film that is used in a solar cell, an electronic component, or the like and is required to be equipped with durability to a change in temperature can be easily mass-produced at low cost.

(Modification Treatment of Barrier Layer Formed by Vapor Phase Film Deposition by Vacuum Ultraviolet Irradiation)

It is preferable that the barrier layer formed by vapor phase film deposition is formed through a modification treatment by vacuum ultraviolet irradiation. As the modification treatment by vacuum ultraviolet irradiation, it is preferable to subject the deposited film to an excimer treatment.

For the excimer treatment (vacuum ultraviolet light treatment), a known method can be used, but a vacuum ultraviolet light treatment that is the same as the modification treatment and the vacuum ultraviolet light irradiation treatment of the barrier layer formed by coating a solution containing a polysilazane compound to be described later is preferable and a vacuum ultraviolet light treatment by the energy of light having a wavelength of from 100 to 180 nm is even more preferable.

In the excimer treatment that is applied to the barrier layer formed by vapor phase film deposition, the concentration of oxygen when the barrier layer is irradiated with vacuum ultraviolet light (VUV) is set to preferably from 300 to 50000 ppm (5%) and even more preferably from 500 to 10000 ppm. By adjusting the concentration of oxygen to be in such a range, it is possible to activate oxygen in the atmosphere and adequately generate ozone or oxygen radicals without significantly impairing the quantity of vacuum ultraviolet light received by the barrier layer formed by the vapor phase film deposition. Incidentally, it is preferable to use a dry inert gas as a gas other than this oxygen at the time of vacuum ultraviolet light (VUV) irradiation, and in particular, a dry nitrogen gas is preferable from the viewpoint of cost. The concentration of oxygen can be adjusted by measuring the flow rate of the oxygen gas and the inert gas to be introduced into the irradiating house and changing the ratio of flow rate.

In a case in which a foreign substance such as an organic substance is present on the surface of the barrier layer formed by vapor phase film deposition, it is concerned that a decrease in gas barrier property is caused or a short circuit of the electrode due to the protrusion of the foreign substance is caused in a case in which the gas barrier film obtained is used in the substrate of an organic EL device and thus a non-light emitting point called the dark spot is frequently generated.

However, by conducting the excimer treatment, the foreign substance is decomposed, oxidized, and removed by the energy of vacuum ultraviolet light and ozone, active oxygen, and the like generated by the energy, thus the defect as a barrier layer is repaired or the coating uniformity of a solution containing a polysilazane compound can be improved as the surface smoothness is enhanced, and as a result, this leads to an improvement in barrier property.

The intensity of illumination and the quantity of irradiation energy of vacuum ultraviolet rays are not particularly limited, but it is possible to preferably use the same ranges as those in the vacuum ultraviolet light irradiation treatment of the barrier layer formed by coating a solution containing a polysilazane compound to be described later, and for example, they are preferably from 10 to 10000 mJ/cm², more preferably from 100 to 8000 mJ/cm², even more preferably from 200 to 6000 mJ/cm², and even more preferably from 500 to 6000 mJ/cm². A sufficient modification efficiency is obtained when they are 10 mJ/cm² or more, and cracking or thermal deformation of the substrate hardly occurs when they are 10000 mJ/cm² or less.

(After-Treatment)

The barrier layer formed by vapor phase film deposition may be subjected to an after-treatment after being deposited as a film or after being subjected to the modification treatment by vacuum ultraviolet rays. Here, the after-treatment can be carried out by the same technique as that in the after-treatment of the barrier layer formed by coating a solution containing a polysilazane compound to be described later.

[Barrier Layer Formed by Coating Solution Containing Polysilazane Compound]

The barrier layer (silicon-containing film) formed by coating a solution containing a polysilazane compound is a film that is formed on one surface of the substrate or formed on the barrier layer formed by vapor phase film deposition and exhibits gas barrier property and is a barrier layer containing at least one element selected from the group consisting of Group 2 elements, Group 13 elements, and Group 14 elements in the long-period periodic table (provided that silicon and carbon are excluded).

Examples of the Group 2 elements, Group 13 elements, and Group 14 elements in the long-period periodic table (additive elements) contained in the barrier layer formed by coating a solution containing a polysilazane compound may include beryllium (Be), boron (B), magnesium (Mg), aluminum (Al), calcium (Ca), gallium (Ga), germanium (Ge), strontium (Sr), indium (In), tin (Sn), barium (Ba), thallium (Tl), lead (Pb), and radium (Ra).

Among these elements, aluminum (Al), indium (In), gallium (Ga), magnesium (Mg), calcium (Ca), germanium (Ge) and boron (B) are preferable, aluminum (Al) or boron (B) is more preferable, and aluminum (Al) is even more preferable. The group 13 elements such as boron (B), aluminum (Al), gallium (Ga), and indium (In) have a valence of three and the valence is insufficient as compared to four of the valence of silicon, and thus the flexibility of the film is enhanced. By this improvement in flexibility, the defect is repaired, the barrier layer becomes a dense film, and thus the gas barrier property is improved. Moreover, as the flexibility is enhanced, oxygen is supplied to the inside of the barrier layer, a barrier layer in which even the inside of the film is oxidized is obtained, and the barrier layer exhibits high oxidation resistance in a state in which the film formation is finished.

Incidentally, the additive element may be present singly or in the form of a mixture of two or more kinds thereof.

The barrier layer formed by coating a solution containing a polysilazane compound preferably has a chemical composition represented by the following Chemical Formula (1) and satisfies the relation of the following Equation (1) and the following Equation (2).

[Chem. 2]

SiOxNyMz (1)

[Mathematical formula 2]

0.001≦Y/(X+Y)≦0.25 Equation (1)

3.30≦3Y+2X≦4.80 Equation (2)

In the Chemical Formula (1), x is the atomic ratio of oxygen to silicon. x is preferably from 1.1 to 3.1, more preferably from 1.2 to 2.7, and most preferably from 1.3 to 2.6.

In the Chemical Formula (1), y is the atomic ratio of nitrogen to silicon. y is preferably from 0.001 to 0.51, more preferably from 0.01 to 0.39, and most preferably from 0.03 to 0.37.

In the Chemical Formula (1), M is at least one element selected from the group consisting of Group 2 elements, Group 13 elements, and Group 14 elements in the long-period periodic table excluding carbon and silicon (additive element). It is believed that the regularity of the film of the barrier layer containing these additive elements decreases, thus the melting point thereof decreases, the film is melted by heat or light during the film forming step, the defect thereof is repaired, the film becomes a denser film, and the gas barrier property thereof is improved. In addition, it is believed that as the fluidity increases by melting, oxygen is supplied to the inside of the barrier layer, a barrier layer is obtained in which even the inside of the film is oxidized, and the barrier layer exhibits high oxidation resistance in a state in which the film formation is finished. In addition, the dangling bond increases as the barrier layer which does not contain the above additive element is irradiated with an energy ray, and perhaps due to this, the absorbance at 250 nm or less increases, the active energy ray is gradually less likely to penetrate to the inside of the barrier layer, and only the surface of the barrier layer is modified. On the other hand, the absorbance on the lower wavelength side decreases as the barrier layer in the gas barrier film of the present invention is irradiated with an active energy ray although the reason is not clear, and thus it is believed from the fact that the modification is conducted from the surface to the inside of the barrier layer and a film which is strong in a high temperature and high humidity environment is obtained. In addition, it is believed that the above additive element has a function as a catalyst in the modification of polysilazane by irradiation of an active energy ray, and it is believed that the modification reaction to be described later more efficiently proceeds as the additive element is added.

In the Chemical Formula (1), z is the atomic ratio of the additive element to silicon, and z is preferably from 0.01 to 0.3. The addition effect hardly exerts when z is less than 0.01. On the other hand, the gas barrier property of the barrier layer formed by coating a solution containing a polysilazane compound decreases and a problem of coloration also occurs depending on the kind of the element when z exceeds 0.3. z is preferably from 0.02 to 0.25 and more preferably from 0.03 to 0.2.

Furthermore, it is preferable that the barrier layer formed by coating a solution containing a polysilazane compound satisfies the relation of the Equation (1) above and the Equation (2) above.

In the Equation (1) above and the Equation (2) above, X=x/(1+(az/4)), Y=y/(1+(az/4)) (provided that a is the valence of the element M).

X and Y in the Equation (1) above and the Equation (2) above represent the ratio of silicon and the oxygen atom and the ratio of the nitrogen atom to the main scaffold, so to speak, regarding silicon and the additive element as the main scaffold. Accordingly, Y/(X+Y) in the Equation (1) above represents the proportion of nitrogen to the total amount of oxygen and nitrogen and affects the oxidative stability, transparency, plasticity, and the like of the barrier layer.

Y/(X+Y) is preferably in a range of from 0.001 to 0.25. The plasticity is high and it is easy to deal with deformation of the substrate when Y/(X+Y) is 0.001 or more, and perhaps due to this, a rapid decrease in barrier property hardly occurs even in a high-temperature and high-humidity environment. On the other hand, the abundance ratio of nitrogen is relatively low when Y/(X+Y) is 0.25 or less, and thus it is possible to suppress that the nitrogen moiety is oxidized at a high temperature and a high humidity and the gas barrier property decreases with time. Y/(X+Y) is preferably from 0.001 to 0.25 and more preferably from 0.02 to 0.20 in order to be more stable in a high temperature and high humidity environment.

In addition, 3Y+2X in the Equation (2) above is preferably in a range of 3.30 or more and 4.80 or less. It indicates that the oxygen atom and the nitrogen atom are not insufficient with respect to the main scaffold when 3Y+2X is 3.30 or more, and it is believed that the proportion of silicon which corresponds to the deficient amount of the oxygen atom or the nitrogen atom and is present as an unstable Si radical is relatively low. Such a Si radical can suppress that the barrier layer reacts with water vapor, and thus it is possible to prevent the barrier layer from changing with time and the wet-heat resistance decreases. On the other hand, the oxygen atom or the nitrogen atom is not excessive when 3Y+2X is 4.80 or less, and thus it is possible to decrease the proportion that a terminal group such as a —OH group or a —NH₂ group is present in the main scaffold composed of silicon and the additive element and intermolecular network is closely continued and thus the gas barrier property becomes favorable. 3Y+2X is preferably from 3.30 to 4.80 and more preferably from 3.32 to 4.40.

Incidentally, a which represents the valence of the additive element in X and Y adopts the valence of the additive element in the compound which contains an additive element (hereinafter, also simply referred to as the additive element compound) that is used in the method for forming the barrier layer formed by coating a solution containing a polysilazane compound to be described later as it is. In a case in which there are a plurality of additive elements, a sum weighted on the basis of the molar ratio of the additive elements is adopted.

The etching rate when the barrier layer having a composition as described above is immersed in a 0.125% by mass aqueous solution of hydrofluoric acid at a temperature of 25° C. is preferably from 0.1 to 40 nm/min and more preferably from 1 to 30 nm/min. A barrier layer that is excellently balanced in gas barrier property and plasticity is obtained when the etching rate is in this range. Incidentally, as the method for measuring the etching rate, the etching rate can be measured by the method described in JP 2009-111029 A, and more specifically, the etching rate can be measured by the method described in Examples to be described later.

The chemical composition represented by the Chemical Formula (1) above and the relation of the Equation (1) above and the Equation (2) above can be controlled by the kind and amount of the polysilazane compound and the additive element compound which are used when forming the barrier layer formed by coating a solution containing a polysilazane compound and the condition when modifying the layer containing the polysilazane compound and the additive element compound. Hereinafter, the method for forming the barrier layer formed by coating a solution containing a polysilazane compound will be described.

[Method for Forming Barrier Layer Formed by Coating Solution Containing Polysilazane Compound]

The barrier layer formed by coating a solution containing a polysilazane compound is formed on the substrate or the barrier layer formed on the substrate by vapor phase film deposition by coating a solution containing a polysilazane compound and an additive element compound.

(Polysilazane Compound)

The “polysilazane compound” used in the present invention is a polymer having a silicon-nitrogen bond in the structure and is a ceramic precursor inorganic polymer such as SiO₂, Si₃N₄, and an intermediate solid solution of both of them SiOₓN_{y} having a bond such as Si—N, Si—H, and N—H.

The polysilazane compound exhibits film depositing property, has fewer defects such as cracks, contains less residual organic substances, exhibits high gas barrier performance, and maintains the barrier performance even at the time of being bent and under a high temperature and high humidity condition.

In order to form a barrier layer from a polysilazane compound so as not to impair the film substrate, a polysilazane compound that is denatured into SiOₓN_{y} at a relatively low temperature as described in JP 8-112879 A is preferable.

As such a polysilazane compound, those which have the following structure can be preferably used.

[Chem. 3]

[Si(R₁)(R₂)—N(R₃)]ₙ— Formula (I)

In the Formula (I) above, R₁, R₂, and R₃ are each independently a hydrogen atom, or an alkyl group, an aryl group, a vinyl group, or a (trialkoxysilyl)alkyl group that is substituted or unsubstituted. At this time, R₁, R₂, and R₃ may be those which are the same as or different from one another. Here, examples of the alkyl group may include a linear, branched, or cyclic alkyl group having from 1 to 8 carbon atoms. More specific examples thereof may include a methyl group, an ethyl group, a n-propyl group, an isopropyl group, a n-butyl group, an isobutyl group, a sec-butyl group, a tert-butyl group, a n-pentyl group, an isopentyl group, a neopentyl group, a n-hexyl group, a n-heptyl group, a n-octyl, a 2-ethylhexyl group, a cyclopropyl group, a cyclopentyl group, and a cyclohexyl group. In addition, examples of the aryl group may include an aryl group having from 6 to 30 carbon atoms. More specific examples thereof may include a non-condensed hydrocarbon group such as a phenyl group, a biphenyl group, or a terphenyl group; and a condensed polycyclic hydrocarbon group such as a pentalenyl group, an indenyl group, a naphthyl group, an azulenyl group, a heptalenyl group, a biphenylenyl group, a fluorenyl group, an acenaphthylenyl group, a pleiadenyl group, an acenaphthenyl group, a phenalenyl group, a phenanthryl group, an anthryl group, a fluoranthenyl group, an acephenanthrylenyl group, an aceanthrylenyl group, a triphenylenyl group, a pyrenyl group, a chrysenyl group, or a naphthacenyl group. Examples of the (trialkoxysilyl)alkyl group may include an alkyl group having from 1 to 8 carbon atoms and having a silyl group substituted with an alkoxy group having from 1 to 8 carbon atoms. More specific examples thereof may include 3-(triethoxysilyl)propyl group and a 3-(trimethoxysilyl)propyl group. The substituent that is optionally present in R₁ to R₃ above is not particularly limited, but example thereof may include an alkyl group, a halogen atom, a hydroxyl group (—OH), a mercapto group (—SH), a cyano group (—CN), a sulfo group (—SO₃H), a carboxyl group (—COOH), and a nitro group (—NO₂). Incidentally, the substituent that is optionally present is not the same as R₁ to R₃ to be substituted. For example, R₁ to R₃ are not further substituted with an alkyl group in a case in which R₁ to R₃ are an alkyl group. Among these, R₁, R₂ and R₃ are preferably a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group, or a 3-(trimethoxysilyl)propyl group.

In addition, in the Formula (I) above, n is an integer, and it is preferably determined so that the polysilazane having the structure represented by the Formula (I) has a number average molecular weight of from 150 to 150,000 g/mol.

A preferred form of the compound having the structure represented by the Formula (I) above is perhydropolysilazane in which R₁, R₂ and R₃ are all a hydrogen atom.

Meanwhile, an organopolysilazane obtained by substituting some of the hydrogen atom moieties that are bonded to Si of the polysilazane with an alkyl group and the like has an advantage that the adhesive property with the substrate of a base is improved as it has an alkyl group such as a methyl group, and it is possible to impart toughness to the hard and brittle ceramic film by a polysilazane and thus cracking is suppressed even in the case of further thickening the (average) film thickness. Hence, it is also possible to appropriately select these perhydropolysilazane and organopolysilazane depending on the application or to use them by mixing together.

It is presumed that perhydropolysilazane has a structure in which a straight-chain structure and a ring structure mainly consisting of 6- and 8-membered rings are present. The molecular weight thereof is about from 600 to 2000 (in terms of polystyrene) as the number average molecular weight (Mn), there is a liquid or solid substance, and the state thereof varies depending on the molecular weight.

Polysilazanes are commercially available in a state of a solution dissolved in an organic solvent, and a commercially available product can be used as a coating liquid for forming a polysilazane layer as it is. Examples of the commercially available product of the polysilazane solution may include AQUAMICA (registered trademark) NN120-10, NN120-20, NAX120-20, NN110, NN310, NN320, NL110A, NL120A, NL120-20, NL150A, NP110, NP140, and SP140 manufactured by AZ Electronic Materials Co.

Although it is not limited to the following ones, other examples of the polysilazane which can be used in the present invention may include a polysilazane that is formed into ceramic at a low temperature such as a silicon alkoxide-added polysilazane that is obtained by reacting a silicon alkoxide with the polysilazane (JP 5-238827 A), a glycidol-added polysilazane obtained by reacting glycidol (JP 6-122852 A), an alcohol-added polysilazane obtained by reacting an alcohol (JP 6-240208 A), a metal carboxylate-added polysilazane obtained by reacting a metal carboxylate (JP 6-299118 A), an acetylacetonate complex-added polysilazane obtained by reacting an acetylacetonate complex containing a metal (JP 6-306329 A), or a fine metal particle-added polysilazane obtained by adding fine metal particles (JP 7-196986 A).

(Additive Element Compound)

The kind of the additive element compound is not particularly limited.

Examples thereof may include anorthoclase, alumina, an aluminosilicate salt, aluminic acid, sodium aluminate, alexandrite, ammonium leucite, yttrium aluminum garnet, yellow feldspar, osarizawaite, omphacite, pyroxene, sericite, gibbsite, sanidine, sapphire, aluminum oxide, aluminum oxide hydroxide, aluminum bromide, aluminum dodecaboride, aluminum nitrate, white mica, aluminum hydroxide, aluminum lithium hydride, sugilite, spinel, diaspore, aluminum arsenide, peacock (pigment), microcline, jadeite, cryolite, hornblende, aluminum fluoride, zeolite, brazilianite, vesuvianite, B alumina solid electrolyte, pezzottaite, sodalite, an organic aluminum compound, spodumene, lithia mica, aluminum sulfate, beryl, chlorite, epidote, aluminum phosphide, and aluminum phosphate as aluminum compounds.

Examples thereof may include zinc-melanterite, magnesium sulfite, magnesiumbenzoate, carnallite, magnesium perchlorate, magnesium peroxide, talc, enstatite, olivine, magnesium acetate, magnesium oxide, serpentinite, magnesium bromide, magnesium nitrate, magnesium hydroxide, spinel, hornblende, augite, magnesium fluoride, magnesium sulfide, magnesium sulfate, and magnesite as magnesium compounds.

Examples thereof may include aragonite, calcium sulfite, calcium benzoate, Egyptian Blue, calcium chloride, calcium chloride hydroxide, calcium chlorate, uvarovite, scheelite, hedenbergite, zoisite, calcium peroxide, superphosphate of lime, calcium cyanamide, calcium hypochlorite, calcium cyanide, calcium bromide, double superphosphate of lime, calcium oxalate, calcium bromate, calcium nitrate, calcium hydroxide, hornblende, augite, calcium fluoride, fluorapatite, calcium iodide, calcium iodate, johannsenite, calcium sulfide, calcium sulfate, actinolite, epidote, epidote, autunite, apatite, and calcium phosphate as calcium compounds.

Examples thereof may include gallium (III) oxide, gallium (III) hydroxide, gallium nitride, gallium arsenide, gallium (III) iodide, and gallium phosphate as gallium compounds.

Examples thereof may include boron oxide, boron tribromide, boron trifluoride, boron triiodide, sodium cyanoborohydride, diborane, boric acid, trimethyl borate, borax, borazine, borane, and boronic acid as boron compounds.

Examples thereof may include an organic germanium compound, an inorganic germanium compound, and germanium oxide as germanium compounds.

Examples thereof may include indium oxide and indium chloride as indium compounds.

However, an alkoxide of an additive element is preferable as the additive element compound from the viewpoint of being able to more efficiently forma high performance barrier layer. Here, the “alkoxide of an additive element” refers to a compound having at least one alkoxy group that is bonded to the additive element. Incidentally, the additive element compound may be used singly or by mixing two or more kinds thereof. In addition, a commercially available product may be used or a synthesized product may be used as the additive element compound.

Examples of the alkoxide of an additive element may include beryllium acetylacetonate, trimethyl borate, triethyl borate, tri-n-propyl borate, triisopropyl borate, tri-n-butyl borate, tri-tert-butyl borate, magnesium ethoxide, magnesium ethoxyethoxide, magnesium methoxyethoxide, magnesium acetylacetonate, aluminum trimethoxide, aluminum triethoxide, aluminum tri-n-propoxide, aluminum tri-isopropoxide, aluminum tri-n-butoxide, aluminum tri-sec-butoxide, aluminum tri-tert-butoxide, aluminum acetylacetonate, acetoalkoxyaluminum diisopropylate, aluminum ethylacetoacetate diisopropylate, aluminum ethylacetoacetate di-n-butyrate, aluminum diethyl acetoacetate mono-n-butyrate, aluminum diisopropylate mono-sec-butyrate, tris(acetylacetonato)aluminum, tris(ethylacetoacetato)aluminum, bis(ethylacetoacetato) (2,4-pentanedionato)aluminum, aluminum alkylacetoacetate diisopropylate, aluminum oxide isopropoxide trimmer, aluminum oxide octylate trimmer, calcium methoxide, calcium ethoxide, calcium isopropoxide, calcium acetylacetonate, strontium acetylacetonate, gallium methoxide, gallium ethoxide, gallium isopropoxide, gallium acetylacetonate, germanium methoxide, germanium ethoxide, germanium isopropoxide, germanium n-butoxide, germanium tert-butoxide, ethyltriethoxy germanium, strontium isopropoxide, tris(2,4-pentanedionato) indium, indium isopropoxide, indium isopropoxide, indium n-butoxide, indium methoxyethoxide, tin n-butoxide, tin tert-butoxide, tin acetylacetonate, barium diisopropoxide, barium tert-butoxide, barium acetylacetonate, thallium ethoxide, thallium acetylacetonate, and lead acetylacetonate. Among these alkoxides of additive elements, triisopropyl borate, magnesium ethoxide, aluminum tri-sec-butoxide, aluminum ethylacetoacetate diisopropylate, calcium isopropoxide, gallium isopropoxide, aluminum diisopropylate mono-sec-butyrate, aluminum ethylacetoacetate di-n-butyrate, and aluminum diethylacetoacetate mono-n-butyrate are preferable.

The method for forming the barrier layer formed by coating a solution containing a polysilazane compound is not particularly limited, and a known method can be applied, but a method is preferable in which a solution containing a polysilazane compound which contains a polysilazane compound, a compound containing an additive element, and if necessary a catalyst in an organic solvent is coated by a known wet coating method, this solvent is removed by evaporation, and subsequently a modification treatment is conducted.

(Solution Containing Polysilazane Compound)

The solvent for preparing a solution containing a polysilazane compound is not particularly limited as long as it can dissolve a polysilazane compound and an additive element compound, but an organic solvent that does not contain water and a reactive group (for example, a hydroxyl group or an amine group) which readily react with the polysilazane compound and is inert to the polysilazane compound is preferable and an aprotic organic solvent is more preferable. Specific examples of the solvent may include an aprotic solvent; for example a hydrocarbon solvent such as an aliphatic hydrocarbon, an alicyclic hydrocarbon, and an aromatic hydrocarbon including pentane, hexane, cyclohexane, toluene, xylene, Solvesso, and turpentine; a halogenated hydrocarbon solvent such as methylene chloride or trichloroethane; an ester such as ethyl acetate or butyl acetate; a ketone such as acetone or methyl ethyl ketone; and an ether such as an aliphatic ether or an alicyclic ether including dibutyl ether, dioxane, and tetrahydrofuran: for example, tetrahydrofuran, dibutyl ether, and mono- and polyalkylene glycol dialkyl ethers (a diglyme). The above solvents are selected according to the purpose such as the solubility of the polysilazane compound and the additive element compound or the evaporation speed of the solvent and may be used singly or in the form of a mixture of two or more kinds thereof.

The concentration of the polysilazane compound in the solution containing a polysilazane compound is not particularly limited and varies depending on the film thickness of the layer or the pot life of the solution, but it is preferably from 0.1 to 30% by mass, more preferably from 0.5 to 20% by mass, and even more preferably from 1 to 15% by mass.

In addition, the concentration of the additive element compound in the solution containing a polysilazane compound is not particularly limited and varies depending on the film thickness of the layer or the pot life of the solution, but it is preferably from 0.01 to 20% by mass, more preferably from 0.1 to 10% by mass, and even more preferably from 0.2 to 5% by mass.

Moreover, the mass ratio of the additive element compound to the polysilazane compound in the solution containing a polysilazane compound is preferably “mass of solid content in polysilazane compound:additive element compound”=1:0.01 to 1:10 and more preferably 1:0.06 to 1:6. It is possible to more efficiently obtain a high performance barrier layer when the mass ratio is in this range.

A catalyst of an amine or a metal may be added to the solution containing a polysilazane compound in order to facilitate the modification. Specific examples thereof may include AQUAMICA NAX120-20, NN110, NN310, NN320, NL110A, NL120A, NL150A, NP110, NP140, and SP140 manufactured by AZ Electronic Materials Co. It is preferable to adjust the amount of the catalyst to be added at this time to 2% by mass or less with respect to the polysilazane compound in order to avoid the excessive formation of silanol by the catalyst, a decrease in film density, an increase of the film defects, and the like.

It is possible to contain an inorganic precursor compound other than the polysilazane compound in the solution containing a polysilazane compound. The inorganic precursor compound other than the polysilazane compound is not particularly limited as long as it makes it possible to prepare a coating liquid.

Specific examples thereof may include polysiloxane, polysilsesquioxane, tetramethylsilane, trimethylmethoxysilane, dimethyldimethoxysilane, methyltrimethoxysilane, trimethylethoxysilane, dimethyldiethoxysilane, methyltriethoxysilane, tetramethoxysilane, tetramethoxysilane, hexamethyldisiloxane, hexamethyldisilazane, 1,1-dimethyl-1-silacyclobutane, trimethylvinylsilane, methoxydimethylvinylsilane, trimethoxyvinylsilane, ethyltrimethoxysilane, dimethyldivinylsilane, dimethylethoxyethynylsilane, diacetoxydimethylsilane, dimethoxymethyl-3,3,3-trifluoropropylsilane, 3,3,3-trifluoropropyltrimethoxysilane, aryltrimethoxysilane, ethoxydimethylvinylsilane, arylaminotrimethoxysilane, N-methyl-N-trimethylsilylacetamide, 3-aminopropyltrimethoxysilane, methyltrivinylsilane, diacetoxymethylvinylsilane, methyltriacetoxysilane, aryloxydimethylvinylsilane, diethylvinylsilane, butyltrimethoxysilane, 3-aminopropyldimethylethoxysilane, tetravinylsilane, triacetoxyvinylsilane, tetraacetoxysilane, 3-trifluoroacetoxypropyltrimethoxysilane, diaryldimethoxysilane, butyldimethoxyvinylsilane, trimethyl-3-vinyl-thiopropylsilane, phenyltrimethylsilane, dimethoxymethylphenylsilane, phenyltrimethoxysilane, 3-acryloxypropyldimethoxymethylsilane, 3-acryloxypropyltrimethoxysilane, dimethylisopentyloxyvinylsilane, 2-aryloxyethylthiomethoxytrimethylsilane, 3-glycidoxypropyltrimethoxysilane, 3-arylaminopropyltrimethoxysilane, hexyltrimethoxysilane, heptadecafluorodecyltrimethoxysilane, dimethylethoxyphenylsilane, benzoyloxytrimethylsilane, 3-methacryloxypropyldimethoxymethylsilane, 3-methacryloxypropyltrimethoxysilane, 3-isocyanatepropyltriethoxysilane, dimethylethoxy-3-glycidoxypropylsilane, dibutoxydimethylsilane, 3-butylaminopropyltrimethylsilane, 3-dimethylaminopropyldiethoxymethylsilane, 2-(2-aminoethylthioethyl)triethoxysilane, bis(butylamino)dimethylsilane, di-vinylmethylphenylsilane, diacetoxymethylphenylsilane, dimethyl-p-tolylvinylsilane, p-styryltrimethoxysilane, diethylmethylphenylsilane, benzyldimethylethoxysilane, diethoxymethylphenylsilane, decylmethyldimethoxysilane, diethoxy-3-glycidoxypropylmethylsilane, octyloxytrimethylsilane, phenyltrivinylsilane, tetraaryloxysilane, dodecyltrimethylsilane, diarylmethylphenylsilane, diphenylmethylvinylsilane, diphenylethoxymethylsilane, diacetoxydiphenylsilane, dibenzyldimethylsilane, diaryldiphenylsilane, octadecyl trimethylsilane, methyloctadecyldimethylsilane, dococylmethyldimethylsilane, 1,3-divinyl-1,1,3,3-tetramethyldisiloxane, 1,3-divinyl-1,1,3,3-tetramethyldisilazane, 1,4-bis(dimethylvinylsilyl)benzene, 1,3-bis(3-acetoxypropyl)tetramethyldisiloxane, 1,3,5-trimethyl-1,3,5-trivinylcyclotrisiloxane, 1,3,5-tris(3,3,3-trifluoropropyl)-1,3,5-trimethylcyclotr isiloxane, octamethylcyclotetrasiloxane, 1,3,5,7-tetraethoxy-1,3,5,7-tetramethylcyclotetrasiloxan e, and decamethylcyclopentasiloxane as compounds containing silicon.

As the polysiloxane, those which have highly reactive Si—H are preferable and methyl hydrogen polysiloxane is preferable. Examples of methyl hydrogen polysiloxane may include TSF484 manufactured by Momentive Performance Materials Inc.

As the polysilsesquioxane, it is possible to preferably use those which have any of a cage-shaped structure, a ladder-shaped structure, and a random structure. Examples of the cage-shaped polysilsesquioxane may include octakis(tetramethylammonium)pentacyclo-octasiloxane-octakis(yloxide)hydrate; octa(tetramethylammonium)silsesquioxane, octakis(dimethylsiloxy)octasilsesquioxane, octa[[3-[(3-ethyl-3-oxetanyl)methoxy]propyl]dimethylsiloxy]octasilsesquioxane; octaallyloxetanesilsesquioxane, octa[(3-propylglycidylether)dimethylsiloxy]silsesquioxane; octakis[[3-(2,3-epoxypropoxy)propyl]dimethylsiloxy]octasilsesquioxane, octakis[[2-(3,4-epoxycyclohexyl)ethyl]dimethylsiloxy]octasilsesquioxane, octakis[2-(vinyl)dimethylsiloxy]silsesquioxane; octakis(dimethylvinylsiloxy)octasilsesquioxane, octakis[(3-hydroxypropyl)dimethylsiloxy]octasilsesquioxane, octa[(methacryloylpropyl)dimethylsilyloxy]silsesquioxane, and octakis[(3-methacryloxypropyl)dimethylsiloxy]octasilsesquioxane of the Q8 series manufactured by Mayaterials Inc. Examples of the polysilsesquioxane in which a cage-shaped structure, a ladder-shaped structure, and a random structure are believed to be present in a mixed state may include SR-20, SR-21, and SR-23 of polyphenylsilsesquioxane, SR-13 of polymethylsilsesquioxane, and SR-33 of polymethylphenylsilsesquioxane manufactured by KONISHI CHEMICAL IND CO., LTD. In addition, it is also possible to preferably use Fox series that is manufactured by Dow Corning Toray Co., Ltd., is a polyhydrogensilsesquioxane solution, and is a commercially available as a spin-on-glass material.

Among the compounds mentioned above, an inorganic silicon compound that is solid at room temperature is preferable and a hydrogenated silsesquioxane is more preferably used.

It is possible to use the additives to be mentioned below in the solution containing a polysilazane compound if necessary. The additives are, for example, a cellulose ether and a cellulose ester; for example, ethyl cellulose, nitrocellulose, cellulose acetate, and cellulose acetobutyrate, and a natural resin; for example, rubber or a rosin resin, a synthetic resin; for example, a polymerization resin, a condensation resin; for example, aminoplast, in particular, a urea resin, a melamine-formaldehyde resin, an alkyd resin, an acrylic resin, a polyester or a modified polyester, an epoxide, a polyisocyanate or a blocked polyisocyanate, and a polysiloxane.

(Method for Coating Solution Containing Polysilazane Compound)

As the method for coating a solution containing a polysilazane compound, a proper wet coating method known in the prior art can be adopted. Specific examples thereof may include a spin coating method, a roll coating method, a flow coating method, an inkjet method, a spray coating method, a printing method, a dip coating method, a casting deposition method, a bar coating method, and a gravure printing method.

The coating thickness is 0.1 nm or more and less than 150 nm as the thickness after drying. It is difficult to obtain sufficient gas barrier property in a case in which the coating thickness is less than 0.1 nm, and it is difficult to obtain sufficient flexibility and crack in the film easily occurs in a case in which the coating thickness is 150 nm or more. The coating thickness is preferably from 1 to 100 nm, more preferably from 2 to 80 nm, and even more preferably from 5 to 60 nm.

It is preferable to dry the coating film after coating a solution containing a polysilazane compound. It is possible to remove the organic solvent contained in the coating film by drying the coating film. At this time, the organic solvent contained in the coating film may be completely dried, but a part thereof may be left. A suitable barrier layer can be obtained even in the case of leaving a part of the organic solvent. Incidentally, the residual solvent can be removed later.

The temperature for drying the coating film varies depending on the substrate to be applied, but it is preferably from 50 to 200° C. For example, in the case of using a polyethylene terephthalate substrate having a glass transition temperature (Tg) of 70° C. as the substrate, it is preferable to set the drying temperature to 150° C. or lower in consideration of the deformation of the substrate by heat, and the like. The above temperature can be set by using a hot plate, an oven, a furnace, and the like. It is preferable to set the drying time to be a short period of time, and for example, it is preferable to set it to be within 30 minutes in a case in which the drying temperature is 150° C. In addition, the drying atmosphere may be any condition of an air atmosphere, a nitrogen atmosphere, an argon atmosphere, a vacuum atmosphere, a reduced pressure atmosphere having a controlled concentration of oxygen.

(Modification Treatment)

In the present invention, it is preferable that the barrier layer formed by coating a solution containing a polysilazane compound is subjected to a modification treatment. The modification treatment in the present invention refers to a reaction by which a part or whole of the polysilazane compound is converted into silicon oxide or silicon oxynitride.

This makes it possible to form an inorganic thin film to be in the level capable of contributing to the exertion of gas barrier property (water vapor transmission rate is 1×10⁻³ g/m²·day or less) by the gas barrier film of the present invention as a whole.

Specific examples of the modification treatment may include a heat treatment, a plasma treatment, and an active energy ray irradiation treatment. Among them, a treatment by active energy ray irradiation is preferable from the viewpoint of being able to modify at a low temperature and a high degree of freedom in selection of the kind of substrate.

(Heat Treatment)

Examples of the method for the heat treatment may include a method in which the substrate is brought into contact with a heat-generating body such as a heat block and the coating film is heated by heat conduction, a method in which the environment in which the coating film is placed is heated by an external heater by a resistance wire or the like, and a method using light in the infrared region such as an IR heater, but the method is not limited thereto. A method which can maintain the smoothness of the coating film may be appropriately selected in the case of conducting the heat treatment.

The temperature for heating the coating film is preferably in the range of from 40 to 250° C. and more preferably in the range of from 60 to 150° C. The heating time is preferably in the range of from 10 seconds to 100 hours and preferably in the range of from 30 seconds to 5 minutes.

(Plasma Treatment)

In the present invention, a known method can be used as the plasma treatment which can be used as the modification treatment, but preferred examples thereof may include an atmospheric pressure plasma treatment. The atmospheric pressure plasma CVD method to conduct a plasma CVD treatment at near atmospheric pressure has not only higher productivity since the pressure is not required to be reduced but also a faster film deposition rate due to a high plasma density as compared to a plasma CVD method in a vacuum, and further the mean free path of the gas is significantly shorter under a condition of a high pressure of the atmospheric pressure as compared to the condition of a usual CVD method, and thus a significantly homogeneous film is obtained.

In the case of the atmospheric pressure plasma treatment, as a discharge gas, a nitrogen gas or a Group 18 atom in the long-periodperiodictable, specifically, helium, neon, argon, krypton, xenon, radon, or the like is used. Among these, nitrogen, helium and argon are preferably used, and in particular, nitrogen is inexpensive and thus preferable.

(Active Energy Ray Irradiation Treatment)

It is possible to use infrared rays, visible light, ultraviolet rays, X-rays, electron beams, α-ray, β-ray, γ-ray, and the like as the active energy ray, but electron beams or ultraviolet rays are preferable and ultraviolet rays are more preferable. Ozone or an active oxygen atom generated by ultraviolet rays (synonymous with ultraviolet light) exhibits high oxidizing ability, and thus it is possible to form a silicon-containing film (barrier layer) which exhibits high denseness and insulating property at a low temperature.

In the ultraviolet ray irradiation treatment, it is also possible to use any one of the ultraviolet ray generators that are usually used.

In the method for producing a gas barrier film according to the present invention, the coating film which contains a polysilazane compound and from which the moisture is removed is modified through a treatment by ultraviolet light irradiation. Ozone or an active oxygen atom generated by ultraviolet rays (synonymous with ultraviolet light) exhibits high oxidizing ability, and thus it is possible to form a silicon oxide film or a silicon oxynitride film which exhibits high denseness and insulating property at a low temperature.

By this ultraviolet light irradiation, O₂ and H₂O contributing to the formation of ceramic or an ultraviolet absorber and a polysilazane itself are excited and activated. Thereafter, the excited polysilazane is promoted to form ceramic, and thus the ceramic film to be obtained becomes dense. The ultraviolet light irradiation is effective even though it is carried out at any time point as long as it is carried out after the formation of coating film.

It is possible to use any one of the ultraviolet ray generators which are commonly used in the vacuum ultraviolet light irradiation treatment of the present invention. Incidentally, the ultraviolet light used in the present invention generally refers to ultraviolet light including an electromagnetic wave having a wavelength of from 10 to 200 nm called vacuum ultraviolet light.

Upon irradiation of vacuum ultraviolet light, it is preferable to set the irradiation intensity and irradiation time in the range in which the substrate supporting the layer that contains a polysilazane compound before being modified to be irradiated is not damaged.

When the case of using a plastic film as the substrate is taken as an example, it is possible to set the distance between the substrate and the ultraviolet ray irradiating lamp so that the intensity on the substrate surface becomes from 20 to 300 mW/cm² and preferably from 50 to 200 mW/cm² and to conduct irradiation for from 0.1 second to 10 minutes using a lamp of 2 kW (80 W/cm×25 cm), for example.

Examples of such an ultraviolet ray generating means may include a metal halide lamp, a high pressure mercury lamp, a low pressure mercury lamp, a xenon arc lamp, a carbon arc lamp, an excimer lamp, and a UV light laser, but the ultraviolet ray generating means is not particularly limited. In addition, when irradiating the polysilazane layer before being modified with the generated ultraviolet rays, it is desirable that the ultraviolet rays from the generating source hit the polysilazane layer before being modified after being reflected from the reflective plate from the viewpoint of improving the efficiency and achieving uniform irradiation.

The ultraviolet ray irradiation is adaptable to a batch treatment or a continuous treatment, and thus the type of treatment can be appropriately selected depending on the shape of the substrate to be used. In a case in which the substrate having a coating layer containing a polysilazane compound has a long film shape, it is possible to form the polysilazane compound into ceramic by continuously irradiating the coating layer with ultraviolet rays in the drying zone equipped with an ultraviolet ray generating source as described above while conveying the coating layer. The time required for ultraviolet ray irradiation is generally from 0.1 second to 10 minutes and preferably from 0.5 seconds to 3 minutes although it is also dependent on the substrate to be used or the composition and concentration of the coating layer containing a polysilazane compound.

(Vacuum Ultraviolet Irradiation Treatment: Excimer Irradiation Treatment)

In the present invention, the most preferred method for the modification treatment is a treatment by vacuum ultraviolet irradiation (excimer irradiation treatment).

It is preferable to use a dry inert gas as a gas other than this oxygen at the time of vacuum ultraviolet light (VUV) irradiation, and the gas is preferably a dry nitrogen gas particularly from the viewpoint of cost. The concentration of oxygen can be adjusted by measuring the flow rate of the oxygen gas and the inert gas to be introduced into the irradiating house and changing the ratio of flow rate.

Specifically, the method for the modification treatment of the layer containing a polysilazane compound before being modified in the present invention is a treatment by vacuum ultraviolet light irradiation. The treatment by vacuum ultraviolet light irradiation is a method to conduct the formation of silicon oxide film at a relatively low temperature by allowing an oxidation reaction by active oxygen or ozone to proceed while directly breaking the bond between atoms by the action only of photons called photon process using the energy of light of from 100 to 200 nm that is larger than the interatomic bonding force in the polysilazane compound and preferably using the energy of light having a wavelength of from 100 to 180 nm. As the vacuum ultraviolet light source required for this, a noble gas excimer lamp is preferably used.

As the characteristics of the excimer lamp, it is mentioned that radiation is focused on one wavelength, light other than the required light is hardly radiated, and thus the efficiency is high. In addition, it is possible to maintain the temperature of the target low since extra light is not radiated. Moreover, instantaneous turning on and off is possible since it does not require the time for start and restart.

In the vacuum ultraviolet irradiation step in the present invention, the intensity of illumination by vacuum ultraviolet rays on the coated surface received by the coating film containing a polysilazane compound is preferably from 1 mW/cm² to 10 W/cm², more preferably from 30 to 200 mW/cm², and even more preferably from 50 to 160 mW/cm². A sufficient modification efficiency can be obtained when it is 1 mW/cm² or more. In addition, ablation of the coating film hardly occurs and the substrate is hardly damaged when it is 10 W/cm² or less.

The energy quantity irradiated on the coated surface containing a polysilazane compound with vacuum ultraviolet rays is preferably from 10 to 10000 mJ/cm², more preferably from 100 to 8000 mJ/cm², even more preferably from 200 to 6000 mJ/cm², and particularly preferably from 500 to 6000 mJ/cm². A sufficient modification efficiency can be obtained when it is 10 mJ/cm² or more, and cracking or thermal deformation of the substrate hardly occurs when it is 10000 mJ/cm² or less.

In addition, it is preferable to set the concentration of oxygen when irradiating with vacuum ultraviolet light (VUV) to from 300 to 10000 ppm by volume (1% by volume), and the concentration of oxygen is more preferably from 500 to 5000 ppm by volume. It is possible to prevent the formation of a barrier layer with excess oxygen and the deterioration of barrier property by adjusting the concentration of oxygen to be in such a range.

The Xe excimer lamp has excellent light emission efficiency since it radiates ultraviolet ray having a short wavelength of 172 nm as a single wavelength. This light has a high absorption coefficient of oxygen and thus can generate a radical oxygen atomic species or ozone at a high concentration with a trace amount of oxygen. In addition, it is known that the energy of light which has a short wavelength of 172 nm and thus dissociates the bonding of an organic substance exhibits high ability. It is possible to realize the modification of the coating layer containing a polysilazane compound in a short period of time by this active oxygen or ozone and the high energy due to ultraviolet radiation. Accordingly, it is possible to shorten the process time associated with high throughput or to decrease the area for the equipment as compared to a low pressure mercury lamp which emits a wavelength of 185 nm and 254 nm or plasma cleaning and to irradiate an organic material or a plastic substrate, a resin film, and the like which are easily damaged by heat.

The layer formed by coating described above is formed as a barrier layer containing silicon oxynitride represented by the composition of SiOₓN_{y}M_{z} as a whole layer as at least a part of the polysilazane is modified in the step of irradiating the coating film containing a polysilazane compound with vacuum ultraviolet rays.

Incidentally, the composition of the film can be determined by measuring the atomic composition ratio using an XPS surface analyzer. In addition, it is also possible to determine the composition of the film by cutting the barrier layer formed by coating a solution containing a polysilazane compound and measuring the atomic composition ratio of the cut surface using an XPS surface analyzer.

In addition, the film density can be appropriately set depending on the purpose. For example, the film density of the barrier layer formed by coating a solution containing a polysilazane compound is preferably in the range of from 1.5 to 2.6 g/cm³. The denseness of the film is improved when the film density is within this range, and thus it is possible to prevent deterioration in gas barrier property or deterioration of the film under a high temperature and high humidity condition.

(After-Treatment)

It is preferable that the barrier layer formed by coating a solution containing a polysilazane compound is subjected to an after-treatment after being coated or after being subjected to the modification treatment and particularly after being subjected to the modification treatment. The after-treatment described herein also includes temperature treatment (heat treatment) at a temperature of from 40 to 120° C. or a humidity treatment at a humidity of 30% or more and 100% or less or of being immersed in a water bath, and the treatment time is defined as a range selected from the range of from 30 seconds to 100 hours. The barrier layer may be subjected to both the temperature treatment and the humidity treatment or may be subjected only to either one, but it is preferable to subject the barrier layer at least to the temperature treatment (heat treatment). The preferred condition is that the temperature is from 40 to 120° C., the humidity is from 30% to 85%, and the treatment time is from 30 seconds to 100 hours.

When conducting the temperature treatment, the method is not particularly limited, and a contact type method to place the barrier layer on a hot plate, a non-contact type method to hang the barrier layer in an oven and to leave to stand, and the like may be used concurrently or singly.

Incidentally, only one layer of the barrier layer formed by coating a solution containing a polysilazane compound may be formed or two or more layers thereof may be stacked. In addition, the barrier layer may be used in combination with a coating layer which contains a polysilazane compound but does not contain an additive element. The coating layer which contains a polysilazane compound but does not contain an additive element can be formed by the same method as that for forming the barrier layer formed by coating a solution containing a polysilazane compound described above except that an additive element compound is not used. At this time, each of the barrier layer formed by coating a solution containing a polysilazane compound and the coating layer not containing an additive element may be or may not be subjected to the modification treatment, but it is preferable that they are subjected to the modification treatment. The gas barrier property can be further improved by providing a plurality of coating layers in this manner. Preferably, the barrier layer formed by vapor phase film deposition is formed on a substrate, and subsequently, two or more, for example two or three barrier layers formed by coating a solution containing a polysilazane compound and contains an additive element are stacked thereon. A gas barrier film which exhibits superior gas barrier property and more hardly fluctuates in performance such as gas barrier property even at a high temperature and a high humidity can be obtained by containing two or more barrier layers formed by coating a solution containing a polysilazane compound on the barrier layer formed by vapor phase film deposition of an inorganic compound.

(Intermediate Layer)

In the present invention, in a case in which two or more barrier layers are stacked, an intermediate layer may be formed between the respective barrier layers or between the barrier layer and the substrate.

In the present invention, as the method for forming the intermediate layer, it is possible to apply a method for forming a polysiloxane-modified layer. This method is a method for forming an intermediate layer by coating a coating liquid containing a polysiloxane on the barrier layer by a wet coating method, drying it, and then irradiating the dried coating film with vacuum ultraviolet light to form a polysiloxane-modified layer.

The coating liquid used for forming the intermediate layer in the present invention mainly contains a polysiloxane and an organic solvent.

As specific forms of the constituent material, forming method, and the like of the intermediate layer, for example, the material, the method, and the like disclosed in the paragraphs “0161” to “0185” in JP 2014-046272 A can be appropriately adopted.

Incidentally, the intermediate layer covers the barrier layer and has a function to prevent the barrier layer in the gas barrier film from being damaged, but the intermediate layer can also prevent the barrier layer from being damaged in the producing process of the gas barrier film.

(Protective Layer)

In the gas barrier film according to the present invention, a protective layer containing an organic compound may be provided on top of the barrier layer formed by coating or the barrier layer formed by vapor phase film deposition of an inorganic compound. As the organic compound used in the protective layer, an organic resin of an organic monomer, an oligomer, a polymer and the like, and an organic and inorganic composite resin layer using a monomer, an oligomer, a polymer, and the like of a siloxane or a silsesquioxane having an organic group can be preferably used.

It is preferable to form the protective layer by blending the organic resin or the inorganic material, and if necessary, other components together, appropriately diluting the mixture with a diluting solvent to be used if necessary to prepare a coating liquid, coating the coating liquid on the surface of the substrate by a coating method known in the prior art, and then irradiating the coating film with ionizing radiation to cure it. Incidentally, as the method for irradiating the coating film with ionizing radiation, the coating film is irradiated with ultraviolet rays in a wavelength region of from 100 to 400 nm, preferably from 200 to 400 nm emitted from an ultra-high pressure mercury lamp, a high pressure mercury lamp, a low pressure mercury lamp, a carbon arc, a metal halide lamp, or the like. Alternatively, the curing can be conducted by irradiating the coating film with an electron beam in a wavelength region of 100 nm or less emitted from an electron beam accelerator of a scanning type or a curtain type.

In addition, the protective layer can also be cured through irradiation using the excimer lamp described above. It is preferable that curing of the protective layer is also conducted through irradiation using an excimer lamp in the case of coating and forming the barrier layer and the protective layer in the same line.

In addition, in a case in which an alkoxy-modified polysiloxane coating film is deposited on the coating film obtained from the coating liquid before the barrier layer formed by coating a solution containing a polysilazane compound is subjected to the modification treatment and then irradiated with vacuum ultraviolet light from above, the alkoxy-modified polysiloxane coating film serves as a protective layer, further the modification of the polysilazane coating film of the lower layer can also be conducted, and thus it is possible to obtain a barrier layer exhibiting superior storage stability at a high temperature and a high humidity.

In addition, as the protective layer, it is possible to apply the method for forming the polysiloxane-modified layer of the intermediate layer.

[Desiccant Layer]

The gas barrier film of the present invention may include a desiccant layer (moisture adsorbing layer). Examples of the material used as the desiccant layer may include calcium oxide or an organic metal oxide. As calcium oxide, those that are dispersed in a binder resin and the like are preferable, and as a commercially available product, for example, AqvaDry series manufactured by SAES Getters can be preferably used. In addition, as the organic metal oxide, for example, OleDry (registered trademark) series manufactured by Futaba Corporation and the like can be used.

[Smoothing Layer (Base Layer, Primer Layer)]

The gas barrier film of the present invention may include a smoothing layer (base layer, primer layer) on the surface having a barrier layer of the substrate, and preferably between the substrate and the first barrier layer. The smoothing layer is provided in order to flatten the rough surface of the substrate having protrusions and the like or to fill and flatten the concave and convex or pinholes generated on the barrier layer by the protrusions present on the substrate.

As the constituent material, forming method, surface roughness, film thickness, and the like of the smoothing layer, the material, the method, and the like disclosed in the paragraphs “0233” to “0248” of JP 2013-52561 A are appropriately adopted.

[Anchor Coat Layer]

An anchor coat layer may be formed on the surface of the substrate as an adhesion promoting layer for the purpose of improving adhesiveness (adhesive property). As the anchor coating agent used in this anchor coat layer, it is possible to use a polyester resin, an isocyanate resin, a urethane resin, an acrylic resin, an ethylene and vinyl alcohol resin, a vinyl-modified resin, an epoxy resin, a modified styrene resin, a modified silicone resin, an alkyl titanate, and the like singly, or two or more kinds thereof can be used concurrently. As the anchor coating agent, a commercially available product may be used. Specifically, a siloxane-based UV-curable polymer solution (3% isopropyl alcohol solution of “X-12-2400” manufactured by Shin-Etsu Chemical Co., Ltd.) can be used.

It is possible to add an additive known in the prior art to these anchor coating agents. In addition, the above anchor coating agent can be coated by coating it on the substrate by a known method such as roll coating, gravure coating, knife coating, dip coating, or spray coating and then removing the solvent, the diluent, and the like through drying. The coating amount of the above anchor coating agent is preferably about from 0.1 to 5 g/m² (dried state). Incidentally, a commercially available substrate with adhesion promoting layer may be used.

Alternatively, the anchor coat layer can also be formed by a vapor phase method such as a physical deposition method or a chemical deposition method. For example, it is also possible to form an inorganic film containing silicon oxide as the main component for the purpose of improving adhesiveness and the like as described in JP 2008-142941 A.

In addition, the thickness of the anchor coat layer is not particularly limited, but it is preferably about from 0.5 to 10.0 p.m.

[Bleed-Out Preventing Layer]

The gas barrier film of the present invention may include a bleed-out preventing layer on the substrate surface on the side opposite to the surface provided with the barrier layer.

The bleed-out preventing layer is provided for the purpose of suppressing a phenomenon that the unreacted oligomer and the like migrate from the inside of the film to the surface when heating the film and contaminate the surface that comes in contact with them. The bleed-out preventing layer may basically have the same configuration as the smoothing layer as long as it has this function.

As the constituent material, forming method, film thickness, and the like of the bleed-out preventing layer, the material, the method, and the like disclosed in the paragraphs “0249” to “0262” of JP 2013-52561 A are appropriately adopted.

<<Packing State of Gas Barrier Film>>

The gas barrier film of the present invention can be continuously produced and wound into a roll form (so-called roll-to-roll production). At that time, it is preferable to paste a protective sheet on the surface on which the barrier layer is formed and to wind it. In particular, in the case of using the gas barrier film of the present invention as a sealing material for an organic thin film device, a defect is caused by the dust (for example, particles) attached to the surface in many cases, and thus it is significantly effective to prevent the attachment of dust by pasting a protective sheet at a place having a high degree of cleanliness. In addition, it is effective to prevent the barrier layer surface from being scratched at the time of winding.

The protective sheet is not particularly limited, but it is possible to use a general “protective sheet” or “release sheet” having a configuration that an adhesive layer exhibiting weak pressure-sensitive adhesive property is imparted to a resin substrate having a film thickness of about 100 μm.

<<Water Vapor Transmission Rate of Gas Barrier Film>>

It is more preferable as the water vapor transmission rate of the gas barrier film of the present invention is lower, but for example, the water vapor transmission rate is preferably 0.001 to 0.00001 g/m²·24 hours and more preferably 0.0001 to 0.00001 g/m²·24 hours.

In the present invention, the measurement was conducted using the following Ca method as the method for measuring the water vapor transmission rate.

<Ca Method Used in the Present Invention>

Deposition apparatus: vacuum deposition apparatus JEE-400 manufactured by JEOL Ltd.

Constant temperature and humidity oven: Yamato Humidic ChamberIG47M

Metal corroded by reaction with water: Calcium (granular)

Water vapor impermeable metal: aluminum (φ3 to 5 mm, granular)

Fabrication of cell for water vapor barrier property evaluation

On the barrier layer surface of the barrier film sample, where other than the part (9 places of 12 mm×12 mm) desired to be deposited of the barrier film sample before being attached with a transparent conductive film was masked, metallic calcium was deposited using a vacuum deposition apparatus (vacuum deposition apparatus JEE-400 manufactured by JEOL Ltd.). Thereafter, the mask was removed therefrom as it was in the vacuum state, and aluminum was deposited on the entire surface of one side of the sheet from another metal deposition source. After aluminum sealing, the vacuum state was released, and immediately the aluminum sealed side of the barrier film sample was faced quartz glass having a thickness of 0.2 mm via an ultraviolet curable resin for sealing (manufactured by Nagase ChemteX Corporation) in a dry nitrogen gas atmosphere and irradiated with ultraviolet rays, thereby fabricating a cell for evaluation. In addition, as presented in Examples to be described later, the same cells for water vapor barrier property evaluation were fabricated for the gas barrier film that was subjected to the bending treatment and the gas barrier film that was not subjected to the bending treatment in order to confirm a change in gas barrier property before and after bending.

The sample that was thus obtained and had both surfaces sealed was stored at a high temperature and a high humidity of 60° C. and 90% RH, and the amount of moisture that had transmitted into the cell was calculated from the quantity of corrosion of metallic calcium on the basis of the method described in JP 2005-283561 A.

Incidentally, in order to confirm that the water vapor does not transmit through the cell other than from the barrier film surface, a sample fabricated by depositing metallic calcium on a quartz glass plate having a thickness of 0.2 mm was stored under the same condition of a high temperature and a high humidity of 60° C. and 90% RH as a comparative sample instead of the barrier film sample and it was confirmed that the corrosion of metallic calcium did not proceed even after 1000 hours elapsed.

<Electronic Device>

The gas barrier film of the present invention can be preferably used in a device of which the performance is deteriorated by the chemical components (oxygen, water, nitrogen oxides, sulfur oxides, ozone, and the like) in the air. Examples of the device may include an electronic device such as an organic EL device, a liquid crystal display device (LCD), a thin film transistor, a touch panel, electronic paper, or a photovoltaic (PV) cell. The gas barrier film of the present invention is used preferably in an organic EL device or a photovoltaic cell and particularly preferably in an organic EL device from the viewpoint of more efficiently obtaining the effect of the present invention.

The gas barrier film of the present invention can also be used to film-seal of a device. In other words, the surface of a device which itself serves as a support is provided with the gas barrier film of the present invention. The device may be covered with a protective layer before being provided with the gas barrier film.

The gas barrier film of the present invention can also be used as the substrate of a device or a film for sealing by a solid sealing method. The solid sealing method is a method in which a protective layer is formed on a device and an adhesive agent layer and a gas barrier film are then superimposed thereon and cured. The adhesive agent is not particularly limited, but examples thereof may include a thermosetting epoxy resin and a photocurable acrylate resin.

(Organic EL Device)

Examples of the organic EL device using a gas barrier film are described in detail in JP 2007-30387 A.

(Liquid Crystal Display Device)

A reflective liquid crystal display device has a configuration consisting of a lower substrate, a reflective electrode, a lower alignment film, a liquid crystal layer, an upper alignment film, a transparent electrode, an upper substrate, a λ/4 plate, and a polarizing film in order from the bottom. The gas barrier film of the present invention can be used as the substrate of the transparent electrode and the upper substrate.

<Photovoltaic Cell>

The gas barrier film of the present invention can also be used as a sealing film of a photovoltaic cell device. Here, it is preferable that the gas barrier film of the present invention is sealed so that the barrier layer is on the side near to the solar cell device.

(Others)

Examples of other applications may include a thin film transistor described in JP 10-512104 W, a touch panel described in JP 5-127822 A and JP 2002-48913 A, and electronic paper described in JP 2000-98326 A.

<Optical Member>

The gas barrier film of the present invention can also be used as an optical member. Examples of the optical member may include a circularly polarizing plate.

(Circularly Polarizing Plate)

It is possible to fabricate a circularly polarizing plate by stacking a λ/4 plate and a polarizing plate on the gas barrier film of the present invention serving as the substrate. In this case, stacking is conducted such that the angle formed by the slow axis of the λ/4 plate and the absorption axis of the polarizing plate becomes 45°. As such a polarizing plate, it is preferable to use those which are stretched in the direction of 45° with respect to the machine direction (MD), and for example, those described in JP 2002-865554 A can be suitably used.

### EXAMPLES

The effect of the present invention will be described with reference to the following Examples and Comparative Examples. However, the technical scope of the present invention is not limited only to the following Examples. In addition, the denotation “part” or “%” used in Examples represents “parts by mass” or “% by mass” unless otherwise specified. In addition, in the following operations, the operation and the measurement of physical properties and the like are conducted under the condition of room temperature (20 to 25° C.)/relative humidity of 40 to 50% unless otherwise specified.

<Production of Gas Barrier Film>

(Fabrication of Sample 1)

[Formation of First Layer (Vapor Phase Film Deposition)]

The first layer (100 nm) of silicon oxycarbide was formed on a transparent resin substrate with hard coat layer (intermediate layer) (a polyethyleneterephthalate (PET) film with clear hard coat layer (CHC) manufactured by KIMOTO CO., LTD., the hard coat layer is composed of a UV curing resin containing an acrylic resin as a main component, the thickness of PET is 125 μm, and the thickness of CHC is 6 μm) by an atmospheric pressure plasma method using an atmospheric pressure plasma deposition apparatus (atmospheric pressure plasma CVD apparatus of a roll-to-roll form illustrated in FIG. 2) under the following condition for thin film formation.

(Mixed Gas Composition)

Discharge gas: nitrogen gas 94.9% by volume

Thin film forming gas: tetraethoxysilane 0.1% by volume

Additive gas: oxygen gas 5.0% by volume

(Film Deposition Condition)

<First Electrode Side>

Kind of power supply: 100 kHz (continuous mode) PHF-6k manufactured by HAIDENLABORATORY

Frequency: 100 kHz

Power density: 10 W/cm²

Electrode temperature: 120° C.

<Second Electrode Side>

Kind of power supply: 13.56 MHz CF-5000-13M manufactured by PEARL KOGYO Co., Ltd.

Frequency: 13.56 MHz

Power density: 10 W/cm²

Electrode temperature: 90° C.

The first layer formed in accordance with the above method was composed of silicon oxycarbide (SiOC), the film thickness thereof was 100 nm, and the elastic modulus, E1, thereof was consistently 30 GPa in the film thickness direction.

[Formation of Second Layer (Coating of Solution Containing Polysilazane Compound)]

(Preparation of Polysilazane-Containing Coating Liquid)

A dibutyl ether solution containing 20% by mass of perhydropolysilazane not containing a catalyst (NN120-20 manufactured by AZ Electronic Materials Co.) and a dibutyl ether solution containing 20% by mass of perhydropolysilazane containing an amine catalyst (NAX120-20 manufactured by AZ Electronic Materials Co.) were mixed at a proportion of 4:1, and further the mixture was diluted and adjusted with the dibutyl ether solvent so that the solid content of the coating liquid became 5% by mass.

(Film Formation)

A film was formed on a substrate using a spin coater so as to have a thickness of 150 nm, and the resultant was left to stand for 2 minutes and then subjected to the additional heat treatment for 1 minute at 80° C. in a hot plate, thereby forming a polysilazane coating film.

After the formation of the polysilazane coating film, a gas barrier film was produced by irradiating the polysilazane coating film with vacuum ultraviolet light (excimer irradiation apparatus MODEL: MECL-M-1-200 manufactured by M. D. COM, inc., wavelength: 172 nm, stage temperature: 100° C., accumulated light amount 3000 mJ/cm², concentration of oxygen: 0.1%) in accordance with the following method.

<Condition of Vacuum Ultraviolet Irradiation and Measurement of Irradiation Energy>

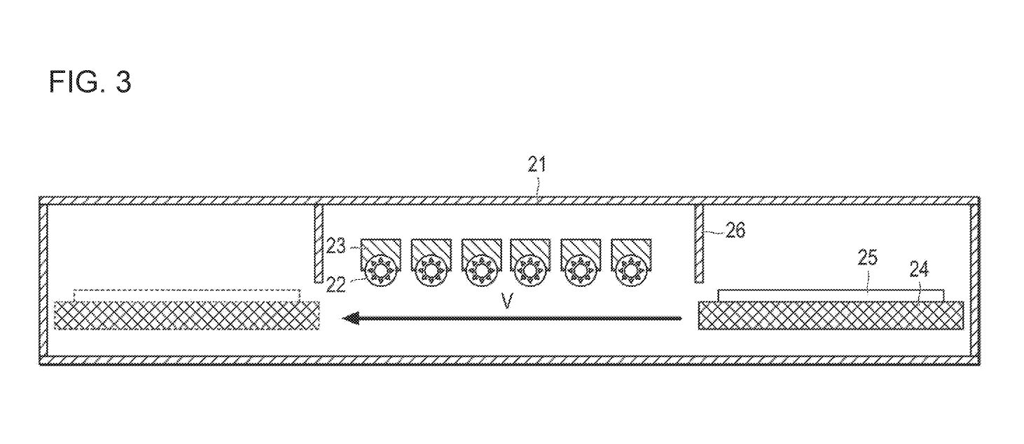

Vacuum ultraviolet irradiation was conducted using the apparatus illustrated as a schematic sectional diagram in FIG. 3.

In FIG. 3, 21 is an apparatus chamber, and it is possible to substantially remove the water vapor from the inside of the chamber and to maintain the concentration of oxygen at a predetermined concentration by supplying a suitable amount of nitrogen and oxygen to the inside thereof through the gas supply port that is not illustrated and exhausting them through the gas discharge port that is not illustrated. 22 is a Xe excimer lamp having a double tube structure to irradiate vacuum ultraviolet rays of 172 nm, 23 is a holder for the excimer lamp which also serves as an external electrode. 24 is a sample stage. The sample stage 24 can be horizontally reciprocated at a predetermined speed in the apparatus chamber 21 by a moving means that is not illustrated. In addition, the sample stage 24 can be maintained at a predetermined temperature by a heating means that is not illustrated. 25 is a sample on which the polysilazane coating layer is formed. The height of the sample stage is adjusted so that the shortest distance between the coating layer surface of the sample and the excimer lamp tube surface becomes 3 mm when the sample stage horizontally moves. 26 is a light shielding plate by which the coating layer of the sample is prevented from being irradiated with vacuum ultraviolet light during aging of the Xe excimer lamp 22.

The energy irradiated on the coating layer surface of the sample in the vacuum ultraviolet ray irradiating step was measured using an accumulated light amount meter for ultraviolet rays: C8026/H8025 UV POWER METER manufactured by Hamamatsu Photonics K. K. and a sensor head of 172 nm. Upon the measurement, the sensor head was installed in the center of the sample stage 24 so that the shortest distance between the Xe excimer lamp tube surface and the measurement surface of the sensor head became 3 mm, and nitrogen and oxygen were supplied into the apparatus chamber 21 so that the atmosphere therein had the same concentration of oxygen as in the vacuum ultraviolet ray irradiating step, and the sample stage 24 was moved at a speed of 0.5 m/min to conduct the measurement. Prior to the measurement, in order to stabilize the intensity of illumination of the Xe excimer lamp 22, 10 minutes of aging time was provided after turning on the Xe excimer lamp, and the sample stage was then moved to start the measurement.

The irradiation energy was adjusted to 3000 mJ/cm² by adjusting the moving speed of the sample stage on the basis of the irradiation energy obtained in this measurement. Incidentally, the vacuum ultraviolet irradiation was conducted after 10 minutes of aging in the same manner as in the irradiation energy measurement.

The gas barrier film fabricated in the above was denoted as Sample 1.

(Fabrication of Sample 2)

Sample 2 was fabricated in the same manner as in Sample 1 except that the second layer of Sample 1 was not subjected to the modification treatment.

(Fabrication of Sample 3)

Sample 3 was fabricated in the same manner as in Sample 1 except that the after-treatment for 24 hours at 80° C. is carried out after the modification treatment of the second layer of Sample 1. Incidentally, in the present Example, the after-treatment was conducted under the condition of a relative humidity of 40%.

(Fabrication of Sample 4)

Sample 4 was fabricated in the same manner as in Sample 1 except that the first layer and the second layer of Sample 1 were switched with each other.

(Fabrication of Sample 5)

Sample 5 was fabricated in the same manner as in Sample 2 except that the first layer and the second layer of Sample 2 were switched with each other.

(Fabrication of Sample 6)

Sample 6 was fabricated in the same manner as in Sample 3 except that the first layer and the second layer of Sample 3 were switched with each other.

(Fabrication of Sample 7)

Sample 7 was fabricated in the same manner as in Sample 1 except that a layer that was the same layer as the second layer of Sample 1 and was subjected to the modification treatment in the same manner as the second layer of Sample 1 was provided on the second layer of Sample 1 as the third layer.

(Fabrication of Sample 8)

Sample 8 was fabricated in the same manner as in Sample 7 except that the after-treatment for 24 hours at 80° C. is carried out after the modification treatment of the third layer of Sample 7.

(Fabrication of Sample 10)

The following second coating liquid was fabricated, a film was formed on a substrate using a spin coater so as to have a thickness of 150 nm, and the resultant was left to stand for 2 minutes and then subjected to the additional heat treatment for 1 minute at 80° C. in a hot plate, thereby forming a polysilazane coating film on the first layer of Sample 1 as the second layer. The polysilazane coating film was subjected to the same modification treatment as in Sample 1 after formation, thereby fabricating Sample 10.

(Second Coating Liquid)

A dibutyl ether solution containing 20% by mass of perhydropolysilazane (AQUAMICA (registered trademark) NN120-20 manufactured by AZ Electronic Materials Co.) and a dibutyl ether solution containing 1% by mass of an amine catalyst and 19% by mass of perhydropolysilazane (AQUAMICA NAX120-20 manufactured by AZ Electronic Materials Co.) were mixed at a ratio of 4 g:1 g, 3.74 g of the mixture was taken, and 0.46 g of ALCH (aluminum ethylacetoacetate diisopropylate manufactured by Kawaken Fine Chemicals Co., Ltd.) and 19.2 g of dibutyl ether were added thereto and mixed together, thereby preparing a coating solution.

(Fabrication of Sample 11)

Sample 11 was fabricated in the same manner as in Sample 10 except that the second layer of Sample 10 was not subjected to the modification treatment.

(Fabrication of Sample 12)

Sample 12 was fabricated in the same manner as in Sample 10 except that the after-treatment for 24 hours at 80° C. is carried out after the modification treatment of the second layer of Sample 10.

(Fabrication of Sample 13)

Sample 13 was fabricated in the same manner as in Sample 10 except that the first layer was switched with the second layer and the second layer was switched with the first layer of Sample 10.

(Fabrication of Sample 14)

Sample 14 was fabricated in the same manner as in Sample 13 except that the first layer of Sample 13 was not subjected to the modification treatment.

(Fabrication of Sample 15)

Sample 15 was fabricated in the same manner as in Sample 13 except that the after-treatment for 24 hours at 80° C. is carried out after the modification treatment of the second layer of Sample 13.

(Fabrication of Sample 16)

Sample 16 was fabricated in the same manner as in Sample 7 except that the third layer of Sample 7 was the second layer of Sample 10.

(Fabrication of Sample 17)

Sample 17 was fabricated in the same manner as in Sample 16 except that the after-treatment for 24 hours at 80° C. is carried out after the modification treatment of the third layer of Sample 16.

(Fabrication of Sample 18)

Sample 18 was fabricated in the same manner as in Sample 10 except that the second layer of Sample 10 was further stacked on Sample 10 as the third layer.

(Fabrication of Sample 19)

Sample 19 was fabricated in the same manner as in Sample 18 except that the after-treatment for 24 hours at 80° C. is carried out after the modification treatment of the third layer of Sample 18.

(Fabrication of Sample 20)

Sample 20 was fabricated in the same manner as in Sample 19 except that the following modification treatment was carried out after formation of the first layer of Sample 19.

Modification Treatment

The modification treatment after formation of the first layer was carried out by the same technique as in the modification treatment of the second layer of Sample 1 except that the accumulated light amount was changed to 0.5 J/cm² and the concentration of oxygen was changed to 1.0%.

(Fabrication of Sample 21, Sample 22, and Sample 23)

Sample 21, Sample 22, and Sample 23 were respectively fabricated by the same procedure as in Sample 10, Sample 11, and Sample 12 except that the thickness of the second layer thereof was changed from 150 nm to 145 nm.

(Fabrication of Sample 24, Sample 25, and Sample 26)

Sample 24, Sample 25, and Sample 26 were respectively fabricated by the same procedure as in Sample 13, Sample 14, and Sample 15 except that the thickness of the first layer thereof was changed from 150 nm to 145 nm.

(Fabrication of Sample 27 and Sample 28)

Sample 27 and Sample 28 were respectively fabricated by the same procedure as in Sample 16 and Sample 17 except that the thickness of the third layer thereof was changed from 150 nm to 145 nm.

(Fabrication of Sample 29, Sample 30, and Sample 31)

Sample 29, Sample 30, and Sample 31 were respectively fabricated by the same procedure as in Sample 18, Sample 19, and Sample 20 except that the thicknesses of the second layer and the third layer thereof were respectively changed from 150 nm to 145 nm.

(Fabrication of Sample 32, Sample 33, and Sample 34)

Sample 32, Sample 33, and Sample 34 were respectively fabricated by the same procedure as in Sample 10, Sample 11, and Sample 12 except that the thickness of the second layer thereof was changed from 150 nm to 60 nm.

(Fabrication of Sample 35, Sample 36, and Sample 37)

Sample 35, Sample 36, and Sample 37 were respectively fabricated by the same procedure as in Sample 13, Sample 14, and Sample 15 except that the thickness of the first layer thereof was changed from 150 nm to 60 nm.

(Fabrication of Sample 38 and Sample 39)

Sample 38 and Sample 39 were respectively fabricated by the same procedure as in Sample 16 and Sample 17 except that the thickness of the third layer thereof was changed from 150 nm to 60 nm.

(Fabrication of Sample 40, Sample 41, and Sample 42)

Sample 40, Sample 41, and Sample 42 were respectively fabricated by the same procedure as in Sample 18, Sample 19, and Sample 20 except that the thicknesses of the second layer and the third layer thereof were respectively changed from 150 nm to 60 nm.

(Fabrication of Sample 43, Sample 44, and Sample 45)

Sample 43, Sample 44, and Sample 45 were respectively fabricated by the same procedure as in Sample 10, Sample 11, and Sample 12 except that the thickness of the second layer thereof was changed from 150 nm to 8 nm.

(Fabrication of Sample 46, Sample 47, and Sample 48)

Sample 46, Sample 47, and Sample 48 were respectively fabricated by the same procedure as in Sample 13, Sample 14, and Sample 15 except that the thickness of the first layer thereof was changed from 150 nm to 8 nm.

(Fabrication of Sample 49 and Sample 50)

Sample 49 and Sample 50 were respectively fabricated by the same procedure as in Sample 16 and Sample 17 except that the thickness of the third layer thereof was changed from 150 nm to 8 nm.

(Fabrication of Sample 51, Sample 52, and Sample 53)

Sample 51, Sample 52, and Sample 53 were respectively fabricated by the same procedure as in Sample 18, Sample 19, and Sample 20 except that the thicknesses of the second layer and the third layer thereof were respectively changed from 150 nm to 8 nm.

(Fabrication of Sample 54, Sample 55, and Sample 56)

Sample 54, Sample 55, and Sample 56 were respectively fabricated by the same procedure as in Sample 10, Sample 11, and Sample 12 except that the thickness of the second layer thereof was changed from 150 nm to 0.1 nm.

(Fabrication of Sample 57, Sample 58, and Sample 59)

Sample 57, Sample 58, and Sample 59 were respectively fabricated by the same procedure as in Sample 13, Sample 14, and Sample 15 except that the thickness of the first layer thereof was changed from 150 nm to 0.1 nm.

(Fabrication of Sample 60 and Sample 61)

Sample 60 and Sample 61 were respectively fabricated by the same procedure as in Sample 16 and Sample 17 except that the thickness of the third layer thereof was changed from 150 nm to 0.1 nm.

(Fabrication of Sample 62, Sample 63, and Sample 64)

Sample 62, Sample 63, and Sample 64 were respectively fabricated by the same procedure as in Sample 18, Sample 19, and Sample 20 except that the thicknesses of the second layer and the third layer thereof were respectively changed from 150 nm to 0.1 nm.

(Fabrication of Sample 65, Sample 66, and Sample 67)

Sample 65, Sample 66, and Sample 67 were respectively fabricated by the same procedure as in Sample 10, Sample 11, and Sample 12 except that the thickness of the second layer thereof was changed from 150 nm to 0.08 nm.

(Fabrication of Sample 68, Sample 69, and Sample 70)

Sample 68, Sample 69, and Sample 70 were respectively fabricated by the same procedure as in Sample 13, Sample 14, and Sample 15 except that the thickness of the first layer thereof was changed from 150 nm to 0.08 nm.

(Fabrication of Sample 71 and Sample 72)

Sample 71 and Sample 72 were respectively fabricated by the same procedure as in Sample 16 and Sample 17 except that the thickness of the third layer thereof was changed from 150 nm to 0.08 nm.

(Fabrication of Sample 73, Sample 74, and Sample 75)

Sample 73, Sample 74, and Sample 75 were respectively fabricated by the same procedure as in Sample 18, Sample 19, and Sample 20 except that the thicknesses of the second layer and the third layer thereof were respectively changed from 150 nm to 0.08 nm.

(Fabrication of Sample 76)

Sample 76 was fabricated by forming a film having the same thickness as the second layer of Sample 43 of 8 nm by the same procedure as in Sample 43 except that ALCH of the coating liquid at the time of fabricating the second layer of Sample 43 was changed to 0.46 g of gallium (III) isopropoxide (manufactured by Wako Pure Chemical Industries, Ltd.).

(Fabrication of Sample 77)

Sample 77 was fabricated by forming a film having the same thickness as the second layer of Sample 43 of 8 nm by the same procedure as in Sample 43 except that ALCH of the coating liquid at the time of fabricating the second layer of Sample 43 was changed to 0.46 g of indium (III) isopropoxide (manufactured by Wako Pure Chemical Industries, Ltd.).

(Fabrication of Sample 78)

Sample 78 was fabricated by forming a film having the same thickness as the second layer of Sample 43 of 8 nm by the same procedure as in Sample 43 except that ALCH of the coating liquid at the time of fabricating the second layer of Sample 43 was changed to 0.46 g of magnesium ethoxide (manufactured by Wako Pure Chemical Industries, Ltd.).

(Fabrication of Sample 79)

Sample 79 was fabricated by forming a film having the same thickness as the second layer of Sample 43 of 8 nm by the same procedure as in Sample 43 except that ALCH of the coating liquid at the time of fabricating the second layer of Sample 43 was changed to 0.46 g of calcium isopropoxide (manufactured by Wako Pure Chemical Industries, Ltd.).

(Fabrication of Sample 80)

Sample 80 was fabricated by forming a film having the same thickness as the second layer of Sample 43 of 8 nm by the same procedure as in Sample 43 except that ALCH of the coating liquid at the time of fabricating the second layer of Sample 43 was changed to 0.46 g of triisopropyl borate (manufactured by Wako Pure Chemical Industries, Ltd.).

(Fabrication of Sample 81)

Sample 81 was fabricated by forming a film having the same thickness as the second layer of Sample 43 of 8 nm by the same procedure as in Sample 43 except that ALCH of the coating liquid at the time of fabricating the second layer of Sample 43 was changed to the same amount of tris(dibutylsulfide) rhodium trichloride[tris(dibutylsulfide)RhCl₃ manufactured by Gelest, Inc.].

(Fabrication of Sample 98, Sample 99, and Sample 100)

Sample 98, Sample 99, and Sample 100 were respectively fabricated by the same procedure as in Sample 1, Sample 2, and Sample 3 except that the thickness of the second layer thereof was changed from 150 nm to 8 nm.

(Fabrication of Sample 101, Sample 102, and Sample 103)

Sample 101, Sample 102, and Sample 103 were respectively fabricated by the same procedure as in Sample 4, Sample 5, and Sample 6 except that the thickness of the first layer thereof was changed from 150 nm to 8 nm.

(Fabrication of Sample 104 and Sample 105)

Sample 104 and Sample 105 were respectively fabricated by the same procedure as in Sample 7 and Sample 8 except that the thickness of the second layer and the third layer thereof were respectively changed from 150 nm to 8 nm.

(Fabrication of Sample 122)

The accumulated light amount for the modification treatment after stacking the second layer of Sample 98 was set to 1000 mJ/cm². A layer which was the same layer as the second layer of Sample 98 but of which the thickness was changed to 40 nm and was subjected to the modification treatment in the same manner at an accumulated light amount of 1000 mJ/cm² was provided on this second layer as the third layer. Thereafter, the same layer as the second layer of Sample 98 was stacked on the third layer as the fourth layer and the layer was subjected to the modification treatment in the same manner at an accumulated light amount of 1000 mJ/cm².

(Fabrication of Sample 123)

Sample 123 was fabricated by the same procedure as in Sample 122 except that the after-treatment for 24 hours at 80° C. was carried out after forming the fourth layer of Sample 122.

(Fabrication of Sample 124)

The second layer of Sample 122 was changed to the same layer as the second layer of Sample 43 but the accumulated light amount for the modification treatment was set to 1000 mJ/cm². The conditions other than this were set in the same manner as in Sample 122, thereby fabricating Sample 124.

(Fabrication of Sample 125)

Sample 125 was fabricated by the same procedure as in Sample 124 except that the after-treatment for 24 hours at 80° C. was carried out after forming the fourth layer of Sample 124.

(Fabrication of Sample 126)

Sample 126 was fabricated by the same procedure as in Sample 122 except that the third layer of Sample 122 was changed to a layer which was the same layer as the second layer of Sample 43 but of which the thickness was changed to 40 nm and was subjected to the modification treatment in the same manner at an accumulated light amount of 1000 mJ/cm².

(Fabrication of Sample 127)

Sample 127 was fabricated by the same procedure as in Sample 126 except that the after-treatment for 24 hours at 80° C. was carried out after forming the fourth layer of Sample 126.

(Fabrication of Sample 128)

The fourth layer of Sample 122 was changed to the same layer as the second layer of Sample 43 but the accumulated light amount for the modification treatment was set to 1000 mJ/cm². The conditions other than this were set in the same manner as in Sample 122, thereby fabricating Sample 128.

(Fabrication of Sample 129)

Sample 129 was fabricated by the same procedure as in Sample 128 except that the after-treatment for 24 hours at 80° C. was carried out after forming the fourth layer of Sample 128.

(Fabrication of Sample 130)

The second layer of Sample 122 was changed to the same layer as the second layer of Sample 81 but the accumulated light amount for the modification treatment was set to 1000 mJ/cm². The conditions other than this were set in the same manner as in Sample 122, thereby fabricating Sample 130.

(Fabrication of Sample 131)

Sample 131 was fabricated by the same procedure as in Sample 130 except that the after-treatment for 24 hours at 80° C. was carried out after forming the fourth layer of Sample 130.

(Fabrication of Sample 132)

Sample 132 was fabricated by the same procedure as in Sample 98 except that the first layer of Sample 98 was changed to the barrier layer formed by the following vapor phase film deposition and the accumulated light amount for the modification treatment after stacking the second layer was changed to 2000 mJ/cm².

The formation of the barrier layer on the surface of the smooth layer of the substrate to be the target was conducted using the vacuum plasma CVD apparatus illustrated in FIG. 1. The high frequency power supply used at this time was a high frequency power supply of 27.12 MHz, and the distance between electrodes was set to 20 mm.

As the raw material gas, a silane gas, an ammonia gas, and a hydrogen gas were introduced into the vacuum chamber under the condition of 7.5 sccm, 50 sccm, and 200 sccm as a flow rate, respectively. At the time of starting the film deposition, the temperature of the substrate to be the target was set to 100° C., the gas pressure at the time of film deposition was set to 4 Pa, and an inorganic film mainly composed of silicon nitride was formed in a film thickness of 30 nm. Thereafter, the temperature of the substrate was maintained as it was, the gas pressure was changed to 30 Pa, and an inorganic film mainly composed of silicon nitride was continuously formed in a film thickness of 30 nm, thereby forming the first layer having the total film thickness of 60 nm.

(Fabrication of Sample 133)

Sample 133 was fabricated by the same procedure as in Sample 132 except that the after-treatment for 24 hours at 80° C. was carried out after forming the second layer of Sample 132.

(Fabrication of Sample 134)

Sample 134 was fabricated by the same procedure as in Sample 132 except that the second layer of Sample 43 was provided instead of the second layer of Sample 132 and further the accumulated light amount for the modification treatment after stacking the second layer was changed to 2000 mJ/cm².

(Fabrication of Sample 135)

Sample 135 was fabricated by the same procedure as in Sample 134 except that the after-treatment for 24 hours at 80° C. was carried out after forming the second layer of Sample 134.

Each of the gas barrier films fabricated in the above was subjected to the following evaluations.

<<Method for Measuring Property Value of Gas Barrier Film>>

<<Evaluation on Adhesive Force>>

For each of the gas barrier films fabricated in the above, a sample which was exposed to a high temperature and a high humidity of 85° C. and 85% RH for 500 hours was prepared.

The 100 squares test of JIS 5400 by the cross-cut method was carried out.

The number of squares that were not peeled off among the 100 squares was measured. The adhesive force was stronger as the number of squares that were not peeled off was increased.

This evaluation was carried out for both of the sample before being exposed to a high temperature and a high humidity of 85° C. and 85% RH for 500 hours (immediately) and the sample after being exposed to a high temperature and a high humidity of 85° C. and 85% RH for 500 hours (after DH 500 hours). As the indicator of adhesive property, it was judged to be acceptable when the results for the “immediately” and the “after DH 500 hours” were 20 or more, respectively.

<<Evaluation on Folding Resistance>>

Each of the gas barrier films fabricated in the above was repeatedly bent at an angle of 180° so as to have a radius of curvature of 2 mm 100 times, the water vapor transmission rate thereof was then measured in the same manner as above, the degree of deterioration resistance was determined from a change in water vapor transmission rate before and after the bending treatment by the following Equation, and the folding resistance was evaluated according to the following criteria.

Degree of deterioration resistance=(water vapor transmission rate after bending test/water vapor transmission rate before bending test)×100(%)

This degree of deterioration resistance was evaluated by classifying into the following five grades.

5: degree of deterioration resistance is 95% or more

4: degree of deterioration resistance is 85% or more and less than 95%

3: degree of deterioration resistance is 50% or more and less than 85%

2: degree of deterioration resistance is 10% or more and less than 50% and

1: degree of deterioration resistance is less than 10%.

This evaluation was carried out for both of the sample before being exposed to a high temperature and a high humidity of 85° C. and 85% RH for 500 hours (immediately) and the sample after being exposed to a high temperature and a high humidity of 85° C. and 85% RH for 500 hours (after DH 500 hours). As the indicator of folding resistance, it was judged to be acceptable when the results for the “immediately” and the “after DH 500 hours” were 3 or more, respectively.

<<Evaluation on Barrier Property Test>>

For the gas barrier films fabricated in the above, the samples which were exposed to a high temperature and a high humidity of 85° C. and 85% RH for 500 hours (after DH 500 hours) were prepared.

The barrier property test was carried out by forming a 80 nm thick film of metallic calcium on the gas barrier film by deposition and evaluating the time required to be 50% of the area as the deterioration time. The 50% area time for each of the sample before being exposed to a high temperature and a high humidity of 85° C. and 85% RH for 500 hours (immediately) and the sample after being exposed to a high temperature and a high humidity of 85° C. and 85% RH for 500 hours (after DH 500 hours) was evaluated, and the retention rate (%) was calculated by 50% area time of (after DH 500 hours)/50% area time of (immediately) and presented in Table 1 as well. As the indicator of the retention rate, it was judged to be acceptable when the retention rate was 70% or more and it was judged to be unacceptable when the retention rate was less than 70%.

(Metallic Calcium Film Forming Apparatus)

Deposition apparatus: vacuum deposition apparatus JEE-400 manufactured by JEOL Ltd.

Constant temperature and humidity oven: Yamato Humidic ChamberIG47M

(Raw Materials)

Metal corroded by reaction with water: Calcium (granular)

Water vapor impermeable metal: aluminum (φ3 to 5 mm, granular)

(Fabrication of sample for water vapor barrier property evaluation)

Metallic calcium was deposited on the barrier layer surface of the gas barrier film thus fabricated through the mask in a size of 12 mm×12 mm using a vacuum deposition apparatus (vacuum deposition apparatus JEE-400 manufactured by JEOL Ltd.). At this time, the thickness of the deposited film was set to 80 nm.

Thereafter, the mask was removed therefrom as it was in the vacuum state, and aluminum was deposited on the entire surface of one side of the sheet to temporarily seal. Subsequently, the vacuum state was released, and the resultant was immediately moved in a dry nitrogen gas atmosphere, quartz glass having a thickness of 0.2 mm was pasted to the aluminum deposited surface via an ultraviolet curable resin for sealing (manufactured by Nagase ChemteX Corporation), the resin was cured and stuck by irradiating with ultraviolet rays to mainly seal the resultant, thereby fabricating the sample for water vapor barrier property evaluation.

The sample thus obtained was stored at a high temperature and a high humidity of 85° C. and 85% RH, and the course that the corrosion of metallic calcium proceeded with the storage time was observed. Upon observation, the time required for that the area in which metallic calcium corroded became 50% with respect to the area in which metallic calcium deposited of 12 mm×12 mm was determined by interpolating the observed result in a straight line, and the results for the samples before and after being exposed to a high temperature and a high humidity of 85° C. and 85% RH for 500 hours are presented in Table 1.

<<Evaluation on Cracking>>

Each of the gas barrier film samples fabricated in the above was exposed to a high temperature and a high humidity of 85° C. and 85% RH for 300 hours to prepare the sample (after DH 300 hours). This sample was left to stand for 12 hours in an environment of 23±2° C. and 55±5% RH and then left to stand for 12 hours under the condition of 85±3° C. and 90±2% RH, and again this sample was alternately repeatedly left to stand for 12 hours at 23±2° C. and 55±5% RH and then for 12 hours at 85±3° C. and 90±2% RH. This operation was conducted 30 times, and the sample was left to stand for 12 hours in an environment of 23±2° C. and 55±5% RH at the end, and then the state of cracking thereof was observed using an optical microscope and evaluated according to the following criteria. As the indicator of crack resistance, it was judged to be acceptable when the evaluation was 4 or more and it was judged to be unacceptable when the evaluation was 3 or less.

5: cracking is not observed at all

4: cracking is slightly observed but to a level to which there is no problem as barrier property

3: cracking is observed and there is a high possibility that barrier property deteriorates

2: cracking is observed and there is a high possibility that barrier property significantly deteriorates and

1: cracking is frequently observed and the barrier property significantly deteriorates.

<<Fabrication of Organic Thin Film Electronic Device>>

An organic EL device was fabricated using the gas barrier film produced in the above by the following method.

[Fabrication of Organic EL Device]

(Formation of First Electrode Layer)

ITO (indium tin oxide) was deposited on the barrier layer of the gas barrier film produced in each of Examples and Comparative Examples in a thickness of 150 nm by the sputtering method. Subsequently, the patterning thereof was conducted by photolithography to form the first electrode layer. Incidentally, the patterning was conducted so as to have a light-emitting area of 50 mm².

(Formation of Hole Transport Layer)

The hole transport layer was formed by coating the coating liquid for hole transport layer formation to be described later on the first electrode layer of each of the gas barrier films on which the first electrode layer was formed using an extrusion coating machine and then drying it. The coating liquid for hole transport layer formation was coated so as to have a thickness after drying of 50 nm.

Before coating the coating liquid for hole transport layer formation, the cleaning surface modification treatment of the gas barrier film was conducted at an irradiation intensity of 15 mW/cm² and a distance 10 mm using a low pressure mercury lamp having a wavelength of 184.9 nm. A static eliminator by weak X-ray was used for the charge removal treatment.

<Coating Condition>

The coating step was conducted in the air and in an environment of 25° C. and a relative humidity (RH) of 50%.

<Preparation of Coating Liquid for Hole Transport Layer Formation>

A solution obtained by diluting polyethylene dioxythiophene polystyrene sulfonate (PEDOT/PSS, Bytron P AI 4083 manufactured by Bayer AG) to 65% with pure water and 5% with methanol was prepared as the coating liquid for hole transport layer formation.

<Drying and Heating Treatment Condition>

After coating the coating liquid for hole transport layer formation, the solvent was removed by blowing wind at a temperature of 100° C., a height toward the film formed surface of 100 mm, an ejection velocity of 1 m/s, and a wind speed distribution in width of 5%, and subsequently, a heat treatment by the backside heat transfer method was conducted at a temperature 150° C. using a heating treatment apparatus, thereby forming the hole transport layer.

(Formation of Light Emitting Layer)

Subsequently, the light emitting layer was formed by coating the coating liquid for white light emitting layer formation to be described below on the hole transport layer using the extrusion coating machine and then drying it. The coating liquid for white light emitting layer formation was coated so as to have a thickness of 40 nm after drying.

<Coating Liquid for White Light Emitting Layer Formation>

In 100 g of toluene, 1.0 g of a host material H-A, 100 mg of a dopant material D-A, 0.2 mg of a dopant material D-B, and 0.2 mg of a dopant material D-C were dissolved to prepare a solution as a coating liquid for white light emitting layer formation.

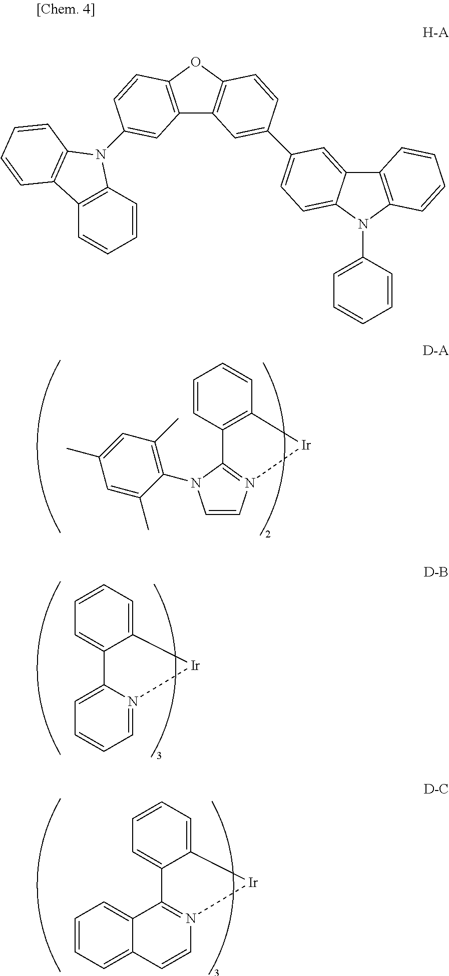

<Coating Condition>

The coating step was conducted in an atmosphere of the concentration of nitrogen gas of 99% or more at a coating temperature of 25° C. and a coating speed of 1 m/min.

<Drying and Heating Treatment Condition>

After coating the coating liquid for white light emitting layer formation, the solvent was removed by blowing wind at a temperature of 60° C., a height toward the film formed surface of 100 mm, an ejection velocity of 1 m/s, and a wind speed distribution in width of 5%. Subsequently, a heating treatment was conducted at a temperature 130° C., thereby forming the light emitting layer.

(Formation of Electron Transport Layer)

Next, the electron transport layer was formed by coating the coating liquid for electron transport layer formation to be described below using the extrusion coating machine and then drying it. The coating liquid for electron transport layer formation was coated so as to have a thickness after drying of 30 nm.

<Coating Condition>

The coating step was conducted in an atmosphere of the concentration of nitrogen gas of 99% or more at a coating temperature of the coating liquid for electron transport layer formation of 25° C. and a coating speed of 1 m/min.

<Coating Liquid for Electron Transport Layer Formation>

For the electron transport layer, a compound represented by the following Chemical Formula E-A was dissolved in 2,2,3,3-tetrafluoro-1-propanol and adjusted to be a 0.5% by mass solution, and this was used as the coating liquid for electron transport layer formation.

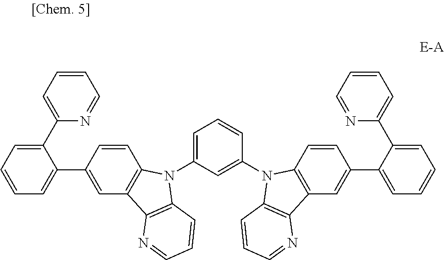 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

<Drying and Heating Treatment Condition>

After coating the coating liquid for electron transport layer formation, the solvent was removed by blowing wind at a temperature of 60° C., a height toward the film formed surface of 100 mm, an ejection velocity of 1 m/s, and a wind speed distribution in width of 5%. Subsequently, a heating treatment was conducted at a temperature 200° C. in the heating treatment unit, thereby forming the electron transport layer.

(Formation of Electron Injection Layer)

Next, the electron injection layer was formed on the electron transport layer thus formed. First, the substrate was introduced into a reduced pressure chamber, the pressure was reduced to 5×10⁻⁴ Pa. Cesium fluoride which had been prepared in advance in the tantalum deposition boat of the vacuum chamber was heated to form an electron injection layer having a thickness of 3 nm.

(Formation of Second Electrode)

A mask pattern was deposited on the electron injection layer thus formed excluding the part that became an extraction electrode on the first electrode using aluminum as the second electrode forming material in a vacuum of 5×10⁻⁴ Pa by a deposition method so as to have an extraction electrode and a light emitting area of 50 mm², thereby stacking the second electrode having a thickness of 100 nm.

(Cutting)

Each of the gas barrier film having the second electrode formed thereon was again moved into a nitrogen atmosphere and cut into a prescribed size using an ultraviolet laser, thereby fabricating an organic EL device.

(Connection of Electrode Lead)

A flexible printed circuit board (Base Film: polyimide of 12.5 μm, rolled copper foil: 18 μm, coverlay: polyimide of 12.5 μm, surface treatment: NiAu plating) was connected to the organic EL device thus fabricated using the anisotropic conductive film DP3232S9 manufactured by Sony Chemical & Information Device Corporation.

Crimping Condition: crimping was conducted for 10 seconds at a temperature of 170° C. (ACF temperature measured using a separate thermocouple: 140° C.) and a pressure of 2 MPa.

(Sealing)

The sealing member was stuck to the organic EL device connected to the electrode lead (flexible printed circuit board) using a commercially available roll laminator, thereby fabricating an organic EL device.

Incidentally, one obtained by laminating a polyethylene terephthalate (PET) film (12 μm thick) on a 30 μm thick aluminum foil (manufactured by Toyo Aluminum K. K.) using an adhesive agent for dry lamination (urethane-based adhesive agent of two-liquid reaction type) (thickness of adhesive agent layer: 1.5 μm) was used as the sealing member.

A thermosetting adhesive agent was uniformly coated on the aluminum surface along the stuck surface (glossy surface) of the aluminum foil in a thickness of 20 μm using a dispenser.

As the thermosetting adhesive agent, the following epoxy adhesive agent was used.

Bisphenol A diglycidyl ether (DGEBA)

Dicyandiamide (DICY)

Epoxy adduct curing promotor

Thereafter, a sealing substrate was closely disposed so as to cover the junction portion between the extraction electrode and the electrode lead and closely sealed using a crimping roll under a crimping condition: crimping roll temperature of 120° C., pressure of 0.5 MPa, device speed of 0.3 m/min.

<<Evaluation of Organic EL Device>>

The evaluation on the durability of the organic EL device thus fabricated was carried out in accordance with the following method.

[Evaluation on Durability]

(Accelerated Deterioration Treatment)

Each of the organic EL devices thus fabricated was subjected to the accelerated deterioration treatment in an environment of 85° C. and 85% RH for 500 hours and then to the following evaluation on dark spots together with the organic EL device that was not subjected to the accelerated deterioration treatment.

(Evaluation on Dark Spots)

The organic EL device that was subjected to the accelerated deterioration treatment and the organic EL device that was not subjected to the accelerated deterioration treatment were allowed to continuously emit light for 24 hours by applying a current of 1 mA/cm² to each of them, a part of the panel was then magnified using a 100-fold microscope (MS-804 manufactured MORITEX Corporation, lens: MP-ZE25-200) and photographed. The photographic image was cut into a 2-mm square, the ratio of the area having dark spots generated was determined, the device deterioration resistance rate was calculated by the following Equation, and the durability was evaluated according to the following criteria. It was judged to have practically preferable properties when the evaluation ranks for the “immediately” and the “after DH 500 hours” to be described later were both ⊙ or ◯.

Device deterioration resistance rate=(area of dark spots generated in device that was not subjected to accelerated deterioration treatment/area of dark spots generated in device that was subjected to accelerated deterioration treatment)×100(%)

⊙: device deterioration resistance rate is 90% or more

◯: device deterioration resistance rate is 60% or more and less than 90%

Δ: device deterioration resistance rate is 20% or more and less than 60% and

X: device deterioration resistance rate is less than 20%.

This evaluation was carried out for both of the sample before being exposed to a high temperature and a high humidity of 85° C. and 85% RH for 500 hours (immediately) and the sample after being exposed to a high temperature and a high humidity of 85° C. and 85% RH for 500 hours (after DH 500 hours).

The evaluation results are presented in the following Tables 1 to 6.

TABLE 1

| | | First layer | | | | | | |
|---|---|---|---|---|---|---|---|---|
| | | Vapor phase film | | Second layer | | | | |
| | | deposition | | Coating | | | Adhesive property | |
| | | | Modification | | Modification | | | After |
| | | | treatment | Constitution | treatment | After- | | DH 500 |
| | Sample No. | Constitution | mJ/cm² | (metal species) | mJ/cm² | treatment | Immediately | hours |
| Comparison | 10 | SiOC | Nil | PHPS(Al) | 3000 | Nil | 78 | 23 |
| | | 100 nm | | 150 nm | | | | |
| Comparison | 11 | SiOC | Nil | PHPS(Al) | Nil | Nil | 68 | 15 |
| | | 100 nm | | 150 nm | | | | |
| Comparison | 12 | SiOC | Nil | PHPS(Al) | 3000 | 80° C. 24 h | 88 | 23 |
| | | 100 nm | | 150 nm | | | | |
| Present | 21 | SiOC | Nil | PHPS(Al) | 3000 | Nil | 82 | 33 |
| invention | | 100 nm | | 145 nm | | | | |
| Present | 22 | SiOC | Nil | PHPS(Al) | Nil | Nil | 72 | 28 |
| invention | | 100 nm | | 145 nm | | | | |
| Present | 23 | SiOC | Nil | PHPS(Al) | 3000 | 80° C. 24 h | 92 | 36 |
| invention | | 100 nm | | 145 nm | | | | |
| Present | 32 | SiOC | Nil | PHPS(Al) | 3000 | Nil | 83 | 58 |
| invention | | 100 nm | | 60 nm | | | | |
| Present | 33 | SiOC | Nil | PHPS(Al) | Nil | Nil | 73 | 51 |
| invention | | 100 nm | | 60 nm | | | | |
| Present | 34 | SiOC | Nil | PHPS(Al) | 3000 | 80° C. 24 h | 93 | 65 |
| invention | | 100 nm | | 60 nm | | | | |
| Present | 43 | SiOC | Nil | PHPS(Al) | 3000 | Nil | 86 | 77 |
| invention | | 100 nm | | 8 nm | | | | |
| Present | 44 | SiOC | Nil | PHPS(Al) | Nil | Nil | 76 | 68 |
| invention | | 100 nm | | 8 nm | | | | |
| Present | 45 | SiOC | Nil | PHPS(Al) | 3000 | 80° C. 24 h | 96 | 86 |
| invention | | 100 nm | | 8 nm | | | | |
| Present | 54 | SiOC | Nil | PHPS(Al) | 3000 | Nil | 81 | 28 |
| invention | | 100 nm | | 0.1 nm | | | | |
| Present | 55 | SiOC | Nil | PHPS(Al) | Nil | Nil | 70 | 24 |
| invention | | 100 nm | | 0.1 nm | | | | |
| Present | 56 | SiOC | Nil | PHPS(Al) | 3000 | 80° C. 24 h | 90 | 31 |
| invention | | 100 nm | | 0.1 nm | | | | |
| Comparison | 65 | SiOC | Nil | PHPS(Al) | 3000 | Nil | 68 | 20 |
| | | 100 nm | | 0.08 nm | | | | |
| Comparison | 66 | SiOC | Nil | PHPS(Al) | Nil | Nil | 58 | 16 |
| | | 100 nm | | 0.08 nm | | | | |
| Comparison | 67 | SiOC | Nil | PHPS(Al) | 3000 | 80° C. 24 h | 78 | 23 |
| | | 100 nm | | 0.08 nm | | | | |
| Comparison | 1 | SiOC | Nil | PHPS(Nil) | 3000 | Nil | 4 | 1 |
| | | 100 nm | | 150 nm | | | | |
| Comparison | 2 | SiOC | Nil | PHPS(Nil) | Nil | Nil | 0 | 0 |
| | | 100 nm | | 150 nm | | | | |
| Comparison | 3 | SiOC | Nil | PHPS(Nil) | 3000 | 80° C. 24 h | 5 | 1 |
| | | 100 nm | | 150 nm | | | | |
| Comparison | 98 | SiOC | Nil | PHPS(Nil) | 3000 | Nil | 6 | 2 |
| | | 100 nm | | 8 nm | | | | |
| Comparison | 99 | SiOC | Nil | PHPS(Nil) | Nil | Nil | 4 | 2 |
| | | 100 nm | | 8 nm | | | | |
| Comparison | 100 | SiOC | Nil | PHPS(Nil) | 3000 | 80° C. 24 h | 16 | 6 |
| | | 100 nm | | 8 nm | | | | |

| | | | | | | | | Evaluation on | |
|---|---|---|---|---|---|---|---|---|---|
| | | Evaluation on | | | | | Evaluation | dark spots of | |
| | | folding resistance | | Barrier property test | | | on cracking | organic EL device | |
| | | | After | | After | | After | | After |
| | | | DH 500 | | DH 500 | Retention | DH 300 | | DH 500 |
| | Sample No. | Immediately | hours | Immediately | hours | rate (%) | hours | Immediately | hours |
| Comparison | 10 | 5 | 2 | 778 | 231 | 29.7 | 3 | ⊙ | Δ |
| Comparison | 11 | 4 | 2 | 480 | 137 | 28.5 | 3 | ◯ | Δ |
| Comparison | 12 | 5 | 3 | 812 | 239 | 29.4 | 3 | ⊙ | ◯ |
| Present | 21 | 5 | 3 | 885 | 637 | 72.0 | 4 | ⊙ | ◯ |
| invention | | | | | | | | | |
| Present | 22 | 5 | 3 | 528 | 380 | 72.0 | 4 | ◯ | ◯ |
| invention | | | | | | | | | |
| Present | 23 | 5 | 3 | 893 | 642 | 71.9 | 4 | ⊙ | ◯ |
| invention | | | | | | | | | |
| Present | 32 | 5 | 4 | 1011 | 764 | 75.6 | 4 | ⊙ | ◯ |
| invention | | | | | | | | | |
| Present | 33 | 5 | 4 | 624 | 461 | 73.9 | 4 | ◯ | ◯ |
| invention | | | | | | | | | |
| Present | 34 | 5 | 4 | 1055 | 798 | 75.6 | 4 | ⊙ | ◯ |
| invention | | | | | | | | | |
| Present | 43 | 5 | 5 | 1050 | 896 | 85.3 | 5 | ⊙ | ⊙ |
| invention | | | | | | | | | |
| Present | 44 | 5 | 5 | 648 | 550 | 84.9 | 4 | ◯ | ◯ |
| invention | | | | | | | | | |
| Present | 45 | 5 | 5 | 1096 | 930 | 84.8 | 5 | ⊙ | ⊙ |
| invention | | | | | | | | | |
| Present | 54 | 4 | 3 | 796 | 581 | 73.0 | 5 | ◯ | ◯ |
| invention | | | | | | | | | |
| Present | 55 | 3 | 3 | 475 | 346 | 72.8 | 5 | ◯ | ◯ |
| invention | | | | | | | | | |
| Present | 56 | 4 | 3 | 803 | 586 | 73.0 | 5 | ◯ | ◯ |
| invention | | | | | | | | | |
| Comparison | 65 | 3 | 2 | 890 | 178 | 20.0 | 2 | Δ | Δ |
| Comparison | 66 | 3 | 1 | 400 | 75 | 18.8 | 4 | Δ | Δ |
| Comparison | 67 | 3 | 2 | 750 | 143 | 19.1 | 2 | Δ | Δ |
| Comparison | 1 | 3 | 1 | 100 | 1 | 1.0 | 2 | Δ | X |
| Comparison | 2 | 1 | 1 | 30 | 0.3 | 1.0 | 1 | X | X |
| Comparison | 3 | 2 | 1 | 103 | 0.5 | 0.5 | 2 | X | X |
| Comparison | 98 | 2 | 1 | 63 | 5 | 7.9 | 1 | X | X |
| Comparison | 99 | 1 | 1 | 14 | 0 | 0.0 | 1 | X | X |
| Comparison | 100 | 2 | 1 | 61 | 5.8 | 9.5 | 1 | X | X |

TABLE 2

| | | First layer | | Second layer | | | | |
|---|---|---|---|---|---|---|---|---|
| | | Coating | | Vapor phase film deposition | | | Adhesive property | |
| | | | Modification | | Modification | | | After |
| | | Constitution | treatment | | treatment | After- | | DH 500 |
| | Sample No. | (metal species) | mJ/cm² | Constitution | mJ/cm² | treatment | Immediately | hours |
| Comparison | 13 | PHPS(Al) | 3000 | SiOC | Nil | Nil | 81 | 21 |
| | | 150 nm | | 100 nm | | | | |
| Comparison | 14 | PHPS(Al) | Nil | SiOC | Nil | Nil | 61 | 14 |
| | | 150 nm | | 100 nm | | | | |
| Comparison | 15 | PHPS(Al) | 3000 | SiOC | Nil | 80° C. 24 h | 79 | 21 |
| | | 150 nm | | 100 nm | | | | |
| Present | 24 | PHPS(Al) | 3000 | SiOC | Nil | Nil | 85 | 34 |
| invention | | 145 nm | | 100 nm | | | | |
| Present | 25 | PHPS(Al) | Nil | SiOC | Nil | Nil | 65 | 26 |
| invention | | 145 nm | | 100 nm | | | | |
| Present | 26 | PHPS(Al) | 3000 | SiOC | Nil | 80° C. 24 h | 83 | 33 |
| invention | | 145 nm | | 100 nm | | | | |
| Present | 35 | PHPS(Al) | 3000 | SiOC | Nil | Nil | 86 | 60 |
| invention | | 60 nm | | 100 nm | | | | |
| Present | 36 | PHPS(Al) | Nil | SiOC | Nil | Nil | 66 | 46 |
| invention | | 60 nm | | 100 nm | | | | |
| Present | 37 | PHPS(Al) | 3000 | SiOC | Nil | 80° C. 24 h | 84 | 58 |
| invention | | 60 nm | | 100 nm | | | | |
| Present | 46 | PHPS(Al) | 3000 | SiOC | Nil | Nil | 89 | 80 |
| invention | | 8 nm | | 100 nm | | | | |
| Present | 47 | PHPS(Al) | Nil | SiOC | Nil | Nil | 69 | 62 |
| invention | | 8 nm | | 100 nm | | | | |
| Present | 48 | PHPS(Al) | 3000 | SiOC | Nil | 80° C. 24 h | 87 | 78 |
| invention | | 8 nm | | 100 nm | | | | |
| Present | 57 | PHPS(Al) | 3000 | SiOC | Nil | Nil | 83 | 29 |
| invention | | 0.1 nm | | 100 nm | | | | |
| Present | 58 | PHPS(Al) | Nil | SiOC | Nil | Nil | 63 | 22 |
| invention | | 0.1 nm | | 100 nm | | | | |
| Present | 59 | PHPS(Al) | 3000 | SiOC | Nil | 80° C. 24 h | 81 | 28 |
| invention | | 0.1 nm | | 100 nm | | | | |
| Comparison | 68 | PHPS(Al) | 3000 | SiOC | Nil | Nil | 71 | 21 |
| | | 0.08 nm | | 100 nm | | | | |
| Comparison | 69 | PHPS(Al) | Nil | SiOC | Nil | Nil | 51 | 16 |
| | | 0.08 nm | | 100 nm | | | | |
| Comparison | 70 | PHPS(Al) | 3000 | SiOC | Nil | 80° C. 24 h | 69 | 20 |
| | | 0.08 nm | | 100 nm | | | | |
| Comparison | 4 | PHPS(Nil) | 3000 | SiOC | Nil | Nil | 8 | 0 |
| | | 150 nm | | 100 nm | | | | |
| Comparison | 5 | PHPS(Nil) | Nil | SiOC | Nil | Nil | 0 | 0 |
| | | 150 nm | | 100 nm | | | | |
| Comparison | 6 | PHPS(Nil) | 3000 | SiOC | Nil | 80° C. 24 h | 21 | 1 |
| | | 150 nm | | 100 nm | | | | |
| Comparison | 101 | PHPS(Nil) | 3000 | SiOC | Nil | Nil | 21 | 4 |
| | | 8 nm | | 100 nm | | | | |
| Comparison | 102 | PHPS(Nil) | Nil | SiOC | Nil | Nil | 5 | 1 |
| | | 8 nm | | 100 nm | | | | |
| Comparison | 103 | PHPS(Nil) | 3000 | SiOC | Nil | 80° C. 24 h | 36 | 13 |
| | | 8 nm | | 100 nm | | | | |

| | | | | | | | | Evaluation on | |
|---|---|---|---|---|---|---|---|---|---|
| | | Evaluation on | | | | | Evaluation | dark spots of | |
| | | folding resistance | | Barrier property test | | | on cracking | organic EL device | |
| | | | After | | After | | After | | After |
| | | | DH 500 | | DH 500 | Retention | DH 300 | | DH 50 |
| | Sample No. | Immediately | hours | Immediately | hours | rate (%) | hours | Immediately | hours |
| Comparison | 13 | 4 | 2 | 717 | 210 | 29.3 | 3 | ◯ | Δ |
| Comparison | 14 | 4 | 1 | 390 | 114 | 29.2 | 3 | ◯ | Δ |
| Comparison | 15 | 5 | 2 | 839 | 231 | 27.5 | 3 | ⊙ | Δ |
| Present | 24 | 5 | 3 | 788 | 567 | 72.0 | 4 | ◯ | ◯ |
| invention | | | | | | | | | |
| Present | 25 | 5 | 3 | 429 | 308 | 71.8 | 4 | ◯ | ◯ |
| invention | | | | | | | | | |
| Present | 26 | 5 | 3 | 922 | 663 | 71.9 | 4 | ⊙ | ◯ |
| invention | | | | | | | | | |
| Present | 35 | 5 | 4 | 932 | 701 | 75.2 | 4 | ⊙ | ◯ |
| invention | | | | | | | | | |
| Present | 36 | 5 | 3 | 507 | 385 | 75.9 | 4 | ◯ | ◯ |
| invention | | | | | | | | | |
| Present | 37 | 5 | 4 | 1090 | 819 | 75.1 | 4 | ⊙ | ◯ |
| invention | | | | | | | | | |
| Present | 46 | 5 | 5 | 968 | 820 | 84.7 | 5 | ◯ | ◯ |
| invention | | | | | | | | | |
| Present | 47 | 5 | 5 | 527 | 444 | 84.3 | 4 | ◯ | ◯ |
| invention | | | | | | | | | |
| Present | 48 | 5 | 5 | 1133 | 961 | 84.8 | 5 | ⊙ | ⊙ |
| invention | | | | | | | | | |
| Present | 57 | 4 | 3 | 709 | 517 | 72.9 | 5 | ◯ | ◯ |
| invention | | | | | | | | | |
| Present | 58 | 4 | 3 | 386 | 281 | 72.8 | 5 | ◯ | ◯ |
| invention | | | | | | | | | |
| Present | 59 | 4 | 3 | 829 | 605 | 73.0 | 5 | ◯ | ◯ |
| invention | | | | | | | | | |
| Comparison | 68 | 3 | 2 | 601 | 118 | 19.6 | 2 | Δ | Δ |
| Comparison | 69 | 3 | 2 | 300 | 53 | 17.7 | 3 | Δ | Δ |
| Comparison | 70 | 3 | 2 | 726 | 141 | 19.4 | 2 | Δ | Δ |
| Comparison | 4 | 3 | 2 | 120 | 1.5 | 1.3 | 1 | Δ | X |
| Comparison | 5 | 1 | 1 | 5 | 0 | 0.0 | 1 | X | X |
| Comparison | 6 | 2 | 1 | 151 | 6 | 4.0 | 1 | Δ | X |
| Comparison | 101 | 2 | 1 | 60 | 2 | 3.3 | 1 | X | X |
| Comparison | 102 | 2 | 1 | 2 | 0 | 0.0 | 1 | X | X |
| Comparison | 103 | 2 | 1 | 98 | 8 | 8.2 | 1 | X | X |

TABLE 3

| | | First layer | | | | | | | |
|---|---|---|---|---|---|---|---|---|---|
| | | Vapor phase film | | Second layer | | | Third layer | | |
| | | deposition | | Coating | | | Coating | | |
| | | | Modification | | Modification | | | Modification | |
| | | | treatment | Constitution | treatment | After- | Constitution | treatment | After- |
| | Sample No. | Constitution | mJ/cm² | (metal species) | mJ/cm² | treatment | (metal species) | mJ/cm² | treatment |
| Comparison | 16 | SiOC | Nil | PHPS(Nil) | 3000 | Nil | PHPS(Al) | 3000 | Nil |
| | | 100 nm | | 150 nm | | | 150 nm | | |
| Comparison | 17 | SiOC | Nil | PHPS(Nil) | 3000 | Nil | PHPS(Al) | 3000 | 80° C. 24 h |
| | | 100 nm | | 150 nm | | | 150 nm | | |
| Comparison | 18 | SiOC | Nil | PHPS(Al) | 3000 | Nil | PHPS(Al) | 3000 | Nil |
| | | 100 nm | | 150 nm | | | 150 nm | | |
| Comparison | 19 | SiOC | Nil | PHPS(Al) | 3000 | Nil | PHPS(Al) | 3000 | 80° C. 24 h |
| | | 100 nm | | 150 nm | | | 150 nm | | |
| Comparison | 20 | SiOC | 500 | PHPS(Al) | 3000 | Nil | PHPS(Al) | 3000 | 80° C. 24 h |
| | | 100 nm | | 150 nm | | | 150 nm | | |
| Present | 27 | SiOC | Nil | PHPS(Nil) | 3000 | Nil | PHPS(Al) | 3000 | Nil |
| invention | | 100 nm | | 150 nm | | | 145 nm | | |
| Present | 28 | SiOC | Nil | PHPS(Nil) | 3000 | Nil | PHPS(Al) | 3000 | 80° C. 24 h |
| invention | | 100 nm | | 150 nm | | | 145 nm | | |
| Present | 29 | SiOC | Nil | PHPS(Al) | 3000 | Nil | PHPS(Al) | 3000 | Nil |
| invention | | 100 nm | | 145 nm | | | 145 nm | | |
| Present | 30 | SiOC | Nil | PHPS(Al) | 3000 | Nil | PHPS(Al) | 3000 | 80° C. 24 h |
| invention | | 100 nm | | 145 nm | | | 145 nm | | |
| Present | 31 | SiOC | 500 | PHPS(Al) | 3000 | Nil | PHPS(Al) | 3000 | 80° C. 24 h |
| invention | | 100 nm | | 145 nm | | | 145 nm | | |
| Present | 38 | SiOC | Nil | PHPS(Nil) | 3000 | Nil | PHPS(Al) | 3000 | Nil |
| invention | | 100 nm | | 150 nm | | | 60 nm | | |
| Present | 39 | SiOC | Nil | PHPS(Nil) | 3000 | Nil | PHPS(Al) | 3000 | 80° C. 24 h |
| invention | | 100 nm | | 150 nm | | | 60 nm | | |
| Present | 40 | SiOC | Nil | PHPS(Al) | 3000 | Nil | PHPS(Al) | 3000 | Nil |
| invention | | 100 nm | | 60 nm | | | 60 nm | | |
| Present | 41 | SiOC | Nil | PHPS(Al) | 3000 | Nil | PHPS(Al) | 3000 | 80° C. 24 h |
| invention | | 100 nm | | 60 nm | | | 60 nm | | |
| Present | 42 | SiOC | 500 | PHPS(Al) | 3000 | Nil | PHPS(Al) | 3000 | 80° C. 24 h |
| invention | | 100 nm | | 60 nm | | | 60 nm | | |

| | | | | | | | | | | Evaluation on | |
|---|---|---|---|---|---|---|---|---|---|---|---|
| | | | | Evaluation on folding | | | | | Evaluation | dark spots of | |
| | | Adhesive property | | resistance | | Barrier property test | | | on cracking | organic EL device | |
| | | | After | | After | | After | | After | | After |
| | | | DH 500 | | DH 500 | | DH 500 | Retention | DH 300 | | DH 500 |
| | Sample No. | Immediately | hours | Immediately | hours | Immediately | hours | rate (%) | hours | Immediately | hours |
| Comparison | 16 | 98 | 26 | 5 | 2 | 2100 | 600 | 28.6 | 3 | ⊙ | ◯ |
| Comparison | 17 | 100 | 27 | 5 | 3 | 2620 | 774 | 29.5 | 3 | ⊙ | ◯ |
| Comparison | 18 | 88 | 26 | 5 | 3 | 2800 | 810 | 28.9 | 3 | ⊙ | ◯ |
| Comparison | 19 | 99 | 28 | 5 | 3 | 3000 | 870 | 29.0 | 3 | ⊙ | ◯ |
| Comparison | 20 | 100 | 30 | 5 | 3 | 3600 | 930 | 25.8 | 3 | ⊙ | ◯ |
| Present | 27 | 100 | 40 | 5 | 3 | 2310 | 1663 | 72.0 | 4 | ⊙ | ◯ |
| invention | | | | | | | | | | | |
| Present | 28 | 100 | 40 | 5 | 4 | 2882 | 2075 | 72.0 | 4 | ⊙ | ◯ |
| invention | | | | | | | | | | | |
| Present | 29 | 92 | 36 | 5 | 4 | 3080 | 2217 | 72.0 | 4 | ⊙ | ◯ |
| invention | | | | | | | | | | | |
| Present | 30 | 100 | 40 | 5 | 4 | 3300 | 2376 | 72.0 | 4 | ⊙ | ◯ |
| invention | | | | | | | | | | | |
| Present | 31 | 100 | 40 | 5 | 4 | 3960 | 2815 | 71.1 | 4 | ⊙ | ◯ |
| invention | | | | | | | | | | | |
| Present | 38 | 100 | 70 | 5 | 4 | 2730 | 2051 | 75.1 | 4 | ⊙ | ◯ |
| invention | | | | | | | | | | | |
| Present | 39 | 100 | 71 | 5 | 5 | 3406 | 2558 | 75.1 | 4 | ⊙ | ◯ |
| invention | | | | | | | | | | | |
| Present | 40 | 93 | 65 | 5 | 5 | 3640 | 2736 | 75.2 | 4 | ⊙ | ◯ |
| invention | | | | | | | | | | | |
| Present | 41 | 100 | 71 | 5 | 5 | 3900 | 2958 | 75.8 | 5 | ⊙ | ◯ |
| invention | | | | | | | | | | | |
| Present | 42 | 100 | 72 | 5 | 5 | 4680 | 3518 | 75.2 | 5 | ⊙ | ⊙ |
| invention | | | | | | | | | | | |

| | | First layer | | | | | | | |
|---|---|---|---|---|---|---|---|---|---|
| | | Vapor phase film | | Second layer | | | Third layer | | |
| | | deposition | | Coating | | | Coating | | |
| | | | Modification | | Modification | | | Modification | |
| | | | treatment | Constitution | treatment | After- | Constitution | treatment | After- |
| | Sample No. | Constitution | mJ/cm² | (metal species) | mJ/cm² | treatment | (metal species) | mJ/cm² | treatment |
| Present | 49 | SiOC | Nil | PHPS(Nil) | 3000 | Nil | PHPS(Al) | 3000 | Nil |
| invention | | 100 nm | | 150 nm | | | 8 nm | | |
| Present | 50 | SiOC | Nil | PHPS(Nil) | 3000 | Nil | PHPS(Al) | 3000 | 80° C. 24 h |
| invention | | 100 nm | | 150 nm | | | 8 nm | | |
| Present | 51 | SiOC | Nil | PHPS(Al) | 3000 | Nil | PHPS(Al) | 3000 | Nil |
| invention | | 100 nm | | 8 nm | | | 8 nm | | |
| Present | 52 | SiOC | Nil | PHPS(Al) | 3000 | Nil | PHPS(Al) | 3000 | 80° C. 24 h |
| invention | | 100 nm | | 8 nm | | | 8 nm | | |
| Present | 53 | SiOC | 500 | PHPS(Al) | 3000 | Nil | PHPS(Al) | 3000 | 80° C. 24 h |
| invention | | 100 nm | | 8 nm | | | 8 nm | | |
| Present | 60 | SiOC | Nil | PHPS(Nil) | 3000 | Nil | PHPS(Al) | 3000 | Nil |
| invention | | 100 nm | | 150 nm | | | 0.1 nm | | |
| Present | 61 | SiOC | Nil | PHPS(Nil) | 3000 | Nil | PHPS(Al) | 3000 | 80° C. 24 h |
| invention | | 100 nm | | 150 nm | | | 0.1 nm | | |
| Present | 62 | SiOC | Nil | PHPS(Al) | 3000 | Nil | PHPS(Al) | 3000 | Nil |
| invention | | 100 nm | | 0.1 nm | | | 0.1 nm | | |
| Present | 63 | SiOC | Nil | PHPS(Al) | 3000 | Nil | PHPS(Al) | 3000 | 80° C. 24 h |
| invention | | 100 nm | | 0.1 nm | | | 0.1 nm | | |
| Present | 64 | SiOC | 500 | PHPS(Al) | 3000 | Nil | PHPS(Al) | 3000 | 80° C. 24 h |
| invention | | 100 nm | | 0.1 nm | | | 0.1 nm | | |
| Comparison | 71 | SiOC | Nil | PHPS(Nil) | 3000 | Nil | PHPS(Al) | 3000 | Nil |
| | | 100 nm | | 150 nm | | | 0.08 nm | | |
| Comparison | 72 | SiOC | Nil | PHPS(Nil) | 3000 | Nil | PHPS(Al) | 3000 | 80° C. 24 h |
| | | 100 nm | | 150 nm | | | 0.08 nm | | |
| Comparison | 73 | SiOC | Nil | PHPS(Al) | 3000 | Nil | PHPS(Al) | 3000 | Nil |
| | | 100 nm | | 0.08 nm | | | 0.08 nm | | |
| Comparison | 74 | SiOC | Nil | PHPS(Al) | 3000 | Nil | PHPS(Al) | 3000 | 80° C. 24 h |
| | | 100 nm | | 0.08 nm | | | 0.08 nm | | |
| Comparison | 75 | SiOC | 500 | PHPS(Al) | 3000 | Nil | PHPS(Al) | 3000 | 80° C. 24 h |
| | | 100 nm | | 0.08 nm | | | 0.08 nm | | |
| Comparison | 7 | SiOC | Nil | PHPS(Nil) | 3000 | Nil | PHPS(Nil) | 3000 | Nil |
| | | 100 nm | | 150 nm | | | 150 nm | | |
| Comparison | 8 | SiOC | Nil | PHPS(Nil) | 3000 | Nil | PHPS(Nil) | 3000 | 80° C. 24 h |
| | | 100 nm | | 150 nm | | | 150 nm | | |
| Comparison | 104 | SiOC | Nil | PHPS(Nil) | 3000 | Nil | PHPS(Nil) | 3000 | Nil |
| | | 100 nm | | 8 nm | | | 8 nm | | |
| Comparison | 105 | SiOC | Nil | PHPS(Nil) | 3000 | Nil | PHPS(Nil) | 3000 | 80° C. 24 h |
| | | 100 nm | | 8 nm | | | 8 nm | | |

| | | | | | | | | | | Evaluation on | |
|---|---|---|---|---|---|---|---|---|---|---|---|
| | | | | Evaluation on | | | | | Evaluation | dark spots of | |
| | | Adhesive property | | folding resistance | | Barrier property test | | | on cracking | organic EL device | |
| | | | After | | After | | After | | After | | After |
| | | | DH 500 | | DH 500 | | DH 500 | Retention | DH 300 | | DH 500 |
| | Sample No. | Immediately | hours | Immediately | hours | Immediately | hours | rate (%) | hours | Immediately | hours |
| Present | 49 | 100 | 90 | 5 | 5 | 2835 | 2411 | 85.0 | 5 | ⊙ | ⊙ |
| invention | | | | | | | | | | | |
| Present | 50 | 100 | 91 | 5 | 5 | 3537 | 3010 | 85.1 | 5 | ⊙ | ⊙ |
| invention | | | | | | | | | | | |
| Present | 51 | 96 | 90 | 5 | 5 | 3780 | 3222 | 85.2 | 5 | ⊙ | ⊙ |
| invention | | | | | | | | | | | |
| Present | 52 | 100 | 93 | 5 | 5 | 4050 | 3510 | 86.7 | 5 | ⊙ | ⊙ |
| invention | | | | | | | | | | | |
| Present | 53 | 100 | 92 | 5 | 5 | 4860 | 4138 | 85.1 | 5 | ⊙ | ⊙ |
| invention | | | | | | | | | | | |
| Present | 60 | 98 | 34 | 4 | 3 | 1079 | 787 | 72.9 | 5 | ◯ | ◯ |
| invention | | | | | | | | | | | |
| Present | 61 | 98 | 34 | 4 | 3 | 1179 | 860 | 72.9 | 5 | ◯ | ◯ |
| invention | | | | | | | | | | | |
| Present | 62 | 90 | 31 | 4 | 3 | 1580 | 1153 | 73.0 | 5 | ◯ | ◯ |
| invention | | | | | | | | | | | |
| Present | 63 | 98 | 34 | 4 | 3 | 1800 | 1314 | 73.0 | 5 | ◯ | ◯ |
| invention | | | | | | | | | | | |
| Present | 64 | 98 | 34 | 4 | 3 | 2460 | 1759 | 71.5 | 5 | ◯ | ◯ |
| invention | | | | | | | | | | | |
| Comparison | 71 | 88 | 28 | 3 | 2 | 899 | 172 | 19.1 | 2 | Δ | Δ |
| Comparison | 72 | 90 | 28 | 3 | 2 | 1010 | 203 | 20.1 | 2 | Δ | Δ |
| Comparison | 73 | 78 | 23 | 3 | 2 | 1402 | 286 | 20.4 | 2 | Δ | Δ |
| Comparison | 74 | 89 | 24 | 3 | 2 | 1700 | 356 | 20.9 | 2 | Δ | Δ |
| Comparison | 75 | 90 | 24 | 3 | 2 | 2000 | 406 | 20.3 | 2 | Δ | Δ |
| Comparison | 7 | 23 | 2 | 3 | 1 | 252 | 16 | 6.3 | 2 | ◯ | X |
| Comparison | 8 | 40 | 1 | 3 | 1 | 251 | 23 | 9.2 | 2 | Δ | X |
| Comparison | 104 | 29 | 9 | 2 | 1 | 139 | 13 | 9.4 | 1 | X | X |
| Comparison | 105 | 31 | 9 | 2 | 1 | 158 | 14 | 8.9 | 1 | X | X |

TABLE 4

| | |
|---|---|
| First layer | |
| Vapor phase film | Second layer |

| | | |
|---|---|---|
| deposition | Coating | Adhesive property |

| | | | Modification | | Modification | | | After |
|---|---|---|---|---|---|---|---|---|
| | | | treatment | Constitution | treatment | After- | | DH 500 |
| | Sample No. | Constitution | mJ/cm² | (metal species) | mJ/cm² | treatment | Immediately | hours |
| Comparison | 98 | SiOC | Nil | PHPS(Nil) | 3000 | Nil | 6 | 2 |
| | | 100 nm | | 8 nm | | | | |
| Present | 43 | SiOC | Nil | PHPS(Al) | 3000 | Nil | 86 | 77 |
| invention | | 100 nm | | 8 nm | | | | |
| Present | 76 | SiOC | Nil | PHPS(Ga) | 3000 | Nil | 85 | 78 |
| invention | | 100 nm | | 8 nm | | | | |
| Present | 77 | SiOC | Nil | PHPS(In) | 3000 | Nil | 84 | 77 |
| invention | | 100 nm | | 8 nm | | | | |
| Present | 78 | SiOC | Nil | PHPS(Mg) | 3000 | Nil | 86 | 70 |
| invention | | 100 nm | | 8 nm | | | | |
| Present | 79 | SiOC | Nil | PHPS(Ca) | 3000 | Nil | 80 | 77 |
| invention | | 100 nm | | 8 nm | | | | |
| Present | 80 | SiOC | Nil | PHPS(B) | 3000 | Nil | 76 | 72 |
| invention | | 100 nm | | 8 nm | | | | |
| Comparison | 81 | SiOC | Nil | PHPS(Rh) | 3000 | Nil | 56 | 2 |
| | | 100 nm | | 8 nm | | | | |

| | | | | | | | | Evaluation on | |
|---|---|---|---|---|---|---|---|---|---|
| | | Evaluation on | | | | | Evaluation | dark spots of | |
| | | folding resistance | | Barrier property test | | | on cracking | organic EL device | |
| | | | After | | After | | After | | After |
| | | | DH 500 | | DH 500 | Retention | DH 300 | | DH 500 |
| | Sample No. | Immediately | hours | Immediately | hours | rate (%) | hours | Immediately | hours |
| Comparison | 98 | 2 | 1 | 63 | 5 | 7.9 | 1 | X | X |
| Present | 43 | 5 | 5 | 1050 | 896 | 85.3 | 5 | ⊙ | ⊙ |
| invention | | | | | | | | | |
| Present | 76 | 5 | 5 | 1050 | 800 | 76 | 5 | ⊙ | ⊙ |
| invention | | | | | | | | | |
| Present | 77 | 4 | 4 | 1000 | 878 | 88 | 5 | ⊙ | ⊙ |
| invention | | | | | | | | | |
| Present | 78 | 5 | 5 | 930 | 823 | 88 | 5 | ⊙ | ⊙ |
| invention | | | | | | | | | |
| Present | 79 | 5 | 4 | 990 | 812 | 82 | 5 | ⊙ | ⊙ |
| invention | | | | | | | | | |
| Present | 80 | 5 | 4 | 1003 | 832 | 83 | 5 | ⊙ | ⊙ |
| invention | | | | | | | | | |
| Comparison | 81 | 3 | 1 | 5 | 1 | 20 | 1 | Δ | X |

TABLE 5

| | | First layer | | | | | |
|---|---|---|---|---|---|---|---|
| | | Vapor phase film | | Second layer | | | |
| | | deposition | | Coating | | | Third layer |
| | | | Modification | | Modification | | Coating |
| | | | treatment | Constitution | treatment | After- | Constitution |
| | Sample No. | Constitution | mJ/cm² | (metal species) | mJ/cm² | treatment | (metal species) |
| Comparison | 122 | SiOC | Nil | PHPS(Nil) | 1000 | Nil | PHPS(Nil) |
| | | 100 nm | | 8 nm | | | 40 nm |
| Comparison | 123 | SiOC | Nil | PHPS(Nil) | 1000 | Nil | PHPS(Nil) |
| | | 100 nm | | 8 nm | | | 40 nm |
| Present | 124 | SiOC | Nil | PHPS(Al) | 1000 | Nil | PHPS(Nil) |
| invention | | 100 nm | | 8 nm | | | 40 nm |
| Present | 125 | SiOC | Nil | PHPS(Al) | 1000 | Nil | PHPS(Nil) |
| invention | | 100 nm | | 8 nm | | | 40 nm |
| Present | 126 | SiOC | Nil | PHPS(Nil) | 1000 | Nil | PHPS(Al) |
| invention | | 100 nm | | 8 nm | | | 40 nm |
| Present | 127 | SiOC | Nil | PHPS(Nil) | 1000 | Nil | PHPS(Al) |
| invention | | 100 nm | | 8 nm | | | 40 nm |
| Present | 128 | SiOC | Nil | PHPS(Nil) | 1000 | Nil | PHPS(Nil) |
| invention | | 100 nm | | 8 nm | | | 40 nm |
| Present | 129 | SiOC | Nil | PHPS(Nil) | 1000 | Nil | PHPS(Nil) |
| invention | | 100 nm | | 8 nm | | | 40 nm |
| Comparison | 130 | SiOC | Nil | PHPS(Rh) | 1000 | Nil | PHPS(Nil) |
| | | 100 nm | | 8 nm | | | 40 nm |
| Comparison | 131 | SiOC | Nil | PHPS(Rh) | 1000 | Nil | PHPS(Nil) |
| | | 100 nm | | 8 nm | | | 40 nm |

| | | Third layer | | Fourth layer | | |
|---|---|---|---|---|---|---|
| | | Coating | | Coating | | |
| | | Modification | | | Modification | |
| | | treatment | After- | Constitution | treatment | After- |
| | Sample No. | mJ/cm² | treatment | (metal species) | mJ/cm² | treatment |
| Comparison | 122 | 1000 | Nil | PHPS(Nil) | 1000 | Nil |
| | | | | 8 nm | | |
| Comparison | 123 | 1000 | Nil | PHPS(Nil) | 1000 | 80° C. 24 h |
| | | | | 8 nm | | |
| Present | 124 | 1000 | Nil | PHPS(Nil) | 1000 | Nil |
| invention | | | | 8 nm | | |
| Present | 125 | 1000 | Nil | PHPS(Nil) | 1000 | 80° C. 24 h |
| invention | | | | 8 nm | | |
| Present | 126 | 1000 | Nil | PHPS(Nil) | 1000 | Nil |
| invention | | | | 8 nm | | |
| Present | 127 | 1000 | Nil | PHPS(Nil) | 1000 | 80° C. 24 h |
| invention | | | | 8 nm | | |
| Present | 128 | 1000 | Nil | PHPS(Al) | 1000 | Nil |
| invention | | | | 8 nm | | |
| Present | 129 | 1000 | Nil | PHPS(Al) | 1000 | 80° C. 24 h |
| invention | | | | 8 nm | | |
| Comparison | 130 | 1000 | Nil | PHPS(Nil) | 1000 | Nil |
| | | | | 8 nm | | |
| Comparison | 131 | 1000 | Nil | PHPS(Nil) | 1000 | 80° C. 24 h |
| | | | | 8 nm | | |

| | | | | | | | | | | Evaluation on | |
|---|---|---|---|---|---|---|---|---|---|---|---|
| | | | | Evaluation on | | | | | Evaluation | dark spots of | |
| | | Adhesive property | | folding resistance | | Barrier property test | | | on cracking | organic EL device | |
| | | | After | | After | | After | | After | | After |
| | | | DH 500 | | DH 500 | | DH 500 | Retention | DH 300 | | DH 500 |
| | Sample No. | Immediately | hours | Immediately | hours | Immediately | hours | rate (%) | hours | Immediately | hours |
| Comparison | 122 | 7 | 0 | 2 | 1 | 45 | 2 | 4.4 | 1 | X | X |
| Comparison | 123 | 8 | 0 | 2 | 1 | 48 | 0 | 0.0 | 1 | X | X |
| Present | 124 | 88 | 80 | 5 | 4 | 1900 | 1700 | 89.5 | 5 | ⊙ | ⊙ |
| invention | | | | | | | | | | | |
| Present | 125 | 95 | 90 | 5 | 5 | 1980 | 1900 | 96.0 | 5 | ⊙ | ⊙ |
| invention | | | | | | | | | | | |
| Present | 126 | 85 | 80 | 5 | 5 | 1800 | 1700 | 94.4 | 5 | ⊙ | ⊙ |
| invention | | | | | | | | | | | |
| Present | 127 | 90 | 88 | 5 | 5 | 1900 | 1850 | 97.4 | 5 | ⊙ | ⊙ |
| invention | | | | | | | | | | | |
| Present | 128 | 80 | 78 | 5 | 5 | 1600 | 1560 | 97.5 | 5 | ⊙ | ⊙ |
| invention | | | | | | | | | | | |
| Present | 129 | 86 | 85 | 5 | 5 | 1750 | 1550 | 88.6 | 5 | ⊙ | ⊙ |
| invention | | | | | | | | | | | |
| Comparison | 130 | 15 | 2 | 1 | 1 | 30 | 0 | 0.0 | 1 | Δ | X |
| Comparison | 131 | 3 | 1 | 1 | 1 | 11 | 0 | 0.0 | 1 | X | X |

TABLE 6

| | | First layer | | | | | | |
|---|---|---|---|---|---|---|---|---|
| | | Vapor phase film | | Second layer | | | | |
| | | deposition | | Coating | | | Adhesive property | |
| | | | Modification | | Modification | | | After |
| | | | treatment | Constitution | treatment | After- | | DH 500 |
| | Sample No. | Constitution | mJ/cm² | (metal species) | mJ/cm² | treatment | Immediately | hours |
| Comparison | 132 | Si₃N₄ | Nil | PHPS(Nil) | 2000 | Nil | 11 | 0 |
| | | 60 nm | | 8 nm | | | | |
| Comparison | 133 | Si₃N₄ | Nil | PHPS(Nil) | 2000 | 80° C. 24 h | 15 | 0 |
| | | 60 nm | | 8 nm | | | | |
| Present | 134 | Si₃N₄ | Nil | PHPS(Al) | 2000 | Nil | 92 | 90 |
| invention | | 60 nm | | 8 nm | | | | |
| Present | 135 | Si₃N₄ | Nil | PHPS(Al) | 2000 | 80° C. 24 h | 100 | 95 |
| invention | | 60 nm | | 8 nm | | | | |

| | | | | | | | | Evaluation on | |
|---|---|---|---|---|---|---|---|---|---|
| | | Evaluation on | | | | | Evaluation | dark spots of | |
| | | folding resistance | | Barrier property test | | | on cracking | organic EL device | |
| | | | After | | After | | After | | After |
| | | | DH 500 | | DH 500 | Retention | DH 300 | | DH 500 |
| | Sample No. | Immediately | hours | Immediately | hours | rate (%) | hours | Immediately | hours |
| Comparison | 132 | 2 | 1 | 78 | 4 | 5.1 | 1 | Δ | X |
| Comparison | 133 | 3 | 1 | 82 | 3 | 3.7 | 1 | Δ | X |
| Present | 134 | 5 | 5 | 1840 | 1723 | 93.6 | 5 | ⊙ | ⊙ |
| invention | | | | | | | | | |
| Present | 135 | 5 | 5 | 1980 | 1880 | 94.9 | 5 | ⊙ | ⊙ |
| invention | | | | | | | | | |

From the results of Tables 1 to 6, it has been found that the gas barrier film of the present invention, by adding at least one element selected from the group consisting of Group 2 elements, Group 13 elements, and Group 14 elements in the long-period periodic table (provided that silicon and carbon are excluded) in the barrier layer formed by coating a solution containing a polysilazane compound, exhibits superior adhesive property, folding resistance, crack resistance, and gas barrier property before and after a high temperature and a high humidity as compared to the case which has the same layer constitution but does not contain these elements. In addition, it has been demonstrated that the adhesive property, folding resistance, gas barrier property, and crack resistance can be maintained even in a high temperature and high humidity environment as the thickness of the barrier layer formed by coating a solution containing a polysilazane compound is set to 0.1 nm or more and less than 150 nm.

In addition, the barrier property can be improved as the barrier layer formed by coating a solution containing a polysilazane compound or the barrier layer formed by vapor phase film deposition, in particular the barrier layer formed by coating a solution containing a polysilazane compound is subjected to the modification treatment. The barrier property can be further improved by further conducting the after-treatment.

For example, as presented in Table 1, the performance of the gas barrier film is improved as the barrier layer formed by coating contains a specific additive element (metal species) although the layer constitution is the same from the comparison between Sample 1 and Sample 10. In addition to this, in particular the adhesive property, folding resistance, gas barrier property, and crack resistance after storing in a high temperature and high humidity environment are improved as the thickness of the barrier layer formed by coating is set to 0.1 nm or more and less than 150 nm as in Samples 21, 32, 43, and 54. In particular, the gas barrier property is maintained high even after storing in a high temperature and high humidity environment. In the same manner, Samples 23, 34, 45, and 56 exhibit well-balanced superior properties in adhesive property, folding resistance, gas barrier property, and crack resistance after storing in a high temperature and high humidity environment as compared to Sample 12 or Sample 67 which has the same layer constitution as Samples 23, 34, 45, and 56 but has a thickness of the barrier layer by coating of 150 nm or more or smaller than 0.1 nm, respectively. In particular, the gas barrier property is maintained high even after storing in a high temperature and high humidity environment as the thickness of the barrier layer by coating is set to be in a predetermined range.

In addition, when Samples 21, 22, and 23 are compared to one another, Samples 21 and 23 in which the barrier layer formed by coating is subjected to the modification treatment exhibit superior gas barrier property than Sample 22 that is not subjected to the modification treatment, and the adhesive property is further improved by conducting the after-treatment as in Sample 23. The same tendency is seen among Samples 32 to 34, among Samples 43 to 45, and among Samples 54 to 56.

In addition, the gas barrier property can be further improved as the barrier layer formed by vapor phase film deposition is subjected to the modification treatment when the layer constitution is the same (for example, comparison between Sample 30 and Sample 31 or comparison between Sample 41 and Sample 42).

Moreover, when Samples 21 to 23 in Table 1 are compared to Samples 24 to 26 in Table 2, it has been found that Samples 21 to 23 in which the substrate, the barrier layer by coating, and the barrier layer by vapor phase film deposition are stacked in this order exhibit superior performance when other constitutions are the same. The same tendency has been confirmed in comparison between Samples 32 to 34 and Samples 35 to 37, in comparison between Samples 43 to 45 and Samples 46 to 48, and in comparison between Samples 54 to 56 and Samples 57 to 59.

The gas barrier property is further improved as a plurality of barrier layers by coating are stacked as in Samples 27 to 31, 38 to 42, 49 to 53, 60 to 64, and 124 to 129.

It has been found that in the case of using Ga, In, Mg, Ca, and B other than Al as the additive elements (metal species) as in Samples 76 to 80 in Table 4 as well, an improvement in gas barrier property, adhesive property, folding resistance, and crack resistance are seen and a decreases in performance is suppressed even after storing in a high temperature and high humidity environment as compared to a case in which a barrier layer which does not contain an additive element is formed, but the desired effect is not obtained in the barrier layer to which Rh is added as in Sample 81.

In addition, in the gas barrier film in which the barrier layer formed by vapor phase film deposition is a deposited layer containing a nitrogen atom as Samples 134 and 135 in Table 6, particularly excellent gas barrier property, adhesive property, and folding resistance are exhibited and gas barrier property, adhesive property, folding resistance, and crack resistance are maintained high even in a wet heat environment among Samples having a constitution in which one barrier layer by vapor phase film deposition and one barrier layer by coating are formed on the substrate.

As described above, the gas barrier film of the present invention exhibits excellent adhesive property, folding resistance, barrier property, and crack resistance, and a fluctuation in performance by a high temperature and high humidity environment is suppressed in any constitution of a case in which the barrier layer formed by vapor phase film deposition and the barrier layer formed by coating are stacked on the substrate in this order (Tables 1, 4, and 6), a case in which the barrier layer formed by coating and the barrier layer formed by vapor phase film deposition are stacked on the substrate in this order (Table 2), or a case in which three or more barrier layers including these layers are included in total (Tables 3 and 5).

Incidentally, this application is based on Japanese Patent Application No. 2013-138333 filed on Jul. 1, 2013, the entire contents of which are incorporated herein by reference.

1. A gas barrier film comprising:
a substrate;
a barrier layer formed by vapor phase film deposition of an inorganic compound at least on one surface of the substrate; and
a barrier layer formed by coating a solution containing a polysilazane compound at least on the same surface as the surface of the substrate on which the barrier layer formed by vapor phase film deposition of an inorganic compound is formed, wherein the barrier layer formed by coating a solution containing a polysilazane compound comprises at least one element selected from the group consisting of Group 2 elements, Group 13 elements, and Group 14 elements in the long-period periodic table (provided that silicon and carbon are excluded), and
a thickness of the barrier layer formed by coating a solution containing a polysilazane compound is 0.1 nm or more and less than 150 nm.

2. The gas barrier film according to claim 1, wherein the element is at least one member selected from the group consisting of aluminum (Al), indium (In), gallium (Ga), magnesium (Mg), calcium (Ca), germanium (Ge), and boron (B).

3. The gas barrier film according to claim 2, wherein the element is aluminum.

4. The gas barrier film according to claim 1, wherein at least either of the barrier layer formed by vapor phase film deposition of an inorganic compound or the barrier layer formed by coating a solution containing a polysilazane compound is formed through a modification treatment by vacuum ultraviolet irradiation.

5. The gas barrier film according to claim 1, wherein the barrier layer formed by vapor phase film deposition of an inorganic compound is a deposited layer containing a nitrogen atom.

6. The gas barrier film according to claim 1, wherein the barrier layer formed by coating a solution containing a polysilazane compound is formed through temperature treatment.

7. The gas barrier film according to claim 1, wherein the gas barrier film comprises the substrate, the barrier layer formed by vapor phase film deposition of an inorganic compound, and the barrier layer formed by coating a solution containing a polysilazane compound in this order.

8. The gas barrier film according to claim 7, wherein the gas barrier film comprises two or more barrier layers formed by coating a solution containing a polysilazane compound on the barrier layer formed by vapor phase film deposition of an inorganic compound.

9. A method for producing a gas barrier film, comprising:
forming a barrier layer on a substrate by vapor phase film deposition of an inorganic compound; and
forming a barrier layer on the barrier layer formed by vapor phase film deposition of an inorganic compound by coating a solution containing a polysilazane compound and a compound containing at least one element selected from the group consisting of Group 2 elements, Group 13 elements, and Group 14 elements in the long-period periodic table (provided that silicon and carbon are excluded), wherein
a thickness of the barrier layer formed by coating a solution containing a polysilazane compound is 0.1 nm or more and less than 150 nm.

10. The production method according to claim 9, further comprising conducting a modification treatment by irradiating at least either of the barrier layer formed by vapor phase film deposition of an inorganic compound or the barrier layer formed by coating a solution containing a polysilazane compound with vacuum ultraviolet rays.

11. The production method according to claim 10, wherein the barrier layer formed by coating a solution containing a polysilazane compound is subjected to a modification treatment, and the method further comprises subjecting the barrier layer formed by coating a solution containing a polysilazane compound after being subjected to the modification treatment to temperature treatment.

12. An electronic device comprising the gas barrier film set forth in claim 1.
